(19) United States
(12) Patent Application Publication
(10) Pub. No.: US 2026/0314341 A1
(43) Pub. Date: Oct. 8, 2026

(54) WET-REMOVABLE SILICON-CONTAINING RESIST UNDERLAYER FILM-FORMING COMPOSITION

(71) Applicant: Nissan Chemical Corporation, Tokyo (JP)

(72) Inventors: Taiki SAIJO, Toyama (JP); Shuhei SHIGAKI, Toyama (JP); Wataru SHIBAYAMA, Toyama (JP)

(73) Assignee: Nissan Chemical Corporation, Tokyo (JP)

(21) Appl. No.: 19/478,035

(22) PCT Filed: Apr. 26, 2024
(86) PCT No.: PCT/JP2024/016368

§ 371 Date: Oct. 23, 2025

(30) Foreign Application Priority Data
Apr. 27, 2023 (JP) 2023-073223

(51) Int. Cl. H10P 76/20; G03F 7/11; G03F 7/20; H10P 50/68

(52) U.S. Cl. CPC H10P 76/2043; G03F 7/11; G03F 7/20; H10P 50/68

(57) ABSTRACT

A silicon-containing resist underlayer film-forming composition for forming a silicon-containing resist underlayer film containing a hydrolysis-condensation compound of a hydrolyzable silane mixture containing a hydrolyzable silane represented by Si(R¹³)₄ and a hydrolyzable silane represented by (R¹)ⱼ(R²)ₕSi(R³)₄₋₍ⱼ₊ₕ₎ and soluble in a basic chemical solution. A silicon-containing resist underlayer film formed from the silicon-containing resist underlayer film-forming composition, a laminate including the silicon-containing resist underlayer film, a method for producing a semiconductor element using the silicon-containing resist underlayer film-forming composition, and a pattern method.

### TECHNICAL FIELD

The present invention relates to a wet-removable silicon-containing resist underlayer film-forming composition.

### BACKGROUND ART

Conventionally, in the production of semiconductor devices, microfabrication using lithography with a photoresist has been performed. The microfabrication is a processing method including: forming a photoresist thin film on a semiconductor substrate such as a silicon wafer; irradiating the thin film with active rays such as ultraviolet rays through a mask pattern having a semiconductor device pattern drawn thereon; developing the irradiated thin film; and etching the substrate with the obtained photoresist pattern serving as a protective film to form, on the surface of the substrate, fine irregularities corresponding to the pattern.

In recent years, as a result of an increase in the degree of integration of semiconductor devices, active rays having a shorter wavelength have tended to be used, that is, shifting from KrF excimer laser (248 nm) to ArF excimer laser (193 nm). With the shortening of the wavelength of an active ray, the influence of reflection of the active ray from the semiconductor substrate becomes a major problem, and a method for providing a resist underlayer film called a bottom anti-reflective coating (BARC) between a photoresist and a substrate to be processed has been widely applied.

A film known as a hard mask containing a metal element such as silicon or titanium has been used as an underlayer between a semiconductor substrate and a photoresist. In this case, the resist and the hard mask are significantly different in components, and the rates to remove the resist and hard mask by dry etching are greatly dependent on the types of gas used for dry etching. Therefore, the appropriate selection of a gas type allows the hard mask to be removed by dry etching without a large reduction in the film thickness of the photoresist. Thus, in the production of semiconductor devices in recent years, a resist underlayer film has been increasingly disposed between a semiconductor substrate and a photoresist to achieve various effects such as an antireflection effect.

Although compositions for resist underlayer films have been studied so far, and development of a new material for the resist underlayer film has been desired because a variety of characteristics are required for the resist underlayer film. For example, Patent Literature 1 discloses a coating-type composition for forming a boron phosphorus glass (BPSG) film containing a structure having a specific silicic acid as a skeleton in response to the issue of forming a wet-etchable film, and Patent Literature 2 discloses a silicon-containing resist underlayer film-forming composition containing a carbonyl structure in response to the issue of providing a method for removing a mask residue with a chemical after lithography.

### CITATION LIST

### Patent Literature

Patent Literature 1: JP 2016-74774 A
Patent Literature 2: WO 2018/181989 A

### SUMMARY OF INVENTION

### Technical Problem

In the most advanced semiconductor devices, while a multilayer process is frequently used due to miniaturization of an implant layer, transfer to an underlayer is usually performed by the above-described dry etching in the multilayer process, and finally processing of a substrate and removal of a mask residue after processing of the substrate, for example, a resist film or an underlayer film including a resist underlayer film may also be performed by dry etching or ashing processing. However, dry etching and ashing treatment are not without causing damage to the substrate, and improvement thereof is required.

The present invention has been made in view of the above circumstances, and an object of the present invention is to provide a silicon-containing resist underlayer film-forming composition that can be peeled off not only by a conventional dry etching method but also by a wet etching method using a chemical solution such as dilute hydrofluoric acid, buffered hydrofluoric acid, or an alkaline chemical solution (basic chemical solution) in a processing step of a semiconductor substrate or the like, and can form a resist underlayer film exhibiting excellent solubility particularly in alkaline chemical solution (basic chemical solution), a silicon-containing resist underlayer film that is formed from the silicon-containing resist underlayer film-forming composition, has excellent storage stability, and exhibits excellent solubility with respect to a chemical solution, a laminate including the silicon-containing resist underlayer film, and a method for producing a semiconductor element using the silicon-containing resist underlayer film-forming composition, and a pattern method.

### Solution to Problem

As a result of intensive studies to solve the above problems, the present inventors have found that the above problems can be solved, and have completed the present invention having the following gist.

That is, the present invention includes the following aspects.

[1] A silicon-containing resist underlayer film-forming composition for forming a silicon-containing resist underlayer film containing a hydrolysis-condensation compound of a hydrolyzable silane mixture containing a hydrolyzable silane represented by Formula (1-1) below and a hydrolyzable silane represented by Formula (2) below and soluble in a basic chemical solution, the composition containing:
a hydrolyzable silane represented by Formula (1-1)

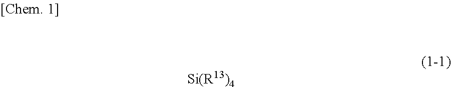

(in Formula (1-1),
R¹³ is a group or an atom bonded to a silicon atom, and each independently represents a hydroxy group, an alkoxy group, an aralkyloxy group, an acyloxy group, or a halogen atom); and
a hydrolyzable silane represented by Formula (2)

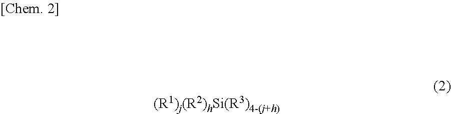

(in Formula (2),
R¹ is a group bonded to a silicon atom, and represents an organic group containing a succinic anhydride skeleton,
R² is a group bonded to a silicon atom, and each independently represents an optionally substituted alkyl group, an optionally substituted halogenated alkyl group, or an optionally substituted alkoxyalkyl group, or represents an organic group containing an epoxy group, an acryloyl group, a methacryloyl group, a mercapto group, an amino group, an amide group, an alkoxy group, a sulfonyl group, or a cyano group, or a combination of two or more thereof,
R³ is a group or an atom bonded to a silicon atom, and each independently represents an alkoxy group, an aralkyloxy group, an acyloxy group, or a halogen atom,
j represents 1, h represents an integer of 0 to 2, and 4-(j+h) represents an integer of 1 to 3).

[2] The silicon-containing resist underlayer film-forming composition according to [1], in which in the hydrolyzable silane mixture, a content ratio of the hydrolyzable silane represented by the Formula (1-1) is more than 0 mol % and 30 mol % or less with respect to 100 mol % of the hydrolyzable silane contained in the hydrolyzable silane mixture.

[3] The silicon-containing resist underlayer film-forming composition according to [1], in which
the hydrolyzable silane mixture further contains a hydrolyzable silane represented by Formula (1) below.

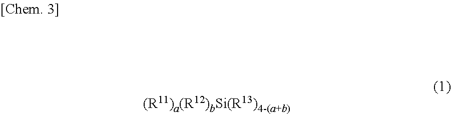

In Formula (1), R¹¹ is a group bonded to a silicon atom, and each independently represents a monovalent group represented by Formula (2a) below or a monovalent group represented by Formula (2b) below.
R¹² is a group bonded to a silicon atom, and each independently represents an optionally substituted alkyl group, an optionally substituted aryl group, an optionally substituted aralkyl group, an optionally substituted halogenated alkyl group, an optionally substituted halogenated aryl group, an optionally substituted halogenated aralkyl group, an optionally substituted alkoxyalkyl group, an optionally substituted alkoxyaryl group, an optionally substituted alkoxyaralkyl group, or an optionally substituted alkenyl group, or an organic group including an epoxy group, an acryloyl group, a methacryloyl group, a mercapto group, an amino group, an alkoxy group, a sulfonyl group, or a cyano group, or a combination of two or more thereof.
R¹³ is a group or an atom bonded to a silicon atom, and each independently represents a hydroxy group, an alkoxy group, an aralkyloxy group, an acyloxy group, or a halogen atom.
a represents an integer of 0 to 2, b represents an integer of 0 to 2, and 4-(a+b) represents an integer of 1 to 3.

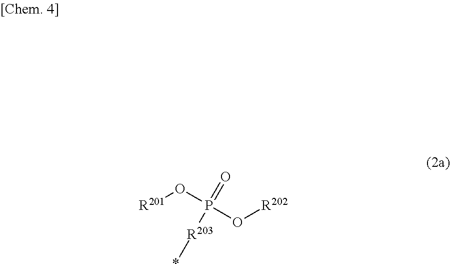

(In Formula (2a),
R²⁰¹ to R²⁰² each independently represent a hydrogen atom or an organic group containing an optionally substituted alkyl group, R²⁰³ represents an optionally substituted alkylene group, and * represents a bond bonded to a silicon atom.)

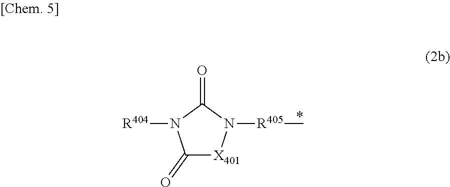

(In Formula (2b),
R⁴⁰⁴ each independently represents a hydrogen atom, an optionally substituted alkyl group, an optionally substituted alkenyl group, or an organic group having an epoxy group or an organic group having a sulfonyl group, and R⁴⁰⁵ each independently represents an alkylene group, a hydroxyalkylene group, a sulfide bond (—S—), an ether bond (—O—), or an ester bond (—CO—O— or —O—CO—). * represents a bond.
X₄₀₁ each independently represents any of the groups represented by Formulas (4-3) to (4-5) below, and a carbon atom of a ketone group in Formulas (4-4) and (4-5) below is bonded to the nitrogen atom to which R⁴⁰⁵ in Formula (2b) is bonded.

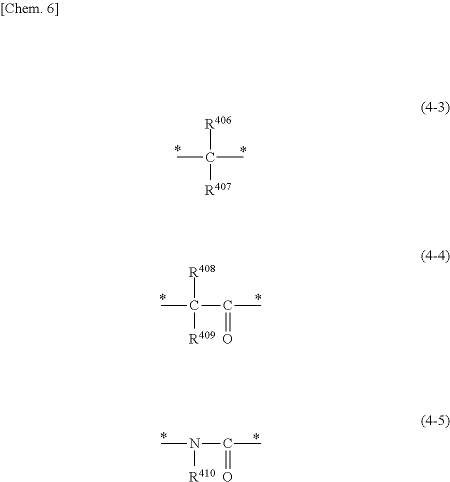

(In Formulas (4-3) to (4-5),
R⁴⁰⁶ to R⁴¹⁰ each independently represent a hydrogen atom, an optionally substituted alkyl group, an optionally substituted alkenyl group, or an organic group having an epoxy group or a sulfonyl group. * represents a bond.))

[4] The silicon-containing resist underlayer film-forming composition according to [3], containing a hydrolyzable silane represented by Formula (1-2) below among the hydrolyzable silanes represented by the Formula (1).

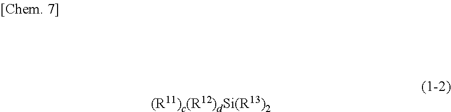

(In Formula (1-2),
R¹¹ is the same as R¹¹ in the Formula (1).
R¹² is the same as R¹² in Formula (1).
R¹³ is the same as R¹³ in Formula (1).
c represents an integer of 0 to 2, d represents an integer of 0 to 2, and c+d=2.)

[5] The silicon-containing resist underlayer film-forming composition according to [3], containing a hydrolyzable silane represented by Formula (1-3) below among the hydrolyzable silanes represented by the Formula (1).

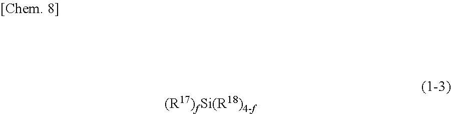

(In Formula (1-3), R¹⁷ is a group bonded to a silicon atom, and each independently represents an optionally substituted alkyl group, an optionally substituted aryl group, an optionally substituted aralkyl group, an optionally substituted halogenated alkyl group, an optionally substituted halogenated aryl group, an optionally substituted halogenated aralkyl group, an optionally substituted alkoxyalkyl group, an optionally substituted alkoxyaryl group, an optionally substituted alkoxyaralkyl group, or an optionally substituted alkenyl group, or an organic group containing an epoxy group, an acryloyl group, a methacryloyl group, a mercapto group, an amino group, or a cyano group.
R¹⁸ is a group or an atom bonded to a silicon atom, and each independently represents an alkoxy group, an aralkyloxy group, an acyloxy group, or a halogen atom.
f represents an integer of 1 to 3).

[6] A silicon-containing resist underlayer film, which is a cured product of the silicon-containing resist underlayer film-forming composition according to any one of [1] to [5].

[7] A laminate including: a semiconductor substrate; and the silicon-containing resist underlayer film according to in [6].

[8] A method for producing a semiconductor element, the method including:
a step of forming an organic underlayer film on a substrate;
a step of forming a silicon-containing resist underlayer film using the silicon-containing resist underlayer film-forming composition according to any one of [1] to [5] on the organic underlayer film; and a step of forming a resist film on the silicon-containing resist underlayer film.

[9] A method for forming a pattern, the method including:
a step of forming an organic underlayer film on a semiconductor substrate;
a step of applying the silicon-containing resist underlayer film-forming composition according to any one of [1] to [5] on the organic underlayer film and baking to form a silicon-containing resist underlayer film;
a step of forming a resist film on the silicon-containing resist underlayer film;
a step of exposing and developing the resist film to obtain a resist pattern;
a step of etching the silicon-containing resist underlayer film using the resist pattern as a mask; and
a step of etching the organic underlayer film using the patterned silicon-containing resist underlayer film as a mask.

[10] The method for forming a pattern according to [9], further including
a step of removing the silicon-containing resist underlayer film by a wet method using a chemical solution, after the step of etching the organic underlayer film.

[11] The method for forming a pattern according to [10], in which the chemical solution is a basic chemical solution.

### Advantageous Effects of Invention

According to the present invention, it is possible to provide a silicon-containing resist underlayer film-forming composition which can be peeled off not only by a conventional dry etching method but also by a wet etching method using a chemical solution such as dilute hydrofluoric acid, buffered hydrofluoric acid, or an alkaline chemical solution (basic chemical solution) in a processing step of a semiconductor substrate or the like and can form a resist underlayer film exhibiting excellent solubility particularly in an alkaline chemical solution (basic chemical solution), a silicon-containing resist underlayer film which is formed from the silicon-containing resist underlayer film-forming composition and exhibits excellent storage stability and solubility with respect to a chemical solution, a laminate including the silicon-containing resist underlayer film, and a method for producing a semiconductor element using the silicon-containing resist underlayer film-forming composition, and a pattern method.

### DESCRIPTION OF EMBODIMENTS

Hereinafter, the present invention will be described in detail. Note that the description of the constituent requirements described below is an example for describing the present invention, and the present invention is not limited to the content thereof.

### [Silicon-Containing Resist Underlayer Film-Forming Composition]

The present invention is directed to a composition for forming a silicon-containing resist underlayer film that can be peeled off by a wet method, particularly that exhibits excellent solubility to a basic chemical solution.

The silicon-containing resist underlayer film-forming composition of the present invention contains a product (hydrolysis-condensation compound) obtained by hydrolytically condensing a hydrolyzable silane mixture containing a hydrolyzable silane.

One feature of the silicon-containing resist underlayer film-forming composition of the present invention is that, among the hydrolyzable silanes constituting the hydrolyzable silane mixture, a hydrolyzable silane of a tetrafunctional monomer and a hydrolyzable silane represented by a specific structural formula are contained. Hereinafter, a detailed description will be given in the section of (Silicon-Containing Resist Underlayer Film-Forming Composition of First Aspect).

In addition, the silicon-containing resist underlayer film-forming composition of the present invention preferably contains a hydrolyzable silane of a bifunctional monomer among the hydrolyzable silanes constituting the hydrolyzable silane mixture. Therefore, this aspect will be described in detail below in the section of (Silicon-Containing Resist Underlayer Film-Forming Composition of Second Aspect).

The silicon-containing resist underlayer film-forming composition of the present invention may contain other components such as a solvent and various additives in addition to the hydrolysis-condensation compound of the hydrolyzable silane mixture.

In the present invention, the hydrolysis-condensation compound includes not only a polyorganosiloxane polymer that is a condensation compound in which the condensation has been completely completed, but also a polyorganosiloxane polymer that is a partially hydrolysis-condensation compound in which the condensation has not been completely completed. Such a partial hydrolysis-condensation compound is a polymer obtained through hydrolysis and condensation of a hydrolyzable silane compound, similarly to a condensation product in which the condensation has been completely completed. However, hydrolysis proceeds only partially without undergoing condensation, and therefore, Si—OH groups remain. Further, the silicon-containing resist underlayer film-forming composition of the present invention may contain an uncondensed hydrolysate (complete hydrolysate or partial hydrolysate) or a remaining monomer (hydrolyzable silane compound), in addition to the hydrolysis-condensation compound.

In the present specification, the “hydrolyzable silane” may be simply referred to as “silane compound”.

### (Silicon-Containing Resist Underlayer Film-Forming Composition of First Aspect)

The silicon-containing resist underlayer film-forming composition of the present invention contains a hydrolysis-condensation compound of a hydrolyzable silane mixture containing a hydrolyzable silane of a tetrafunctional monomer and a hydrolyzable silane represented by a specific structural formula having an organic acid including a succinic anhydride skeleton.

### <Hydrolysis-Condensation Compound of Hydrolyzable Silane Mixture>

The hydrolyzable silane mixture contains a hydrolyzable silane represented by the following Formula (1-1) and a hydrolyzable silane represented by the following Formula (2).

The hydrolyzable silane mixture preferably further contains a hydrolyzable silane represented by the following Formula (1) in addition to the hydrolyzable silane represented by Formula (1-1) or Formula (2).

In addition, the hydrolyzable silane mixture preferably contains, among the hydrolyzable silanes represented by Formula (1), particularly a bifunctional hydrolyzable silane represented by Formula (1-2).

In addition, the hydrolyzable silane mixture preferably contains, among the hydrolyzable silanes represented by Formula (1), particularly a hydrolyzable silane represented by Formula (1-3).

### <<Silane Compound (Hydrolyzable Silane) Represented by Formula (1-1)>>

The hydrolyzable silane mixture according to the present invention contains a hydrolyzable silane of a tetrafunctional monomer represented by the following Formula (1-1).

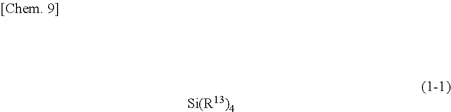

In Formula (1-1),
R¹³ is a group or an atom bonded to a silicon atom, and each independently represents a hydroxy group, an alkoxy group, an aralkyloxy group, an acyloxy group, or a halogen atom.

### <<<R¹³>>>

The alkoxy group in R¹³ is, for example, an alkoxy group having at least any one of linear, branched, and cyclic alkyl moieties having 1 to 20 carbon atoms.

Examples of the linear or branched alkoxy group include a methoxy group, an ethoxy group, an n-propoxy group, an i-propoxy group, an n-butoxy group, an i-butoxy group, an s-butoxy group, a t-butoxy group, an n-pentyloxy group, a 1-methyl-n-butoxy group, a 2-methyl-n-butoxy group, a 3-methyl-n-butoxy group, a 1,1-dimethyl-n-propoxy group, a 1,2-dimethyl-n-propoxy group, a 2,2-dimethyl-n-propoxy group, a 1-ethyl-n-propoxy group, an n-hexyloxy group, a 1-methyl-n-pentyloxy group, a 2-methyl-n-pentyloxy group, a 3-methyl-n-pentyloxy group, a 4-methyl-n-pentyloxy group, a 1,1-dimethyl-n-butoxy group, a 1,2-dimethyl-n-butoxy group, a 1,3-dimethyl-n-butoxy group, a 2,2-dimethyl-n-butoxy group, a 2,3-dimethyl-n-butoxy group, a 3,3-dimethyl-n-butoxy group, a 1-ethyl-n-butoxy group, a 2-ethyl-n-butoxy group, a 1,1,2-trimethyl-n-propoxy group, a 1,2,2-trimethyl-n-propoxy group, a 1-ethyl-1-methyl-n-propoxy group, and a 1-ethyl-2-methyl-n-propoxy group.

Examples of the cyclic alkoxy group include a cyclopropoxy group, a cyclobutoxy group, a 1-methyl-cyclopropoxy group, a 2-methyl-cyclopropoxy group, a cyclopentyloxy group, a 1-methyl-cyclobutoxy group, a 2-methyl-cyclobutoxy group, a 3-methyl-cyclobutoxy group, a 1,2-dimethyl-cyclopropoxy group, a 2,3-dimethyl-cyclopropoxy group, a 1-ethyl-cyclopropoxy group, a 2-ethyl-cyclopropoxy group, a cyclohexyloxy group, a 1-methyl-cyclopentyloxy group, a 2-methyl-cyclopentyloxy group, a 3-methyl-cyclopentyloxy group, a 1-ethyl-cyclobutoxy group, a 2-ethyl-cyclobutoxy group, a 3-ethyl-cyclobutoxy group, a 1,2-dimethyl-cyclobutoxy group, a 1,3-dimethyl-cyclobutoxy group, a 2,2-dimethyl-cyclobutoxy group, a 2,3-dimethyl-cyclobutoxy group, a 2,4-dimethyl-cyclobutoxy group, a 3,3-dimethyl-cyclobutoxy group, a 1-n-propyl-cyclopropoxy group, a 2-n-propyl-cyclopropoxy group, a 1-i-propyl-cyclopropoxy group, a 2-i-propyl-cyclopropoxy group, a 1,2,2-trimethyl-cyclopropoxy group, a 1,2,3-trimethyl-cyclopropoxy group, a 2,2,3-trimethyl-cyclopropoxy group, a 1-ethyl-2-methyl-cyclopropoxy group, a 2-ethyl-1-methyl-cyclopropoxy group, a 2-ethyl-2-methyl-cyclopropoxy group, and a 2-ethyl-3-methyl-cyclopropoxy group.

Examples of the halogen atom in R¹³ include a fluorine atom, a chlorine atom, a bromine atom, and an iodine atom.

The aralkyloxy group is a monovalent group derived by removing a hydrogen atom from a hydroxy group of aralkyl alcohol.

The aralkyl group in the aralkyloxy group is an alkyl group substituted with an aryl group.

Here, the aryl group may be any of a phenyl group, a monovalent group derived by removing one hydrogen atom of the condensed cyclic aromatic hydrocarbon compound, and a monovalent group derived by removing one hydrogen atom of the ring-linked aromatic hydrocarbon compound, and the alkyl group may be linear, branched, or cyclic.

The number of carbon atoms of the aralkyloxy group is not particularly limited, but may be, for example, 40 or less, preferably 30 or less, and more preferably 20 or less.

Specific examples of the aralkyloxy group include, but are not limited to, a phenylmethyloxy group (benzyloxy group), 2-phenylethyleneoxy group, 3-phenyl-n-propyloxy group, 4-phenyl-n-butyloxy group, 5-phenyl-n-pentyloxy group, 6-phenyl n-hexyloxy group, 7-phenyl-n-heptyloxy group, 8-phenyl-n-octyloxy group, 9-phenyl-n-nonyloxy group, and 10-phenyl-n-decyloxy group.

The acyloxy group is a monovalent group derived by removing a hydrogen atom from a carboxyl group (—COOH) of a carboxylic acid compound, and examples of the acyloxy group typically include, but are not limited to, an alkylcarbonyloxy group, an arylcarbonyloxy group, or an aralkylcarbonyloxy group, derived by removing a hydrogen atom from a carboxyl group of an alkyl carboxylic acid, an aryl carboxylic acid, or an aralkyl carboxylic acid. The alkyl group, aryl group, and aralkyl group in such alkyl carboxylic acids, aryl carboxylic acids, and aralkyl carboxylic acids will be described in detail in the section for R¹² in Formula (1) described later (<<R¹²>>>).

Specific examples of the acyloxy group include an acyloxy group having 2 to 20 carbon atoms, and examples thereof include a methylcarbonyloxy group, an ethylcarbonyloxy group, an n-propylcarbonyloxy group, an i-propylcarbonyloxy group, an n-butylcarbonyloxy group, an i-butylcarbonyloxy group, an s-butylcarbonyloxy group, a t-butylcarbonyloxy group, an n-pentylcarbonyloxy group, a 1-methyl-n-butylcarbonyloxy group, a 2-methyl-n-butylcarbonyloxy group, a 3-methyl-n-butylcarbonyloxy group, a 1,1-dimethyl-n-propylcarbonyloxy group, a 1,2-dimethyl-n-propylcarbonyloxy group, a 2,2-dimethyl-n-propylcarbonyloxy group, a 1-ethyl-n-propylcarbonyloxy group, an n-hexylcarbonyloxy group, a 1-methyl-n-pentylcarbonyloxy group, a 2-methyl-n-pentylcarbonyloxy group, a 3-methyl-n-pentylcarbonyloxy group, a 4-methyl-n-pentylcarbonyloxy group, a 1,1-dimethyl-n-butylcarbonyloxy group, a 1,2-dimethyl-n-butylcarbonyloxy group, a 1,3-dimethyl-n-butylcarbonyloxy group, a 2,2-dimethyl-n-butylcarbonyloxy group, a 2,3-dimethyl-n-butylcarbonyloxy group, a 3,3-dimethyl-n-butylcarbonyloxy group, a 1-ethyl-n-butylcarbonyloxy group, a 2-ethyl-n-butylcarbonyloxy group, a 1,1,2-trimethyl-n-propylcarbonyloxy group, a 1,2,2-trimethyl-n-propylcarbonyloxy group, a 1-ethyl-1-methyl-n-propylcarbonyloxy group, a 1-ethyl-2-methyl-n-propylcarbonyloxy group, a phenylcarbonyloxy group, and a tosylcarbonyloxy group.

Specific examples of the hydrolyzable silane represented by Formula (1-1) include tetramethoxysilane, tetrachlorosilane, tetraacetoxysilane, tetraethoxysilane, tetra-n-propoxysilane, tetraisopropoxysilane, and tetra-n-butoxysilane.

The content ratio of the hydrolyzable silane represented by Formula (1-1) in the hydrolyzable silane mixture is preferably more than 0 mol % and 30 mol % or less with respect to 100 mol % of the hydrolyzable silane contained in the hydrolyzable silane mixture.

By suppressing the content of the hydrolyzable silane of the tetrafunctional monomer represented by Formula (1-1) within the above range, the solubility of the silicon-containing resist underlayer film in an alkaline chemical solution (basic chemical solution) can be further improved.

### <<Silane Compound Represented by Formula (2) (Hydrolyzable Silane)>>

The hydrolyzable silane mixture according to the present invention contains a hydrolyzable silane represented by a specific structural formula of the following Formula (2).

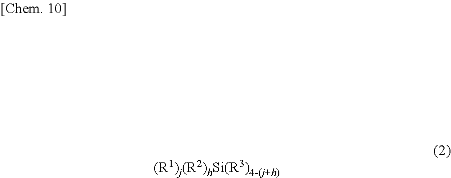

In Formula (2),
R¹ is a group bonded to a silicon atom, and represents an organic group containing a succinic anhydride skeleton,
R² is a group bonded to a silicon atom, and each independently represents an optionally substituted alkyl group, an optionally substituted halogenated alkyl group, or an optionally substituted alkoxyalkyl group, or represents an organic group containing an epoxy group, an acryloyl group, a methacryloyl group, a mercapto group, an amino group, an amide group, an alkoxy group, a sulfonyl group, or a cyano group, or a combination of two or more thereof,
R³ is a group or an atom bonded to a silicon atom, and each independently represents an alkoxy group, an aralkyloxy group, an acyloxy group, or a halogen atom,
j represents 1, h represents an integer of 0 to 2, and 4-(j+h) represents an integer of 1 to 3.

### <<<R¹>>>

R¹ is a group bonded to a silicon atom, and represents an organic group containing a succinic anhydride skeleton.

Examples of the organic group containing a succinic anhydride skeleton include not only the skeleton itself but also an organic group in which one or more hydrogen atoms in the alkyl group are substituted with a succinic anhydride skeleton.

The alkyl group in which a hydrogen atom is substituted by the succinic anhydride skeleton or the like is not particularly limited, and may be linear, branched, or cyclic, and the number of carbon atoms thereof can be usually 40 or less, for example, 30 or less, more preferably 20 or less, or 10 or less.

Specific examples of the linear or branched alkyl group and the cyclic alkyl group will be described in detail in the section of <<<R²>>> described later.

Examples of the organic group containing a succinic anhydride skeleton of R¹ include a monovalent group represented by the following Formula (A2).

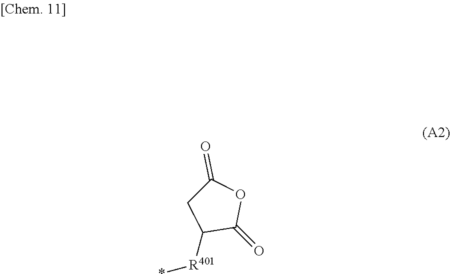

R⁴⁰¹ represents, for example, an alkylene group which is a divalent group derived by removing one hydrogen atom from the above-described linear, branched, or cyclic alkyl group. * represents a bond bonded to a silicon atom.

### <<<R²>>>

In Formula (2), R² is a group bonded to a silicon atom, and each independently represents an optionally substituted alkyl group, an optionally substituted halogenated alkyl group, or an optionally substituted alkoxyalkyl group, or represents an organic group containing an epoxy group, an acryloyl group, a methacryloyl group, a mercapto group, an amino group, an amide group, an alkoxy group, a sulfonyl group, or a cyano group, or a combination of two or more thereof.

The alkyl group may be linear, branched, or cyclic, and the number of carbon atoms thereof is not particularly limited, but is preferably 40 or less, more preferably 30 or less, still more preferably 20 or less, and yet still more preferably 10 or less.

Specific examples of the linear or branched alkyl group as the alkyl group include a methyl group, an ethyl group, an n-propyl group, an i-propyl group, an n-butyl group, an i-butyl group, an s-butyl group, a t-butyl group, an n-pentyl group, a 1-methyl-n-butyl group, a 2-methyl-n-butyl group, a 3-methyl-n-butyl group, a 1,1-dimethyl-n-propyl group, a 1,2-dimethyl-n-propyl group, a 2,2-dimethyl-n-propyl group, a 1-ethyl-n-propyl group, an n-hexyl group, a 1-methyl-n-pentyl group, a 2-methyl-n-pentyl group, a 3-methyl-n-pentyl group, a 4-methyl-n-pentyl group, a 1,1-dimethyl-n-butyl group, a 1,2-dimethyl-n-butyl group, a 1,3-dimethyl-n-butyl group, a 2,2-dimethyl-n-butyl group, a 2,3-dimethyl-n-butyl group, a 3,3-dimethyl-n-butyl group, a 1-ethyl-n-butyl group, a 2-ethyl-n-butyl group, a 1,1,2-trimethyl-n-propyl group, a 1,2,2-trimethyl-n-propyl group, a 1-ethyl-1-methyl-n-propyl group, and a 1-ethyl-2-methyl-n-propyl group.

In the present specification, “i” means “iso”, “s” means “sec”, and “t” means “tert”.

Specific examples of the cyclic alkyl group include: cyclic alkyl groups such as a cyclopropyl group, a cyclobutyl group, a 1-methyl-cyclopropyl group, a 2-methyl-cyclopropyl group, a cyclopentyl group, a 1-methyl-cyclobutyl group, a 2-methyl-cyclobutyl group, a 3-methyl-cyclobutyl group, a 1,2-dimethyl-cyclopropyl group, a 2,3-dimethyl-cyclopropyl group, a 1-ethyl-cyclopropyl group, a 2-ethyl-cyclopropyl group, a cyclohexyl group, a 1-methyl-cyclopentyl group, a 2-methyl-cyclopentyl group, a 3-methyl-cyclopentyl group, a 1-ethyl-cyclobutyl group, a 2-ethyl-cyclobutyl group, a 3-ethyl-cyclobutyl group, a 1,2-dimethyl-cyclobutyl group, a 1,3-dimethyl-cyclobutyl group, a 2,2-dimethyl-cyclobutyl group, a 2,3-dimethyl-cyclobutyl group, a 2,4-dimethyl-cyclobutyl group, a 3,3-dimethyl-cyclobutyl group, a 1-n-propyl-cyclopropyl group, a 2-n-propyl-cyclopropyl group, a 1-i-propyl-cyclopropyl group, a 2-i-propyl-cyclopropyl group, a 1,2,2-trimethyl-cyclopropyl group, a 1,2,3-trimethyl-cyclopropyl group, a 2,2,3-trimethyl-cyclopropyl group, a 1-ethyl-2-methyl-cyclopropyl group, a 2-ethyl-1-methyl-cyclopropyl group, a 2-ethyl-2-methyl-cyclopropyl group, and a 2-ethyl-3-methyl-cyclopropyl group; and crosslinked cyclic cycloalkyl groups, such as a bicyclobutyl group, a bicyclopentyl group, a bicyclohexyl group, a bicycloheptyl group, a bicyclooctyl group, a bicyclononyl group, and a bicyclodecyl group.

The halogenated alkyl group is an alkyl group substituted with one or more halogen atoms, and specific examples of the alkyl group are the same as those described above.

Examples of the halogen atom include fluorine atom, chlorine atom, bromine atom, and iodine atom.

The number of carbon atoms of the halogenated alkyl group is not particularly limited, but is preferably 40 or less, more preferably 30 or less, still more preferably 20 or less, and yet still more preferably 10 or less.

Specific examples of the halogenated alkyl group include, but are not limited to, a monofluoromethyl group, a difluoromethyl group, a trifluoromethyl group, a bromodifluoromethyl group, a 2-chloroethyl group, a 2-bromoethyl group, a 1,1-difluoroethyl group, a 2,2,2-trifluoroethyl group, a 1,1,2,2-tetrafluoroethyl group, a 2-chloro-1,1,2-trifluoroethyl group, a pentafluoroethyl group, a 3-bromopropyl group, a 2,2,3,3-tetrafluoropropyl group, a 1,1,2,3,3,3-hexafluoropropyl group, a 1,1,1,3,3,3-hexafluoropropane-2-yl group, a 3-bromo-2-methylpropyl group, a 4-bromobutyl group, and a perfluoropentyl group.

The alkoxyalkyl group is an alkyl group substituted with one or more alkoxy groups, and specific examples of the alkyl group are the same as those described above.

The alkoxy group as the substituent is, for example, an alkoxy group having at least any one of linear, branched, and cyclic alkyl moieties having 1 to 20 carbon atoms.

Examples of the linear or branched alkoxy group include a methoxy group, an ethoxy group, an n-propoxy group, an i-propoxy group, an n-butoxy group, an i-butoxy group, an s-butoxy group, a t-butoxy group, an n-pentyloxy group, a 1-methyl-n-butoxy group, a 2-methyl-n-butoxy group, a 3-methyl-n-butoxy group, a 1,1-dimethyl-n-propoxy group, a 1,2-dimethyl-n-propoxy group, a 2,2-dimethyl-n-propoxy group, a 1-ethyl-n-propoxy group, an n-hexyloxy group, a 1-methyl-n-pentyloxy group, a 2-methyl-n-pentyloxy group, a 3-methyl-n-pentyloxy group, a 4-methyl-n-pentyloxy group, a 1,1-dimethyl-n-butoxy group, a 1,2-dimethyl-n-butoxy group, a 1,3-dimethyl-n-butoxy group, a 2,2-dimethyl-n-butoxy group, a 2,3-dimethyl-n-butoxy group, a 3,3-dimethyl-n-butoxy group, a 1-ethyl-n-butoxy group, a 2-ethyl-n-butoxy group, a 1,1,2-trimethyl-n-propoxy group, a 1,2,2-trimethyl-n-propoxy group, a 1-ethyl-1-methyl-n-propoxy group, and a 1-ethyl-2-methyl-n-propoxy group.

Examples of the cyclic alkoxy group include a cyclopropoxy group, a cyclobutoxy group, a 1-methyl-cyclopropoxy group, a 2-methyl-cyclopropoxy group, a cyclopentyloxy group, a 1-methyl-cyclobutoxy group, a 2-methyl-cyclobutoxy group, a 3-methyl-cyclobutoxy group, a 1,2-dimethyl-cyclopropoxy group, a 2,3-dimethyl-cyclopropoxy group, a 1-ethyl-cyclopropoxy group, a 2-ethyl-cyclopropoxy group, a cyclohexyloxy group, a 1-methyl-cyclopentyloxy group, a 2-methyl-cyclopentyloxy group, a 3-methyl-cyclopentyloxy group, a 1-ethyl-cyclobutoxy group, a 2-ethyl-cyclobutoxy group, a 3-ethyl-cyclobutoxy group, a 1,2-dimethyl-cyclobutoxy group, a 1,3-dimethyl-cyclobutoxy group, a 2,2-dimethyl-cyclobutoxy group, a 2,3-dimethyl-cyclobutoxy group, a 2,4-dimethyl-cyclobutoxy group, a 3,3-dimethyl-cyclobutoxy group, a 1-n-propyl-cyclopropoxy group, a 2-n-propyl-cyclopropoxy group, a 1-i-propyl-cyclopropoxy group, a 2-i-propyl-cyclopropoxy group, a 1,2,2-trimethyl-cyclopropoxy group, a 1,2,3-trimethyl-cyclopropoxy group, a 2,2,3-trimethyl-cyclopropoxy group, a 1-ethyl-2-methyl-cyclopropoxy group, a 2-ethyl-1-methyl-cyclopropoxy group, a 2-ethyl-2-methyl-cyclopropoxy group, and a 2-ethyl-3-methyl-cyclopropoxy group.

Specific examples of the alkoxyalkyl group include, but are not limited to, lower (about 5 or less carbon atoms) alkyloxy lower (about 5 or less carbon atoms) alkyl groups, such as a methoxymethyl group, an ethoxymethyl group, a 1-ethoxyethyl group, a 2-ethoxyethyl group, and an ethoxymethyl group.

Examples of the substituent in the above-described alkyl group, halogenated alkyl group, and alkoxyalkyl group include an alkyl group, an aryl group, an aralkyl group, a halogenated alkyl group, a halogenated aryl group, a halogenated aralkyl group, an alkoxyalkyl group, an aryloxy group, an alkoxyaryl group, an alkoxyaralkyl group, an alkenyl group, an alkoxy group, and an aralkyloxy group. Specific examples and the suitable numbers of carbon atoms for these groups are the same as those described above or below.

The aryloxy group mentioned in the substituent is a group in which an aryl group is bonded via an oxygen atom (—O—). The number of carbon atoms in the aryloxy group is not particularly limited, but is preferably 40 or less, more preferably 30 or less, and still more preferably 20 or less. Specific examples thereof include, but are not limited to, a phenoxy group and a naphthalene-2-yloxy group.

When two or more substituents are present, the substituents may be bonded together to form a ring.

Examples of the organic group having an epoxy group include a glycidoxymethyl group, a glycidoxyethyl group, a glycidoxypropyl group, a glycidoxybutyl group, and an epoxycyclohexyl group.

Examples of the organic group having an acryloyl group include an acryloyl methyl group, an acryloyl ethyl group, and an acryloyl propyl group.

Examples of the organic group having a methacryloyl group include a methacryloyl methyl group, a methacryloyl ethyl group, and a methacryloyl propyl group.

Examples of the organic group having a mercapto group include a mercaptoethyl group, a mercaptobutyl group, a mercaptohexyl group, a mercaptooctyl group, and a mercaptophenyl group.

Examples of the organic group having an amino group include, but are not limited to, an amino group, an aminomethyl group, an aminoethyl group, an aminophenyl, a dimethylaminoethyl group, and a dimethylaminopropyl group. The organic group having an amino group will be described later in more detail.

Examples of the organic group having an amide group include an amide group-containing aliphatic hydrocarbon group, an amide group-containing alicyclic hydrocarbon group, and an amide group-containing aromatic hydrocarbon group.

Examples of the organic group having an alkoxy group include, but are not limited to, a methoxymethyl group and a methoxyethyl group. However, the organic group excludes a group in which an alkoxy group is directly bonded to a silicon atom.

Examples of the organic group having a sulfonyl group include, but are not limited to, a sulfonylalkyl group and a sulfonylaryl group.

Examples of the organic group having a cyano group include a cyanoethyl group, a cyanopropyl group, a cyanophenyl group, and a thiocyanate group.

Examples of the organic group having an amino group include an organic group having at least one of a primary amino group, a secondary amino group, and a tertiary amino group. A hydrolysis-condensation compound in which a hydrolyzable silane having a tertiary amino group is hydrolyzed with a strong acid to form a counter cation having a tertiary ammonium group can be preferably used. In addition, the organic group may contain a hetero atom such as an oxygen atom or a sulfur atom in addition to the nitrogen atom constituting the amino group.

Preferable examples of the organic group having an amino group include a group represented by the following Formula (A1).

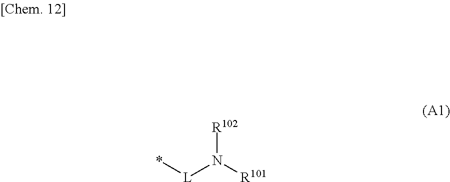

In Formula (A1), R¹⁰¹ and R¹⁰² each independently represent a hydrogen atom or a hydrocarbon group, and L each independently represents an optionally substituted alkylene group. * represents a bond.

Examples of the hydrocarbon group include, but are not limited to, an alkyl group, an alkenyl group, and an aryl group.

The alkylene group may be linear or branched, and the number of carbon atoms of the linear or branched alkylene group is ordinarily 1 to 10, and preferably 1 to 5. Examples of the linear or branched alkylene group include linear alkylene groups such as a methylene group, an ethylene group, a trimethylene group, a tetramethylene group, a pentamethylene group, a hexamethylene group, a heptamethylene group, an octamethylene group, a nonamethylene group, and a decamethylene group.

Examples of the organic group having an amino group include, but are not limited to, an amino group, an aminomethyl group, an aminoethyl group, an aminophenyl, a dimethylaminoethyl group, and a dimethylaminopropyl group.

### <<<R³>>>

In Formula (2), R³ is a group or an atom bonded to a silicon atom, and each independently represents an alkoxy group, an aralkyloxy group, an acyloxy group, or a halogen atom.

The alkoxy group, the aralkyloxy group, the acyloxy group, or the halogen atom in R³ of Formula (2) is as described in the section of <<<R¹³>>> of the above Formula (1-1).

In the above Formula (2), j represents 1, h represents an integer of 0 to 2, and 4-(j+h) represents an integer of 1 to 3.

Specific examples of the hydrolyzable silane represented by Formula (2) include silane compounds containing a succinic anhydride skeleton such as [(3-trimethoxysilyl)propyl]succinic anhydride, [(3-triethoxysilyl)propyl]succinic anhydride, [(3-trimethoxysilyl)ethyl]succinic anhydride, and [(3-trimethoxysilyl)butyl]succinic anhydride.

When a hydrolyzable silane of a tetrafunctional monomer represented by Formula (1-1) and a hydrolyzable silane represented by a specific structural formula having an organic acid containing a succinic anhydride skeleton represented by Formula (2) are contained in the hydrolyzable silane mixture for forming a hydrolysis-condensation compound contained in a silicon-containing resist underlayer film-forming composition, it is possible to improve the crosslinking density of the silicon-containing resist underlayer film obtained from the silicon-containing resist underlayer film-forming composition, suppress the diffusion of components of the resist film into the silicon-containing resist underlayer film and the like, ensure the maintenance and improvement of the properties of the resist film, and exhibit excellent solubility of the silicon-containing resist underlayer film in an alkaline chemical solution (basic chemical solution).

When the hydrolyzable silane of the tetrafunctional monomer represented by Formula (1-1) and the hydrolyzable silane represented by the specific structural formula having an organic acid containing a succinic anhydride skeleton represented by Formula (2) are contained, it is possible to reduce the peak intensity value of the siloxane bond of the silicon-containing resist underlayer film formed from the silicon-containing resist underlayer film-forming composition containing a hydrolysis-condensation compound of a hydrolyzable silane mixture containing these hydrolyzable silanes (refer to the results of Examples described later). The decrease in the peak intensity value of the siloxane bond in the silicon-containing resist underlayer film is considered to effectively act to improve the solubility of the silicon-containing resist underlayer film in a chemical solution.

### <<Silane Compound Represented By Formula (1) (Hydrolyzable Silane)>>

The hydrolysis-condensation compound contained in the silicon-containing resist underlayer film-forming composition of the present invention can be a product of hydrolysis condensation of a hydrolyzable silane mixture containing a silane compound represented by the following Formula (1).

The hydrolyzable silane mixture according to the present invention may contain a hydrolyzable silane represented by the following Formula (1) in addition to the hydrolyzable silane of a tetrafunctional monomer represented by Formula (1-1) and the hydrolyzable silane having an organic acid containing a succinic anhydride skeleton represented by Formula (2).

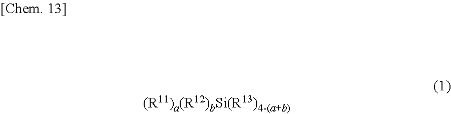

In Formula (1), R¹¹ is a group bonded to a silicon atom, and each independently represents a monovalent group represented by the following Formula (2a) or a monovalent group represented by the following Formula (2b).
R¹² is a group bonded to a silicon atom, and each independently represents an optionally substituted alkyl group, an optionally substituted aryl group, an optionally substituted aralkyl group, an optionally substituted halogenated alkyl group, an optionally substituted halogenated aryl group, an optionally substituted halogenated aralkyl group, an optionally substituted alkoxyalkyl group, an optionally substituted alkoxyaryl group, an optionally substituted alkoxyaralkyl group, or an optionally substituted alkenyl group, or represents an organic group having an epoxy group, an acryloyl group, a methacryloyl group, a mercapto group, an amino group, an alkoxy group, a sulfonyl group, or a cyano group, or a combination of two or more thereof.
R¹³ is a group or an atom bonded to a silicon atom, and each independently represents a hydroxy group, an alkoxy group, an aralkyloxy group, an acyloxy group, or a halogen atom.
a represents an integer of 0 to 2, b represents an integer of 0 to 2, and 4-(a+b) represents an integer of 1 to 3.

### <<<R¹¹>>>

R¹¹ is a group bonded to a silicon atom, and each independently represents a monovalent group represented by the following Formula (2a) or a monovalent group represented by the following Formula (2b).

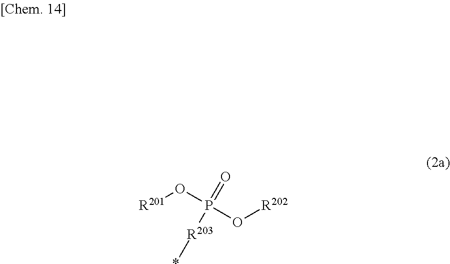

In Formula (2a), R²⁰¹ to R²⁰² each independently represent a hydrogen atom or an organic group containing an optionally substituted alkyl group, R²⁰³ represents an optionally substituted alkylene group, and * represents a bond bonded to a silicon atom.

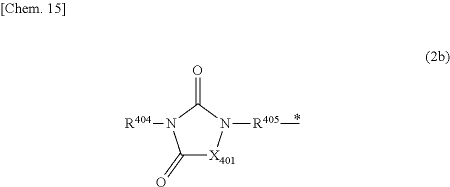

In Formula (2b), R⁴⁰⁴ each independently represents a hydrogen atom, an optionally substituted alkyl group, an optionally substituted alkenyl group, or an organic group having an epoxy group or an organic group having a sulfonyl group, and R⁴⁰⁵ each independently represents an alkylene group, a hydroxyalkylene group, a sulfide bond (—S—), an ether bond (—O—), or an ester bond (—CO—O— or —O—CO—). * represents a bond.
X⁴⁰¹ each independently represents any one of groups represented by the following Formulas (4-3) to (4-5), and a carbon atom of a ketone group in the following Formulas (4-4) and (4-5) is bonded to a nitrogen atom to which R⁴⁰⁵ in Formula (2b) is bonded.

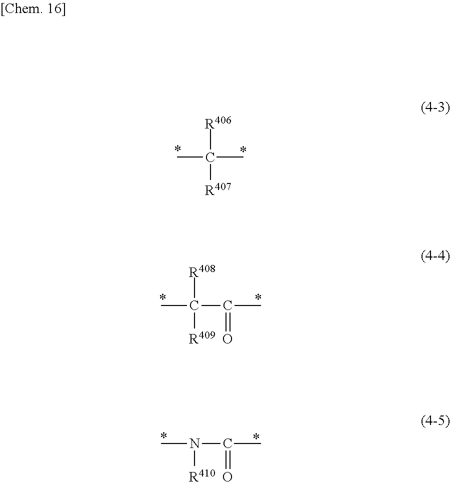

In Formulas (4-3) to (4-5), R⁴⁰⁶ to R⁴¹⁰ each independently represents a hydrogen atom, an optionally substituted alkyl group, an optionally substituted alkenyl group, or an organic group having an epoxy group or a sulfonyl group. * represents a bond.

—Case where R¹¹ is Monovalent Group Represented by Formula (2a)—

In Formula (2a), R²⁰¹ to R²⁰² each independently represent a hydrogen atom or an organic group containing an optionally substituted alkyl group, R²⁰³ represents an optionally substituted alkylene group, and * represents a bond bonded to a silicon atom.

In Formula (1), in the monovalent group represented by Formula (2a) of R¹¹, the optionally substituted alkyl group is as described in the section of <<<R²>>> in Formula (2).

Examples of the organic group containing an optionally substituted alkyl group include an optionally substituted alkyl group.

In Formula (1), the optionally substituted alkylene group in the monovalent group represented by Formula (2a) in R¹¹ refers to a divalent group derived by further removing one hydrogen atom from the optionally substituted alkyl group. The optionally substituted alkylene group may be linear, branched, or cyclic.

Specific examples of the alkylene group include, but are not limited to, linear alkylene groups such as a methylene group, an ethylene group, a trimethylene group, a methyleneethyl group, a tetramethylene group, a pentamethylene group, a hexamethylene group, a heptamethylene group, an octamethylene group, a nonamethylene group and a decamethylene group; branched alkylene groups such as a 1-methyltrimethylene group, a 2-methyltrimethylene group, a 1,1-dimethylethylene group, a 1-methyltetramethylene group, a 2-methyltetramethylene group, a 1,1-dimethyltrimethylene group, a 1,2-dimethyltrimethylene group, a 2,2-dimethyltrimethylene group, and a 1-ethyltrimethylene group; cyclic alkylene groups such as a 1,2-cyclopropanediyl group, a 1,2-cyclobutanediyl group, a 1,3-cyclobutanediyl group, a 1,2-cyclohexanediyl group and a 1,3-cyclohexanediyl group; and ether groups such as —CH₂OCH₂—, —CH₂CH₂OCH₂—, —CH₂CH₂OCH₂CH₂—, —CH₂CH₂CH₂OCH₂CH₂—, —CH₂CH₂OCH₂CH₂CH₂—, —CH₂CH₂CH₂OCH₂CH₂CH₂—, —CH₂SCH₂—, —CH₂CH₂SCH₂—, —CH₂CH₂SCH₂CH₂—, —CH₂CH₂CH₂SCH₂CH₂—, —CH₂CH₂SCH₂CH₂CH₂—, —CH₂CH₂CH₂SCH₂CH₂CH₂—, and —CH₂OCH₂CH₂SCH₂—.

—Case where R¹¹ is Monovalent Group Represented by Formula (2b)—

Specific examples, the suitable numbers of carbon atoms, and the like of the organic group having an optionally substituted alkyl group, an optionally substituted alkenyl group, and an epoxy group of R⁴⁰⁴ in

Formula (2b), will be described in detail in the section of <<<R¹²>>> described later.

In addition to those described in the section of <<<R¹²>>>, as the optionally substituted alkyl group of R⁴⁰⁴, an alkyl group in which a terminal hydrogen atom is substituted with a vinyl group is preferable, and specific examples thereof include an allyl group, a 2-vinylethyl group, a 3-vinylpropyl group, and a 4-vinylbutyl group.

The organic group having a sulfonyl group of R⁴⁰⁴ is not particularly limited as long as a sulfonyl group is contained, and examples thereof include an optionally substituted alkylsulfonyl group, an optionally substituted arylsulfonyl group, an optionally substituted aralkylsulfonyl group, an optionally substituted halogenated alkylsulfonyl group, an optionally substituted halogenated arylsulfonyl group, an optionally substituted halogenated aralkylsulfonyl group, an optionally substituted alkoxyalkylsulfonyl group, an optionally substituted alkoxyarylsulfonyl group, an optionally substituted alkoxyaralkylsulfonyl group, and an optionally substituted alkenylsulfonyl group.

Specific examples, the suitable numbers of carbon atoms, and the like of alkyl group, aryl group, aralkyl group, halogenated alkyl group, halogenated aryl group, halogenated aralkyl group, alkoxyalkyl group, alkoxyaryl group, alkoxyaralkyl group, and alkenyl group in these groups, as well as substituents thereof will be described in detail in the section of <<<R¹²>>> described later.

The alkylene group of R⁴⁰⁵ is a divalent group derived by further removing one hydrogen atom from the alkyl group, and may be linear, branched, or cyclic. Specific examples of the alkylene group are the same as those described above. The number of carbon atoms of the alkylene group is not particularly limited, but is preferably 40 or less, more preferably 30 or less, still more preferably 20 or less, and yet still more preferably 10 or less.

In addition, the alkylene group of R⁴⁰⁵ may have one or more types of bonds selected from a sulfide bond, an ether bond, and an ester bond at terminal ends or in the middle, and preferably in the middle.

Specific examples of the alkylene group include, but are not limited to, linear alkylene groups such as a methylene group, an ethylene group, a trimethylene group, a tetramethylene group, a pentamethylene group, a hexamethylene group, a heptamethylene group, an octamethylene group, a nonamethylene group, and a decamethylene group; branched alkylene groups such as a methylethylene group, a 1-methyltrimethylene group, a 2-methyltrimethylene group, a 1,1-dimethylethylene group, a 1-methyltetramethylene group, a 2-methyltetramethylene group, a 1,1-dimethyltrimethylene group, a 1,2-dimethyltrimethylene group, a 2,2-dimethyltrimethylene group, and a 1-ethyltrimethylene group; cyclic alkylene groups such as a 1,2-cyclopropanediyl group, a 1,2-cyclobutanediyl group, a 1,3-cyclobutanediyl group, a 1,2-cyclohexanediyl group, and a 1,3-cyclohexanediyl group; and ether groups such as —CH₂OCH₂—, —CH₂CH₂OCH₂—, —CH₂CH₂OCH₂CH₂—, —CH₂CH₂CH₂OCH₂CH₂—, —CH₂CH₂OCH₂CH₂CH₂—, —CH₂CH₂CH₂OCH₂CH₂CH₂—, —CH₂SCH₂—, —CH₂CH₂SCH₂—, —CH₂CH₂SCH₂CH₂—, —CH₂CH₂CH₂SCH₂CH₂—, —CH₂CH₂SCH₂CH₂CH₂—, —CH₂CH₂CH₂SCH₂CH₂CH₂—, and —CH₂OCH₂CH₂SCH₂—.

The hydroxyalkylene group of R⁴⁰⁵ is a group in which at least one hydrogen atom of the above-described alkylene group is replaced with a hydroxy group. Specific examples of the hydroxyalkylene group include, but are not limited to, a hydroxymethylene group, a 1-hydroxyethylene group, a 2-hydroxyethylene group, a 1,2-dihydroxyethylene group, a 1-hydroxytrimethylene group, a 2-hydroxytrimethylene group, a 3-hydroxytrimethylene group, a 1-hydroxytetramethylene group, a 2-hydroxytetramethylene group, a 3-hydroxytetramethylene group, a 4-hydroxytetramethylene group, a 1,2-dihydroxytetramethylene group, a 1,3-dihydroxytetramethylene group, a 1,4-dihydroxytetramethylene group, a 2,3-dihydroxytetramethylene group, a 2,4-dihydroxytetramethylene group, and a 4,4-dihydroxytetramethylene group.

In Formula (2b), X₄₀₁ each independently represents any one of groups represented by the following Formulas (4-3) to (4-5), and a carbon atom of a ketone group in the following Formulas (4-4) and (4-5) is bonded to a nitrogen atom to which R⁴⁰⁵ in Formula (4-2) is bonded.

In Formulas (4-3) to (4-5), R⁴⁰⁶ to R⁴¹⁰ each independently represents a hydrogen atom, an optionally substituted alkyl group, an optionally substituted alkenyl group, or an organic group having an epoxy group or a sulfonyl group. Specific examples, the suitable numbers of carbon atoms, and the like of the organic group having an optionally substituted alkyl group, an optionally substituted alkenyl group, and an epoxy group or a sulfonyl group, will be described in detail in the section of <<<R¹²>>> described later.

Specific examples, the suitable numbers of carbon atoms, and the like of the organic group having a sulfonyl group are the same as those described above regarding R⁴⁰⁴. * represents a bond.

In Formulas, from the viewpoint of realizing excellent lithography characteristics with good reproducibility, X₄₀₁ is preferably a group represented by Formula (4-5).

From the viewpoint of realizing excellent lithography characteristics with good reproducibility, at least one of R⁴⁰⁴ and R⁴⁰⁶ to R⁴¹⁰ is preferably an alkyl group in which a terminal hydrogen atom is substituted with a vinyl group.

### <<<R¹²>>>

In Formula (1), R¹² is a group bonded to a silicon atom, and each independently represents an optionally substituted alkyl group, an optionally substituted aryl group, an optionally substituted aralkyl group, an optionally substituted halogenated alkyl group, an optionally substituted halogenated aryl group, an optionally substituted halogenated aralkyl group, an optionally substituted alkoxyalkyl group, an optionally substituted alkoxyaryl group, an optionally substituted alkoxyaralkyl group, or an optionally substituted alkenyl group, or an organic group having an epoxy group, an acryloyl group, a methacryloyl group, a mercapto group, an amino group, an alkoxy group, a sulfonyl group, or a cyano group, or a combination of two or more thereof.

The description of R¹² in Formula (1) partially overlaps with the description of R² in Formula (2) described above.

Although there is a portion, each group specified by R¹² will be described in detail below.

The alkyl group may be linear, branched, or cyclic, and the number of carbon atoms thereof is not particularly limited, but is preferably 40 or less, more preferably 30 or less, still more preferably 20 or less, and yet still more preferably 10 or less.

Specific examples of the linear or branched alkyl group as the alkyl group include a methyl group, an ethyl group, an n-propyl group, an i-propyl group, an n-butyl group, an i-butyl group, an s-butyl group, a t-butyl group, an n-pentyl group, a 1-methyl-n-butyl group, a 2-methyl-n-butyl group, a 3-methyl-n-butyl group, a 1,1-dimethyl-n-propyl group, a 1,2-dimethyl-n-propyl group, a 2,2-dimethyl-n-propyl group, a 1-ethyl-n-propyl group, an n-hexyl group, a 1-methyl-n-pentyl group, a 2-methyl-n-pentyl group, a 3-methyl-n-pentyl group, a 4-methyl-n-pentyl group, a 1,1-dimethyl-n-butyl group, a 1,2-dimethyl-n-butyl group, a 1,3-dimethyl-n-butyl group, a 2,2-dimethyl-n-butyl group, a 2,3-dimethyl-n-butyl group, a 3,3-dimethyl-n-butyl group, a 1-ethyl-n-butyl group, a 2-ethyl-n-butyl group, a 1,1,2-trimethyl-n-propyl group, a 1,2,2-trimethyl-n-propyl group, a 1-ethyl-1-methyl-n-propyl group, and a 1-ethyl-2-methyl-n-propyl group.

In the present specification, “i” means “iso”, “s” means “sec”, and “t” means “tert”.

Specific examples of the cyclic alkyl group include: cyclic alkyl groups such as a cyclopropyl group, a cyclobutyl group, a 1-methyl-cyclopropyl group, a 2-methyl-cyclopropyl group, a cyclopentyl group, a 1-methyl-cyclobutyl group, a 2-methyl-cyclobutyl group, a 3-methyl-cyclobutyl group, a 1,2-dimethyl-cyclopropyl group, a 2,3-dimethyl-cyclopropyl group, a 1-ethyl-cyclopropyl group, a 2-ethyl-cyclopropyl group, a cyclohexyl group, a 1-methyl-cyclopentyl group, a 2-methyl-cyclopentyl group, a 3-methyl-cyclopentyl group, a 1-ethyl-cyclobutyl group, a 2-ethyl-cyclobutyl group, a 3-ethyl-cyclobutyl group, a 1,2-dimethyl-cyclobutyl group, a 1,3-dimethyl-cyclobutyl group, a 2,2-dimethyl-cyclobutyl group, a 2,3-dimethyl-cyclobutyl group, a 2,4-dimethyl-cyclobutyl group, a 3,3-dimethyl-cyclobutyl group, a 1-n-propyl-cyclopropyl group, a 2-n-propyl-cyclopropyl group, a 1-i-propyl-cyclopropyl group, a 2-i-propyl-cyclopropyl group, a 1,2,2-trimethyl-cyclopropyl group, a 1,2,3-trimethyl-cyclopropyl group, a 2,2,3-trimethyl-cyclopropyl group, a 1-ethyl-2-methyl-cyclopropyl group, a 2-ethyl-1-methyl-cyclopropyl group, a 2-ethyl-2-methyl-cyclopropyl group, and a 2-ethyl-3-methyl-cyclopropyl group; and crosslinked cyclic cycloalkyl groups, such as a bicyclobutyl group, a bicyclopentyl group, a bicyclohexyl group, a bicycloheptyl group, a bicyclooctyl group, a bicyclononyl group, and a bicyclodecyl group.

The aryl group may be any of a phenyl group, a monovalent group derived by removing one hydrogen atom from a condensed cyclic aromatic hydrocarbon compound, and a monovalent group derived by removing one hydrogen atom from a ring-linked aromatic hydrocarbon compound. The number of carbon atoms of the aryl group is not particularly limited, but is preferably 40 or less, more preferably 30 or less, and still more preferably 20 or less.

Examples of the aryl group include an aryl group having 6 to 20 carbon atoms, and examples thereof include, but are not limited thereto, a phenyl group, a 1-naphthyl group, a 2-naphthyl group, a 1-anthryl group, a 2-anthryl group, a 9-anthryl group, a 1-phenanthryl group, a 2-phenanthryl group, a 3-phenanthryl group, a 4-phenanthryl group, a 9-phenanthryl group, a 1-naphthacenyl group, a 2-naphthacenyl group, a 5-naphthacenyl group, a 2-chrysenyl group, a 1-pyrenyl group, a 2-pyrenyl group, a pentacenyl group, a benzopyrenyl group, and a triphenylenyl group; a biphenyl-2-yl group (o-biphenylyl group), a biphenyl-3-yl group (m-biphenylyl group), a biphenyl-4-yl group (p-biphenylyl group), a paraterphenyl-4-yl group, a metaterphenyl-4-yl group, an orthoterphenyl-4-yl group, a 1,1′-binaphthyl-2-yl group, and a 2,2′-binaphthyl-1-yl group.

The aralkyl group is an alkyl group substituted with an aryl group, and specific examples of the aryl group and the alkyl group are the same as those described above. The number of carbon atoms of the aralkyl group is not particularly limited, but is preferably 40 or less, more preferably 30 or less, and still more preferably 20 or less.

Specific examples of the aralkyl group include, but are not limited thereto, a phenylmethyl group (benzyl group), a 2-phenylethylene group, a 3-phenyl-n-propyl group, a 4-phenyl-n-butyl group, a 5-phenyl-n-pentyl group, a 6-phenyl-n-hexyl group, a 7-phenyl-n-heptyl group, a 8-phenyl-n-octyl group, a 9-phenyl-n-nonyl group, and a 10 phenyl-n-decyl group.

The halogenated alkyl group, the halogenated aryl group, and the halogenated aralkyl group are an alkyl group substituted with one or more halogen atoms, an aryl group substituted with one or more halogen atoms, and an aralkyl group substituted with one or more halogen atoms, respectively. Specific examples of such alkyl group, aryl group, and alkyl group are the same as those described above.

Examples of the halogen atom include fluorine atom, chlorine atom, bromine atom, and iodine atom.

The number of carbon atoms of the halogenated alkyl group is not particularly limited, but is preferably 40 or less, more preferably 30 or less, still more preferably 20 or less, and yet still more preferably 10 or less.

Specific examples of the halogenated alkyl group include, but are not limited to, a monofluoromethyl group, a difluoromethyl group, a trifluoromethyl group, a bromodifluoromethyl group, a 2-chloroethyl group, a 2-bromoethyl group, a 1,1-difluoroethyl group, a 2,2,2-trifluoroethyl group, a 1,1,2,2-tetrafluoroethyl group, a 2-chloro-1,1,2-trifluoroethyl group, a pentafluoroethyl group, a 3-bromopropyl group, a 2,2,3,3-tetrafluoropropyl group, a 1,1,2,3,3,3-hexafluoropropyl group, a 1,1,1,3,3,3-hexafluoropropane-2-yl group, a 3-bromo-2-methylpropyl group, a 4-bromobutyl group, and a perfluoropentyl group.

The number of carbon atoms of the halogenated aryl group is not particularly limited, but is preferably 40 or less, more preferably 30 or less, and still more preferably 20 or less.

Specific examples of the halogenated aryl group include a 2-fluorophenyl group, a 3-fluorophenyl group, a 4-fluorophenyl group, a 2,3-difluorophenyl group, a 2,4-difluorophenyl group, a 2,5-difluorophenyl group, a 2,6-difluorophenyl group, a 3,4-difluorophenyl group, a 3,5-difluorophenyl group, a 2,3,4-trifluorophenyl group, a 2,3,5-trifluorophenyl group, a 2,3,6-trifluorophenyl group, a 2,4,5-trifluorophenyl group, a 2,4,6-trifluorophenyl group, a 3,4,5-trifluorophenyl group, a 2,3,4,5-tetrafluorophenyl group, a 2,3,4,6-tetrafluorophenyl group, a 2,3,5,6-tetrafluorophenyl group, a pentafluorophenyl group, a 2-fluoro-1-naphthyl group, a 3-fluoro-1-naphthyl group, a 4-fluoro-1-naphthyl group, a 6-fluoro-1-naphthyl group, a 7-fluoro-1-naphthyl group, a 8-fluoro-1-naphthyl group, a 4,5-difluoro-1-naphthyl group, a 5,7-difluoro-1-naphthyl group, a 5,8-difluoro-1-naphthyl group, a 5,6,7,8-tetrafluoro-1-naphthyl group, a heptafluoro-1-naphthyl group, a 1-fluoro-2-naphthyl group, a 5-fluoro-2-naphthyl group, a 6-fluoro-2-naphthyl group, a 7-fluoro-2-naphthyl group, 5,7-difluoro-2-naphthyl group, and a heptafluoro-2-naphthyl group. Examples thereof also include groups in which fluorine atoms (fluoro groups) in the above groups are optionally substituted with chlorine atoms (chloro groups), bromine atoms (bromo groups), or iodine atoms (iodine groups), but not limited thereto.

The number of carbon atoms of the halogenated aralkyl group is not particularly limited, but is preferably 40 or less, more preferably 30 or less, and still more preferably 20 or less.

Specific examples of the halogenated aralkyl group include a 2-fluorobenzyl group, a 3-fluorobenzyl group, a 4-fluorobenzyl group, a 2,3-difluorobenzyl group, a 2,4-difluorobenzyl group, a 2,5-difluorobenzyl group, a 2,6-difluorobenzyl group, a 3,4-difluorobenzyl group, a 3,5-difluorobenzyl group, a 2,3,4-trifluorobenzyl group, a 2,3,5-trifluorobenzyl group, a 2,3,6-trifluorobenzyl group, a 2,4,5-trifluorobenzyl group, a 2,4,6-trifluorobenzyl group, a 2,3,4,5-tetrafluorobenzyl group, a 2,3,4,6-tetrafluorobenzyl group, a 2,3,5,6-tetrafluorobenzyl group, and a 2,3,4,5,6-pentafluorobenzyl group. Examples thereof also include groups in which fluorine atoms (fluoro groups) in the above groups are optionally substituted with chlorine atoms (chloro groups), bromine atoms (bromo groups), or iodine atoms (iodine groups), but not limited thereto.

The alkoxyalkyl group, the alkoxyaryl group, and the alkoxyaralkyl group are an alkyl group substituted with one or more alkoxy groups, an aryl group substituted with one or more alkoxy groups, and an aralkyl group substituted with one or more alkoxy groups, respectively. Specific examples of such alkyl groups, aryl groups, and aralkyl groups are the same as those described above.

The alkoxy group as the substituent is, for example, an alkoxy group having at least any one of linear, branched, and cyclic alkyl moieties having 1 to 20 carbon atoms.

Examples of the linear or branched alkoxy group include a methoxy group, an ethoxy group, an n-propoxy group, an i-propoxy group, an n-butoxy group, an i-butoxy group, an s-butoxy group, a t-butoxy group, an n-pentyloxy group, a 1-methyl-n-butoxy group, a 2-methyl-n-butoxy group, a 3-methyl-n-butoxy group, a 1,1-dimethyl-n-propoxy group, a 1,2-dimethyl-n-propoxy group, a 2,2-dimethyl-n-propoxy group, a 1-ethyl-n-propoxy group, an n-hexyloxy group, a 1-methyl-n-pentyloxy group, a 2-methyl-n-pentyloxy group, a 3-methyl-n-pentyloxy group, a 4-methyl-n-pentyloxy group, a 1,1-dimethyl-n-butoxy group, a 1,2-dimethyl-n-butoxy group, a 1,3-dimethyl-n-butoxy group, a 2,2-dimethyl-n-butoxy group, a 2,3-dimethyl-n-butoxy group, a 3,3-dimethyl-n-butoxy group, a 1-ethyl-n-butoxy group, a 2-ethyl-n-butoxy group, a 1,1,2-trimethyl-n-propoxy group, a 1,2,2-trimethyl-n-propoxy group, a 1-ethyl-1-methyl-n-propoxy group, and a 1-ethyl-2-methyl-n-propoxy group.

Examples of the cyclic alkoxy group include a cyclopropoxy group, a cyclobutoxy group, a 1-methyl-cyclopropoxy group, a 2-methyl-cyclopropoxy group, a cyclopentyloxy group, a 1-methyl-cyclobutoxy group, a 2-methyl-cyclobutoxy group, a 3-methyl-cyclobutoxy group, a 1,2-dimethyl-cyclopropoxy group, a 2,3-dimethyl-cyclopropoxy group, a 1-ethyl-cyclopropoxy group, a 2-ethyl-cyclopropoxy group, a cyclohexyloxy group, a 1-methyl-cyclopentyloxy group, a 2-methyl-cyclopentyloxy group, a 3-methyl-cyclopentyloxy group, a 1-ethyl-cyclobutoxy group, a 2-ethyl-cyclobutoxy group, a 3-ethyl-cyclobutoxy group, a 1,2-dimethyl-cyclobutoxy group, a 1,3-dimethyl-cyclobutoxy group, a 2,2-dimethyl-cyclobutoxy group, a 2,3-dimethyl-cyclobutoxy group, a 2,4-dimethyl-cyclobutoxy group, a 3,3-dimethyl-cyclobutoxy group, a 1-n-propyl-cyclopropoxy group, a 2-n-propyl-cyclopropoxy group, a 1-i-propyl-cyclopropoxy group, a 2-i-propyl-cyclopropoxy group, a 1,2,2-trimethyl-cyclopropoxy group, a 1,2,3-trimethyl-cyclopropoxy group, a 2,2,3-trimethyl-cyclopropoxy group, a 1-ethyl-2-methyl-cyclopropoxy group, a 2-ethyl-1-methyl-cyclopropoxy group, a 2-ethyl-2-methyl-cyclopropoxy group, and a 2-ethyl-3-methyl-cyclopropoxy group.

Specific examples of the alkoxyalkyl group include, but are not limited to, lower (about 5 or less carbon atoms) alkyloxy lower (about 5 or less carbon atoms) alkyl groups, such as a methoxymethyl group, an ethoxymethyl group, a 1-ethoxyethyl group, a 2-ethoxyethyl group, and an ethoxymethyl group.

Specific examples of the alkoxyaryl group include, but are not limited to, a 2-methoxyphenyl group, a 3-methoxyphenyl group, a 4-methoxyphenyl group, a 2-(1-ethoxy)phenyl group, a 3-(1-ethoxy)phenyl group, a 4-(1-ethoxy)phenyl group, a 2-(2-ethoxy)phenyl group, a 3-(2-ethoxy)phenyl group, a 4-(2-ethoxy)phenyl group, a 2-methoxynaphthalene-1-yl group, a 3-methoxynaphthalene-1-yl group, a 4-methoxynaphthalene-1-yl group, a 5-methoxynaphthalene-1-yl group, a 6-methoxynaphthalene-1-yl group, and a 7-methoxynaphthalene-1-yl group.

Specific examples of the alkoxyaralkyl group include, but are not limited to, a 3-(methoxyphenyl)benzyl group and a 4-(methoxyphenyl)benzyl group.

The alkenyl group may be linear or branched, and the number of carbon atoms of the linear or branched alkenyl group is not particularly limited, but is preferably 40 or less, more preferably 30 or less, still more preferably 20 or less, and yet still more preferably 10 or less.

Specific examples of the alkenyl group include an ethenyl group (vinyl group), a 1-propenyl group, a 2-propenyl group, a 1-methyl-1-ethenyl group, a 1-butenyl group, a 2-butenyl group, a 3-butenyl group, a 2-methyl-1-propenyl group, a 2-methyl-2-propenyl group, a 1-ethylethenyl group, a 1-methyl-1-propenyl group, a 1-methyl-2-propenyl group, a 1-pentenyl group, a 2-pentenyl group, a 3-pentenyl group, a 4-pentenyl group, a 1-n-propylethenyl group, a 1-methyl-1-butenyl group, a 1-methyl-2-butenyl group, a 1-methyl-3-butenyl group, a 2-ethyl-2-propenyl group, a 2-methyl-1-butenyl group, a 2-methyl-2-butenyl group, a 2-methyl-3-butenyl group, a 3-methyl-1-butenyl group, a 3-methyl-2-butenyl group, a 3-methyl-3-butenyl group, a 1,1-dimethyl-2-propenyl group, a 1-i-propylethenyl group, a 1,2-dimethyl-1-propenyl group, a 1,2-dimethyl-2-propenyl group, a 1-cyclopentenyl group, a 2-cyclopentenyl group, a 3-cyclopentenyl group, a 1-hexenyl group, a 2-hexenyl group, a 3-hexenyl group, a 4-hexenyl group, a 5-hexenyl group, a 1-methyl-1-pentenyl group, a 1-methyl-2-pentenyl group, a 1-methyl-3-pentenyl group, a 1-methyl-4-pentenyl group, a 1-n-butylethenyl group, a 2-methyl-1-pentenyl group, a 2-methyl-2-pentenyl group, a 2-methyl-3 pentenyl group, a 2-methyl-4-pentenyl group, a 2-n-propyl-2-propenyl group, a 3-methyl-1-pentenyl group, a 3-methyl-2-pentenyl group, a 3-methyl-3-pentenyl group, a 3-methyl-4-pentenyl group, a 3-ethyl-3-butenyl group, a 4-methyl-1-pentenyl group, a 4-methyl-2-pentenyl group, a 4-methyl-3-pentenyl group, a 4-methyl-4-pentenyl group, a 1,1-dimethyl-2-butenyl group, a 1,1-dimethyl-3-butenyl group, a 1,2-dimethyl-1-butenyl group, a 1,2-dimethyl-2-butenyl group, a 1,2-dimethyl-3-butenyl group, a 1-methyl-2-ethyl-2-propenyl group, a 1-s-butylethenyl group, a 1,3-dimethyl-1-butenyl group, a 1,3-dimethyl-2-butenyl group, a 1,3-dimethyl-3-butenyl group, a 1-i-butylethenyl group, a 2,2-dimethyl-3-butenyl group, a 2,3-dimethyl-1-butenyl group, a 2,3-dimethyl-2-butenyl group, a 2,3-dimethyl-3-butenyl group, a 2-i-propyl-2-propenyl group, a 3,3-dimethyl-1-butenyl group, a 1-ethyl-1-butenyl group, a 1-ethyl-2-butenyl group, a 1-ethyl-3-butenyl group, a 1-n-propyl-1-propenyl group, a 1-n-propyl-2-propenyl group, a 2-ethyl-1-butenyl group, a 2-ethyl-2-butenyl group, a 2-ethyl-3-butenyl group, a 1,1,2-trimethyl-2-propenyl group, a 1-t-butylethenyl group, a 1-methyl-1-ethyl-2-propenyl group, a 1-ethyl-2-methyl-1-propenyl group, a 1-ethyl-2-methyl-2-propenyl group, a 1-i-propyl-1-propenyl group, a 1-i-propyl-2-propenyl group, a 1-methyl-2-cyclopentenyl group, a 1-methyl-3-cyclopentenyl group, a 2-methyl-1-cyclopentenyl group, a 2-methyl-2-cyclopentenyl group, a 2-methyl-3-cyclopentenyl group, a 2-methyl-4-cyclopentenyl group, a 2-methyl-5-cyclopentenyl group, a 2-methylene-cyclopentyl group, a 3-methyl-1-cyclopentenyl group, a 3-methyl-2-cyclopentenyl group, a 3-methyl-3-cyclopentenyl group, a 3-methyl-4-cyclopentenyl group, a 3-methyl-5-cyclopentenyl group, a 3-methylene-cyclopentyl group, a 1-cyclohexenyl group, a 2-cyclohexenyl group, and a 3-cyclohexenyl group. Examples thereof also include crosslinked cyclic alkenyl groups such as a bicycloheptenyl group (norbornyl group).

Examples of the substituent in the above-described alkyl group, aryl group, aralkyl group, halogenated alkyl group, halogenated aryl group, halogenated aralkyl group, alkoxyalkyl group, alkoxyaryl group, alkoxyaralkyl group, and alkenyl group include an alkyl group, an aryl group, an aralkyl group, a halogenated alkyl group, a halogenated aryl group, a halogenated aralkyl group, an alkoxyalkyl group, an aryloxy group, an alkoxyaryl group, an alkoxyaralkyl group, an alkenyl group, an alkoxy group, and an aralkyloxy group. Specific examples and the suitable numbers of carbon atoms thereof are the same as those described above or below.

The aryloxy group as described in the substituent is a group in which an aryl group is bonded via an oxygen atom (—O—), and specific examples of the aryl group are the same as those described above. The number of carbon atoms in the aryloxy group is not particularly limited, but is preferably 40 or less, more preferably 30 or less, and still more preferably 20 or less. Specific examples thereof include, but are not limited to, a phenoxy group and a naphthalene-2-yloxy group.

When two or more substituents are present, the substituents may be bonded together to form a ring.

Examples of the organic group having an epoxy group include a glycidoxymethyl group, a glycidoxyethyl group, a glycidoxypropyl group, a glycidoxybutyl group, and an epoxycyclohexyl group.

Examples of the organic group having an acryloyl group include an acryloyl methyl group, an acryloyl ethyl group, and an acryloyl propyl group.

Examples of the organic group having a methacryloyl group include a methacryloyl methyl group, a methacryloyl ethyl group, and a methacryloyl propyl group.

Examples of the organic group having a mercapto group include a mercaptoethyl group, a mercaptobutyl group, a mercaptohexyl group, a mercaptooctyl group, and a mercaptophenyl group.

Examples of the organic group having an amino group include, but are not limited to, an amino group, an aminomethyl group, an aminoethyl group, an aminophenyl, a dimethylaminoethyl group, and a dimethylaminopropyl group. The organic group having an amino group will be described later in more detail.

Examples of the organic group having an alkoxy group include, but are not limited to, a methoxymethyl group and a methoxyethyl group. However, the organic group excludes a group in which an alkoxy group is directly bonded to a silicon atom.

Examples of the organic group having a sulfonyl group include, but are not limited to, a sulfonylalkyl group and a sulfonylaryl group.

Examples of the organic group having a cyano group include a cyanoethyl group, a cyanopropyl group, a cyanophenyl group, and a thiocyanate group.

Examples of the organic group having an amino group include an organic group having at least one of a primary amino group, a secondary amino group, and a tertiary amino group. A hydrolysis-condensation compound in which a hydrolyzable silane having a tertiary amino group is hydrolyzed with a strong acid to form a counter cation having a tertiary ammonium group can be preferably used. In addition, the organic group may contain a hetero atom such as an oxygen atom or a sulfur atom in addition to the nitrogen atom constituting the amino group.

Preferable examples of the organic group having an amino group include a group represented by the following Formula (A1).

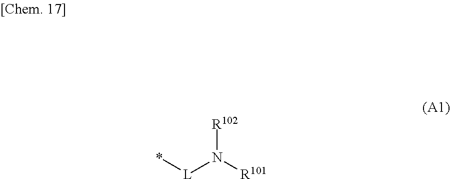

In Formula (A1), R¹⁰¹ and R¹⁰² each independently represent a hydrogen atom or a hydrocarbon group, and L each independently represents an optionally substituted alkylene group. * represents a bond.

Examples of the hydrocarbon group include, but are not limited to, an alkyl group, an alkenyl group, and an aryl group. Specific examples of the alkyl group, the alkenyl group, and the aryl group are the same as those described above regarding R¹.

The alkylene group may be linear or branched, and the number of carbon atoms of the linear or branched alkylene group is ordinarily 1 to 10, and preferably 1 to 5. Examples of the linear or branched alkylene group include linear alkylene groups such as a methylene group, an ethylene group, a trimethylene group, a tetramethylene group, a pentamethylene group, a hexamethylene group, a heptamethylene group, an octamethylene group, a nonamethylene group, and a decamethylene group.

Examples of the organic group having an amino group include, but are not limited to, an amino group, an aminomethyl group, an aminoethyl group, an aminophenyl, a dimethylaminoethyl group, and a dimethylaminopropyl group.

### <<<R¹³>>>

In Formula (1), R¹³ is a group or an atom bonded to a silicon atom, and each independently represents a hydroxy group, an alkoxy group, an aralkyloxy group, an acyloxy group, or a halogen atom.
R¹³ in Formula (1) is the same as R¹³ in the above Formula (1-1).

In the above Formula (1), a represents an integer of 0 to 2, b represents an integer of 0 to 2, and 4-(a+b) represents an integer of 1 to 3.
a preferably represents 0 or 1, and b preferably represents 1 or 2.

### <<<Specific Example of Hydrolyzable Silane Represented by Formula (1)>>>

Among the hydrolyzable silanes represented by Formula (1), specific examples of hydrolyzable silanes in the case where a is 0 include, but are not limited to, tetramethoxysilane, tetrachlorosilane, tetraacetoxysilane, tetraethoxysilane, tetra-n-propoxysilane, tetra-i-propoxysilane, tetra-n-butoxysilane, methyltrimethoxysilane, methyltrichlorosilane, methyltriacetoxysilane, methyltriethoxysilane, methyltripropoxysilane, methyltributoxysilane, methyltriamyloxysilane, methyltriphenoxysilane, methyltribenzyloxysilane, methyltriphenethyloxysilane, glycidoxymethyltrimethoxysilane, glycidoxymethyltriethoxysilane, α-glycidoxyethyltrimethoxysilane, α-glycidoxyethyltriethoxysilane, β-glycidoxyethyltrimethoxysilane, β-glycidoxyethyltriethoxysilane, α-glycidoxypropyltrimethoxysilane, α-glycidoxypropyltriethoxysilane, β-glycidoxypropyltrimethoxysilane, β-glycidoxypropyltriethoxysilane, γ-glycidoxypropyltrimethoxysilane, γ-glycidoxypropyltriethoxysilane, γ-glycidoxypropyltripropoxysilane, γ-glycidoxypropyltributoxysilane, γ-glycidoxypropyltriphenoxysilane, α-glycidoxybutyltrimethoxysilane, α-glycidoxybutyltriethoxysilane, β-glycidoxybutyltriethoxysilane, γ-glycidoxybutyltrimethoxysilane, γ-glycidoxybutyltriethoxysilane, δ-glycidoxybutyltrimethoxysilane, δ-glycidoxybutyltriethoxysilane, (3,4-epoxycyclohexyl)methyltrimethoxysilane, (3,4-epoxycyclohexyl)methyltriethoxysilane, β-(3,4-epoxycyclohexyl)ethyltrimethoxysilane, β-(3,4-epoxycyclohexyl)ethyltriethoxysilane, β-(3,4-epoxycyclohexyl)ethyltripropoxysilane, β-(3,4-epoxycyclohexyl)ethyltributoxysilane, β-(3,4-epoxycyclohexyl)ethyltriphenoxysilane, γ-(3,4-epoxycyclohexyl)propyltrimethoxysilane, γ-(3,4-epoxycyclohexyl)propyltriethoxysilane, 0-(3,4-epoxycyclohexyl)butyltrimethoxysilane, d-(3,4-epoxycyclohexyl)butyltriethoxysilane, glycidoxymethylmethyldimethoxysilane, glycidoxymethylmethyldiethoxysilane, α-glycidoxyethylmethyldimethoxysilane, α-glycidoxyethylmethyldiethoxysilane, β-glycidoxyethylmethyldimethoxysilane, β-glycidoxyethylethyldimethoxysilane, α-glycidoxypropylmethyldimethoxysilane, α-glycidoxypropylmethyldiethoxysilane, β-glycidoxypropylmethyldimethoxysilane, β-glycidoxypropylethyldimethoxysilane, γ-glycidoxypropylmethyldimethoxysilane, γ-glycidoxypropylmethyldiethoxysilane, γ-glycidoxypropylmethyldipropoxysilane, γ-glycidoxypropylmethyldibutoxysilane, γ-glycidoxypropylmethyldiphenoxysilane, γ-glycidoxypropylethyldimethoxysilane, γ-glycidoxypropylethyldiethoxysilane, γ-glycidoxypropylvinyldimethoxysilane, γ-glycidoxypropylvinyldiethoxysilane, ethyltrimethoxysilane, ethyltriethoxysilane, vinyltrimethoxysilane, vinyltriethoxysilane, vinyltrichlorosilane, vinyltriacetoxysilane, methylvinyldimethoxysilane, methylvinyldiethoxysilane, methylvinyldichlorosilane, methylvinyldiacetoxysilane, dimethylvinylmethoxysilane, dimethylvinylethoxysilane, dimethylvinylchlorosilane, dimethylvinylacetoxysilane, divinyldimethoxysilane, divinyldiethoxysilane, divinyldichlorosilane, divinyldiacetoxysilane, γ-glycidoxypropylvinyldimethoxysilane, γ-glycidoxypropylvinyldiethoxysilane, allyltrimethoxysilane, allyltriethoxysilane, allyltrichlorosilane, allyltriacetoxysilane, allylmethyldimethoxysilane, allylmethyldiethoxysilane, allylmethyldichlorosilane, allylmethyldiacetoxysilane, allyldimethylmethoxysilane, allyldimethylethoxysilane, allyldimethylchlorosilane, allyldimethylacetoxysilane, diallyldimethoxysilane, diallyldiethoxysilane, diallyldichlorosilane, diallyldiacetoxysilane, 3-allylaminopropyltrimethoxysilane, 3-allylaminopropyltriethoxysilane, p-styryltrimethoxysilane, phenyltrimethoxysilane, phenyltriethoxysilane, phenyltrichlorosilane, phenyltriacetoxysilane, phenylmethyldimethoxysilane, phenylmethyldiethoxysilane, phenylmethyldichlorosilane, phenylmethyldiacetoxysilane, phenyldimethylmethoxysilane, phenyldimethylethoxysilane, phenyldimethylchlorosilane, phenyldimethylacetoxysilane, diphenylmethylmethoxysilane, diphenylmethylethoxysilane, diphenylmethylchlorosilane, diphenylmethylacetoxysilane, diphenyldimethoxysilane, diphenyldiethoxysilane, diphenyldichlorosilane, diphenyldiacetoxysilane, triphenylmethoxysilane, triphenylethoxysilane, triphenylacetoxysilane, triphenylchlorosilane, 3-phenylaminopropyltrimethoxysilane, 3-phenylaminopropyltriethoxysilane, dimethoxymethyl-3-(3-phenoxypropylthiopropyl) silane, triethoxy ((2-methoxy-4-(methoxymethyl) phenoxy)methyl) silane, benzyltrimethoxysilane, benzyltriethoxysilane, benzylmethyldimethoxysilane, benzylmethyldiethoxysilane, benzyldimethylmethoxysilane, benzyldimethylethoxysilane, benzyldimethylchlorosilane, phenethyltrimethoxysilane, phenethyltriethoxysilane, phenethyltrichlorosilane, phenethyltriacetoxysilane, phenethylmethyldimethoxysilane, phenethylmethyldiethoxysilane, phenetylmethyldichlorosilane, phenethylmethyldiacetoxysilane, methoxyphenyltrimethoxysilane, methoxyphenyltriethoxysilane, methoxyphenyltriacetoxysilane, methoxyphenyltrichlorosilane, methoxybenzyltrimethoxysilane, methoxybenzyltriethoxysilane, methoxybenzyltriacetoxysilane, methoxybenzyltrichlorosilane, methoxyphenethyltrimethoxysilane, methoxyphenetyltriethoxysilane, methoxyphenetyltriacetoxysilane, methoxyphenethyltrichlorosilane, ethoxyphenyltrimethoxysilane, ethoxyphenyltriethoxysilane, ethoxyphenyltriacetoxysilane, ethoxyphenyltrichlorosilane, ethoxybenzyltrimethoxysilane, ethoxybenzyltriethoxysilane, ethoxybenzyltriacetoxysilane, ethoxybenzyltrichlorosilane, i-propoxyphenyltrimethoxysilane, i-propoxyphenyltriethoxysilane, i-propoxyphenyltriacetoxysilane, i-propoxyphenyltrichlorosilane, i-propoxybenzyltrimethoxysilane, i-propoxybenzyltriethoxysilane, i-propoxybenzyltriacetoxysilane, i-propoxybenzyltrichlorosilane, t-butoxyphenyltrimethoxysilane, t-butoxyphenyltriethoxysilane, t-butoxyphenyltriacetoxysilane, t-butoxyphenyltrichlorosilane, t-butoxybenzyltrimethoxysilane, t-butoxybenzyltriethoxysilane, t-butoxybenzyltriacetoxysilane, t-butoxybenzyltrichlorosilane, methoxynaphthyltrimethoxysilane, methoxynaphthyltriethoxysilane, methoxynaphtyltriacetoxysilane, methoxynaphtyltrichlorosilane, ethoxynaphtyltrimethoxysilane, ethoxynaphthyltriethoxysilane, ethoxynaphthyltriacetoxysilane, ethoxynaphthyltrichlorosilane, γ-chloropropyltrimethoxysilane, γ-chloropropyltriethoxysilane, γ-chloropropyltriacetoxysilane, 3,3,3-trifluoropropyltrimethoxysilane, γ-methacryloxypropyltrimethoxysilane, γ-mercaptopropyltrimethoxysilane, γ-mercaptopropyltriethoxysilane, β-cyanoethyltriethoxysilane, thiocyanate propyltriethoxysilane, chloromethyltrimethoxysilane, chloromethyltriethoxysilane, triethoxysilylpropyldiallyl isocyanurate, bicyclo[2,2,1]heptenyltriethoxysilane, benzenesulfonylpropyltriethoxysilane, benzenesulfoneamidepropyltriethoxysilane, dimethylaminopropyltrimethoxysilane, dimethyldimethoxysilane, phenylmethyldimethoxysilane, dimethyldiethoxysilane, phenylmethyldiethoxysilane, γ-chloropropylmethyldimethoxysilane, γ-chloropropylmethyldiethoxysilane, dimethyldiacetoxysilane, y-methacryloxypropylmethyldimethoxysilane, γ-methacryloxypropylmethyldiethoxysilane, γ-mercaptopropylmethyldimethoxysilane, γ-mercaptomethyldiethoxysilane, methylvinyldimethoxysilane, methylvinyldiethoxysilane, silanes represented by the following Formulas (A-1) to (A-41), and silanes represented by the following Formulas (1-1) to (1-5) and (1-11) to (1-290).

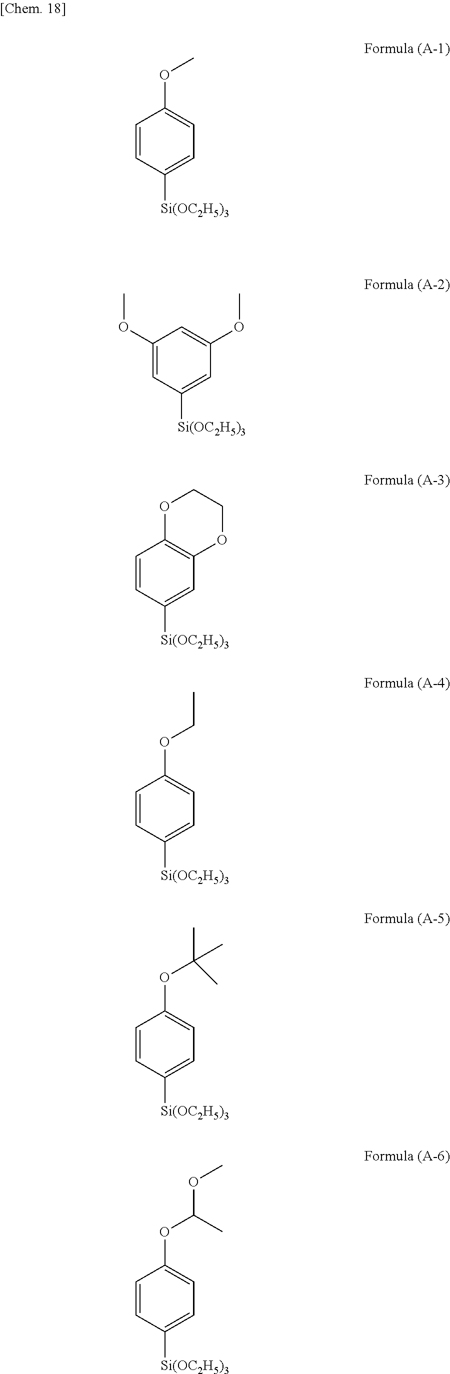

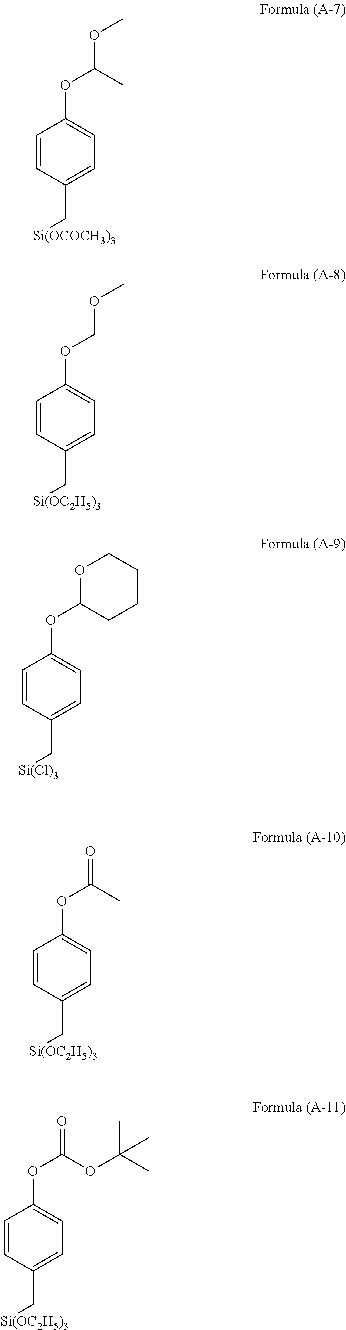

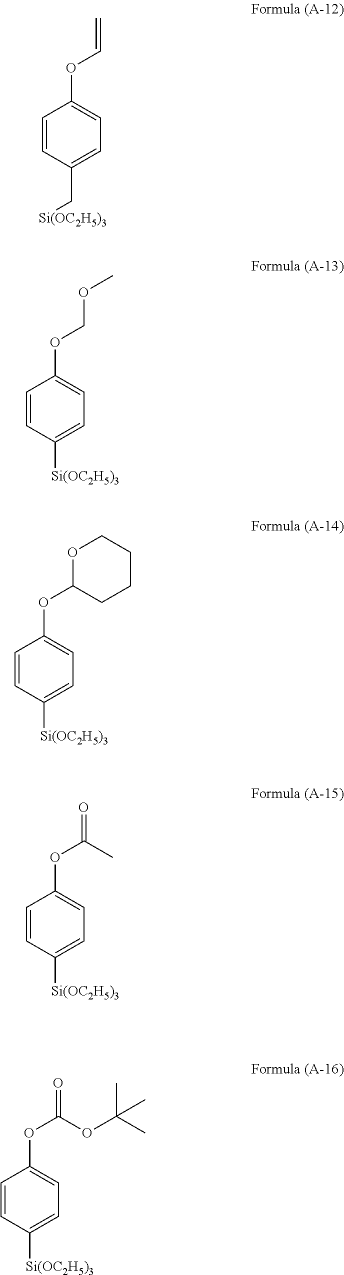

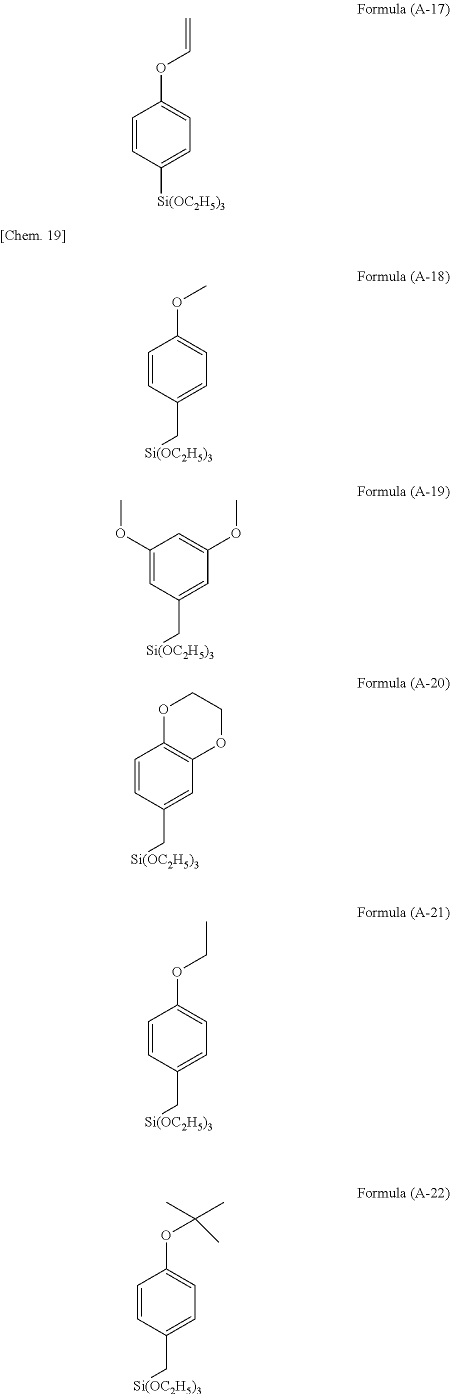

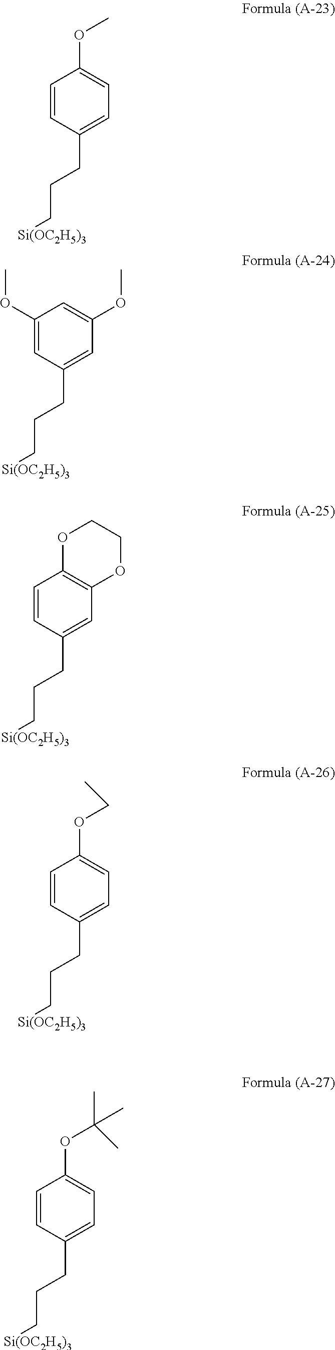

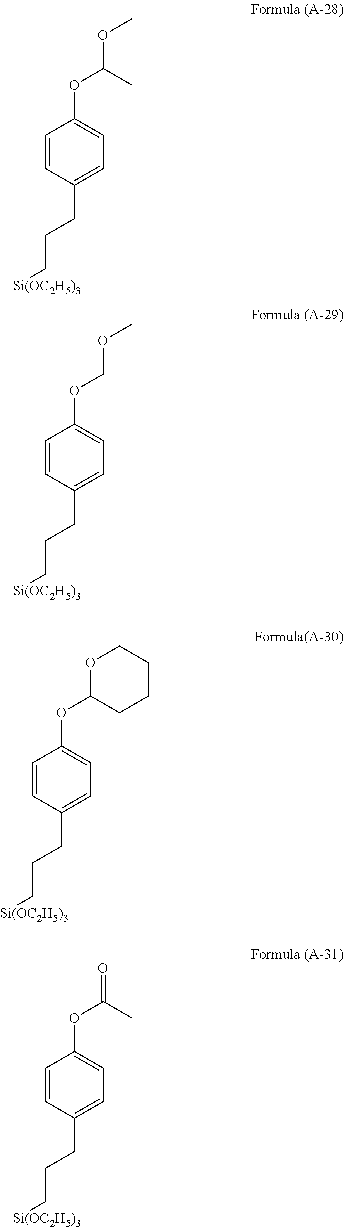

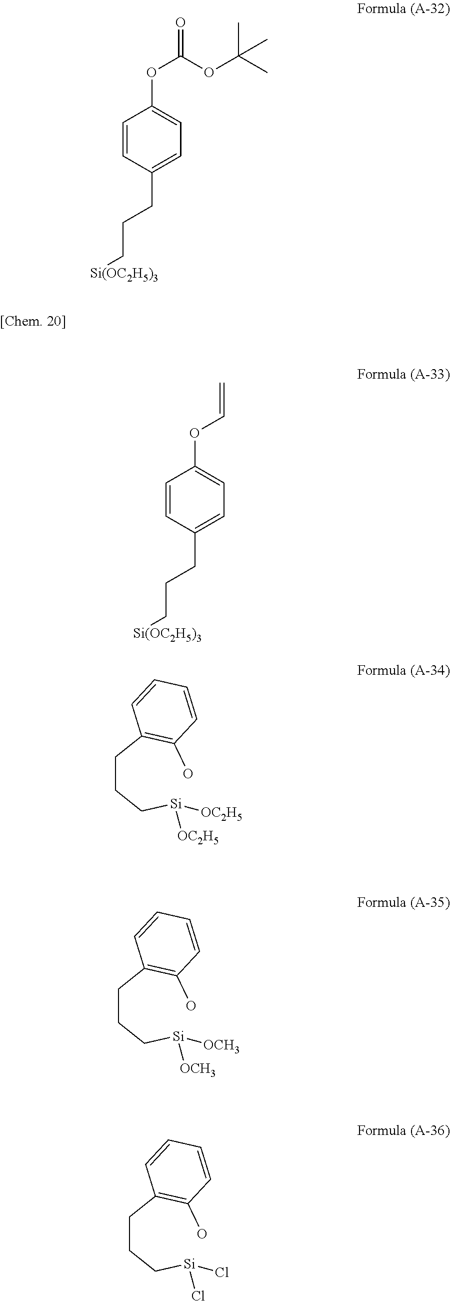

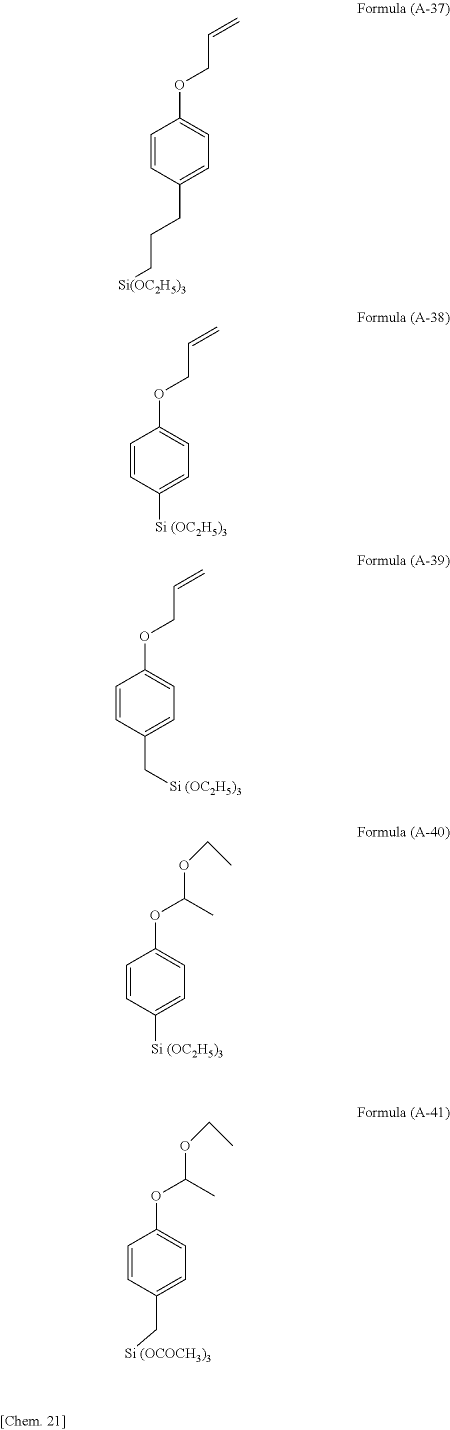

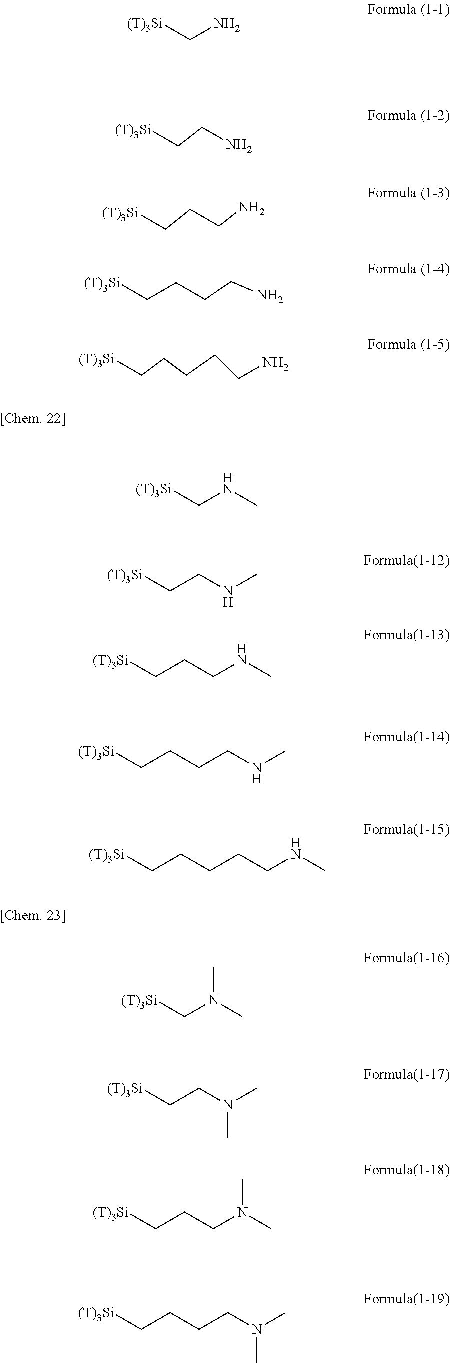

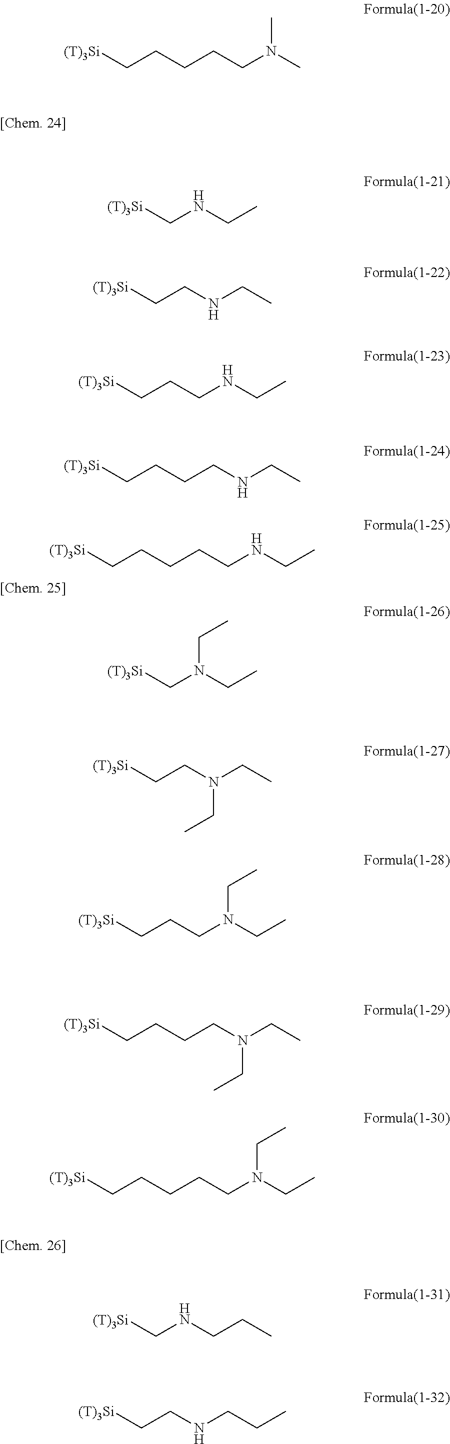

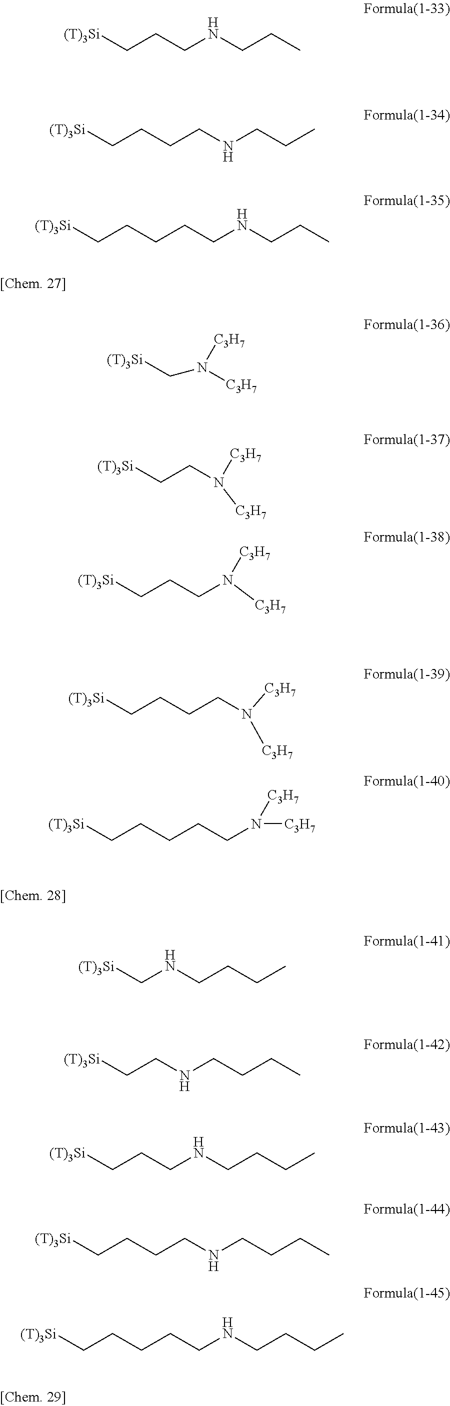

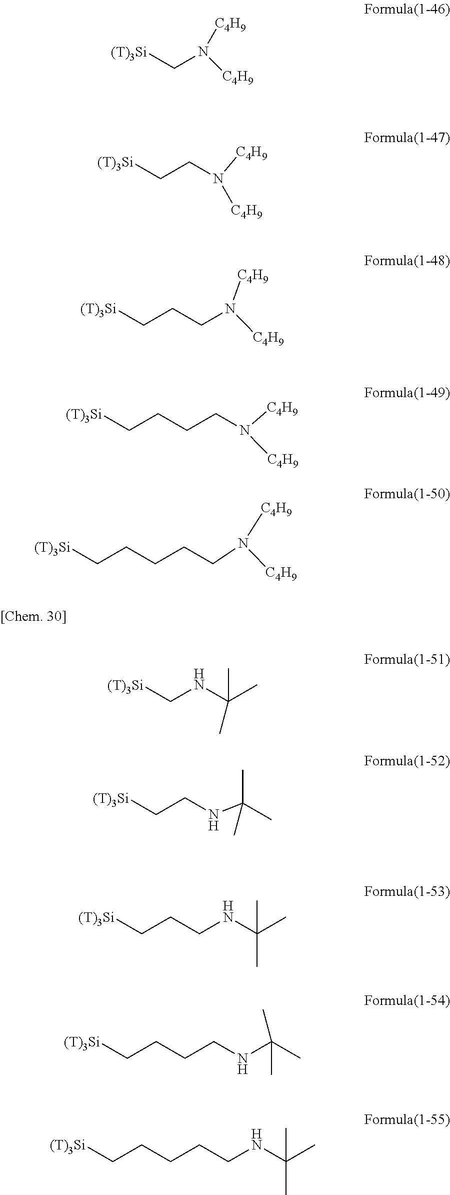

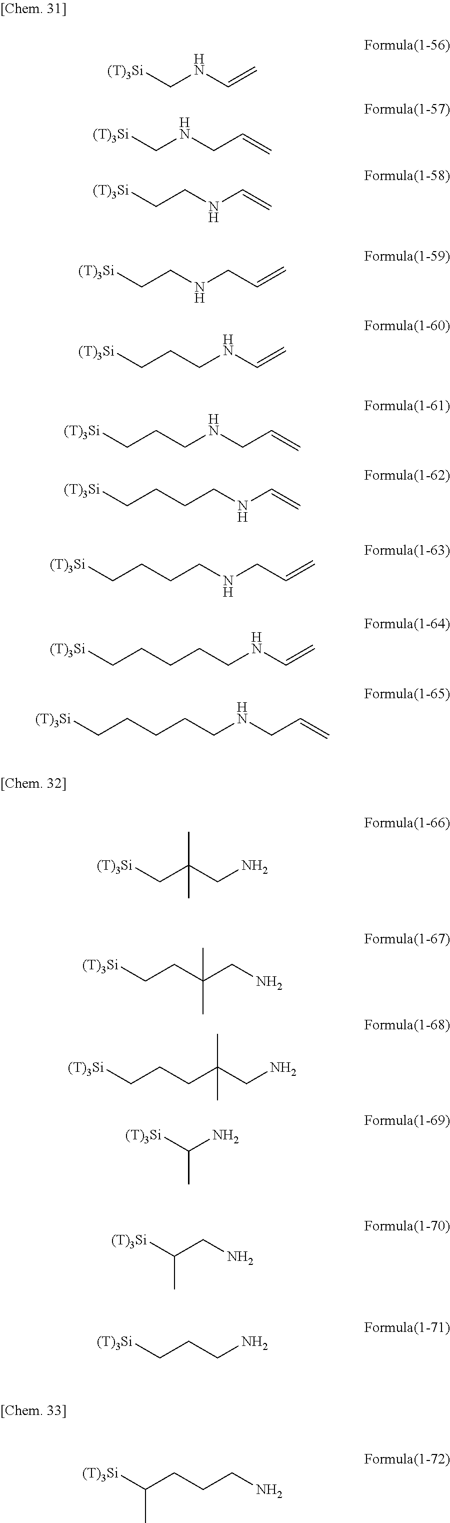

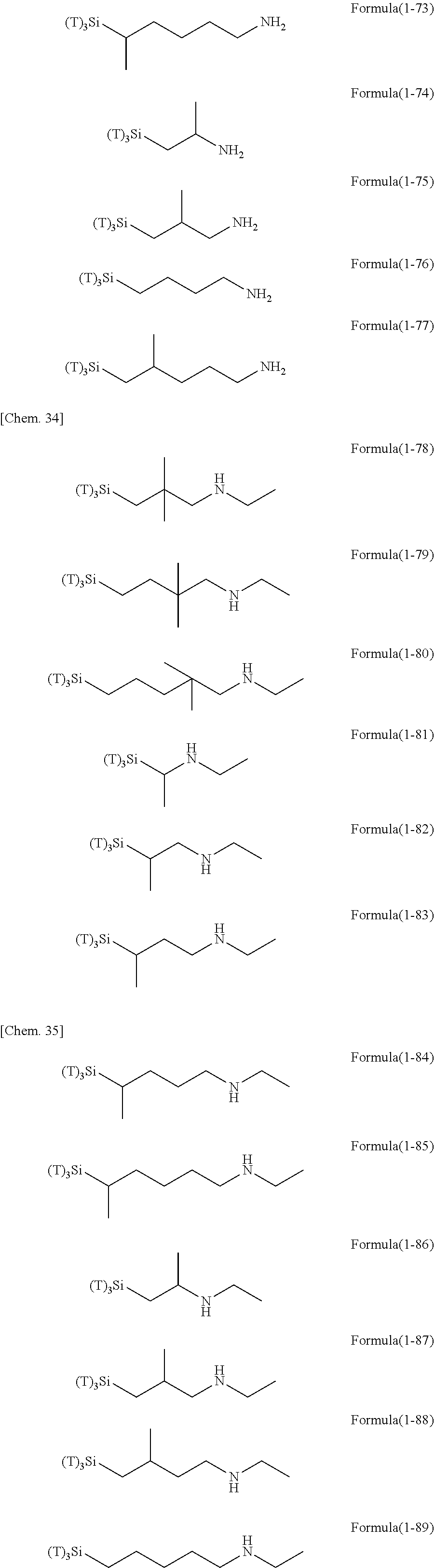

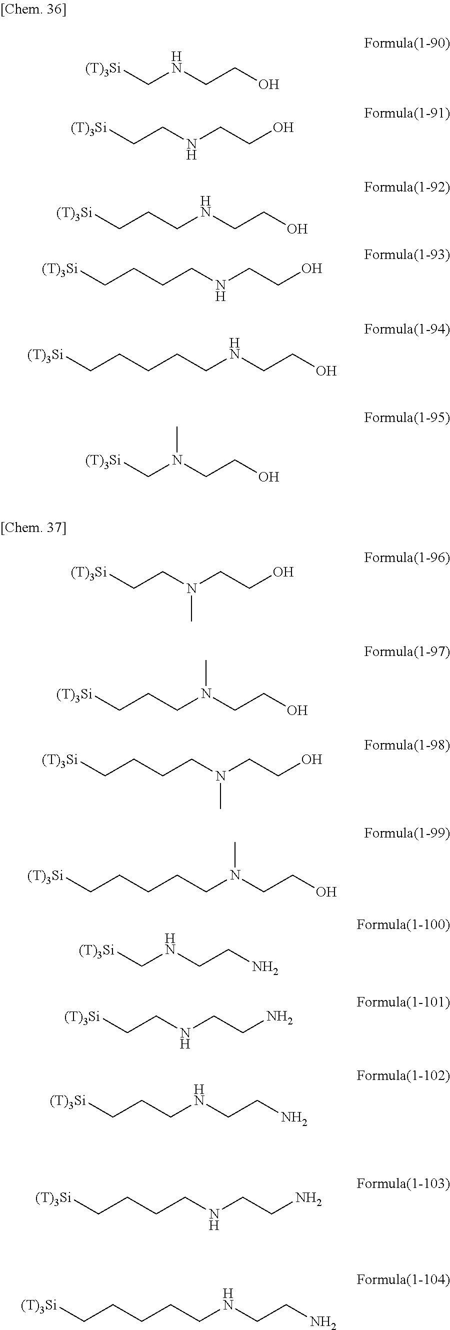

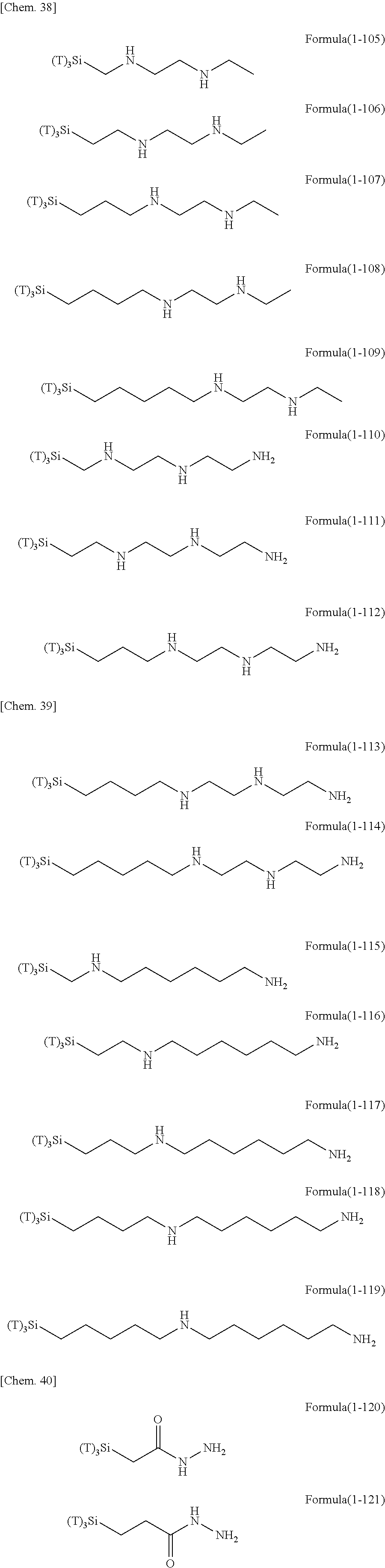

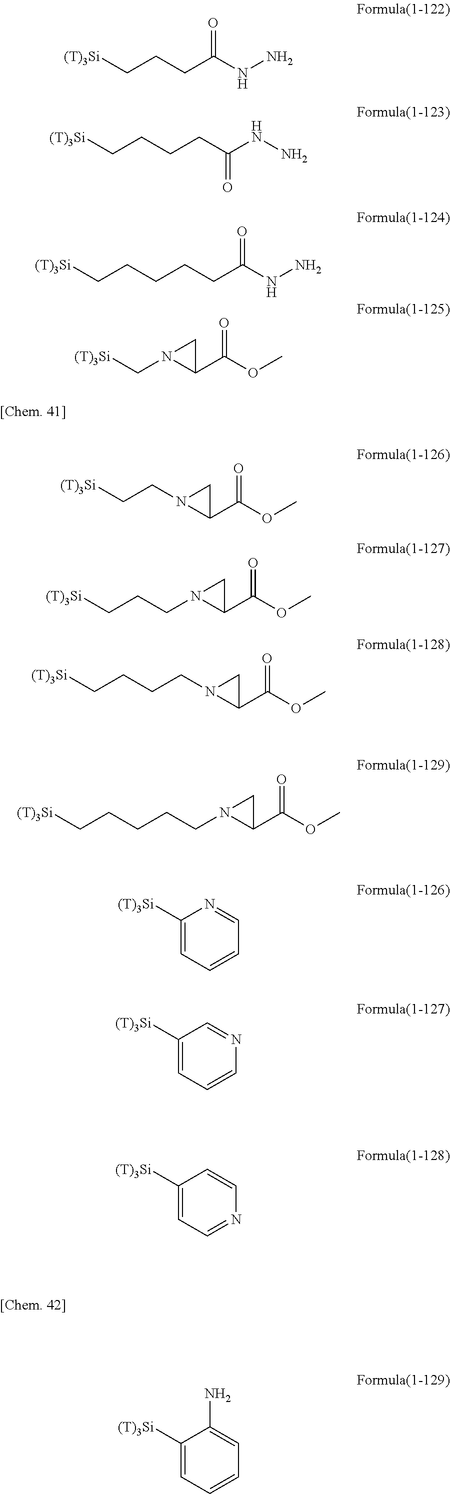

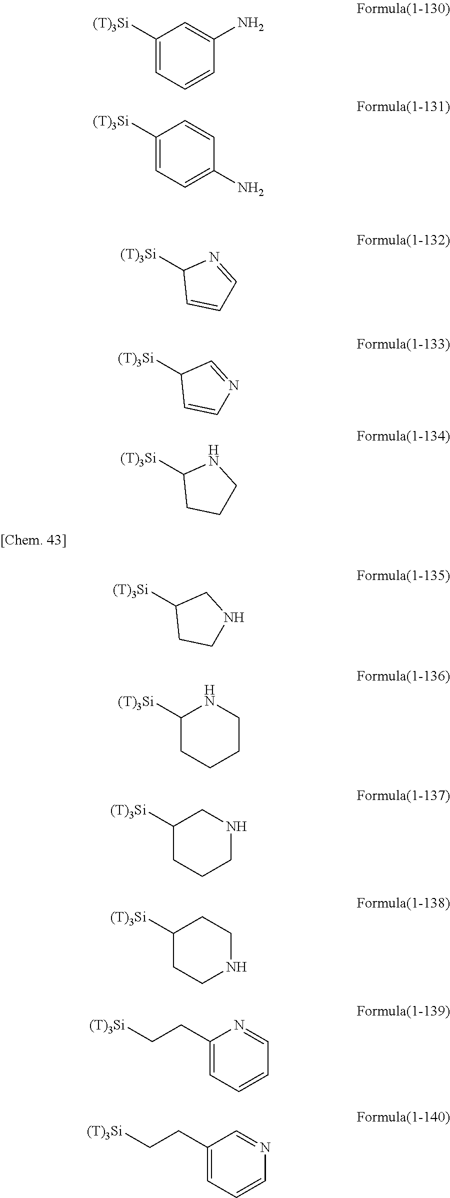

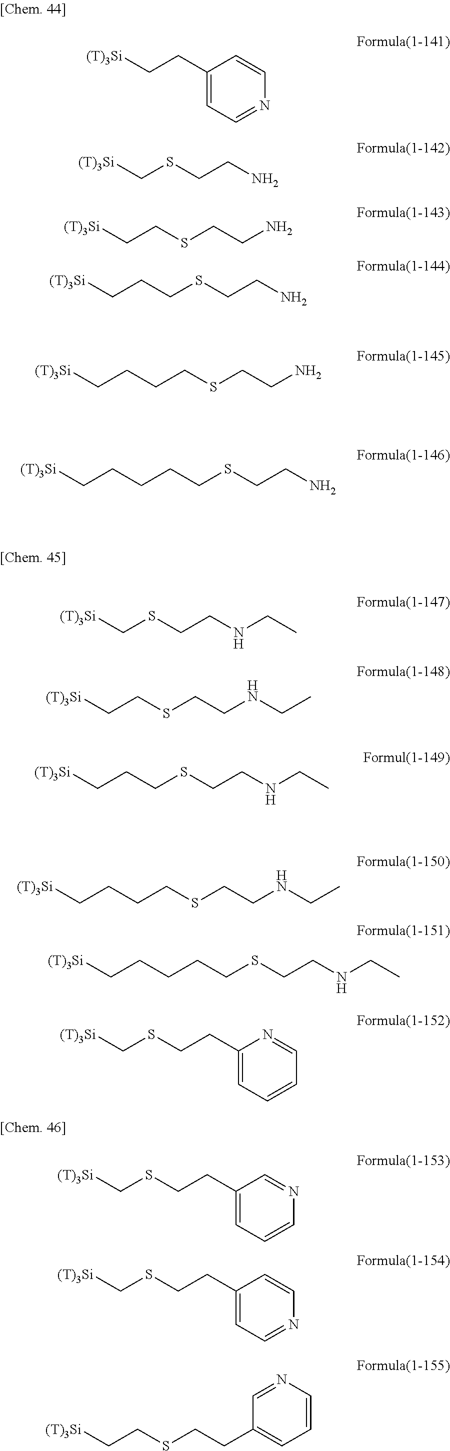

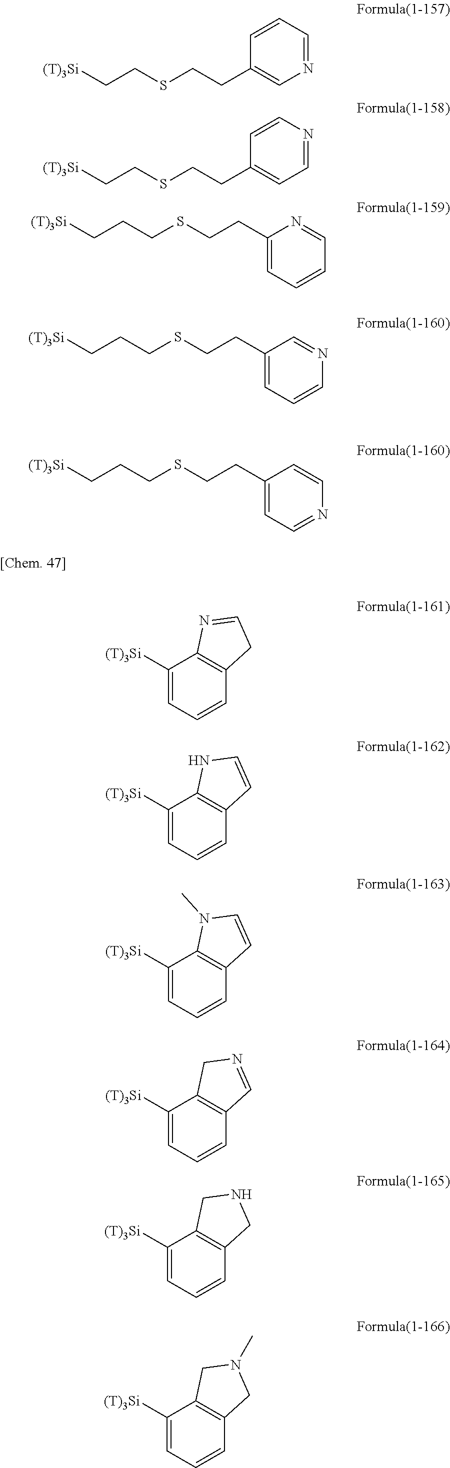

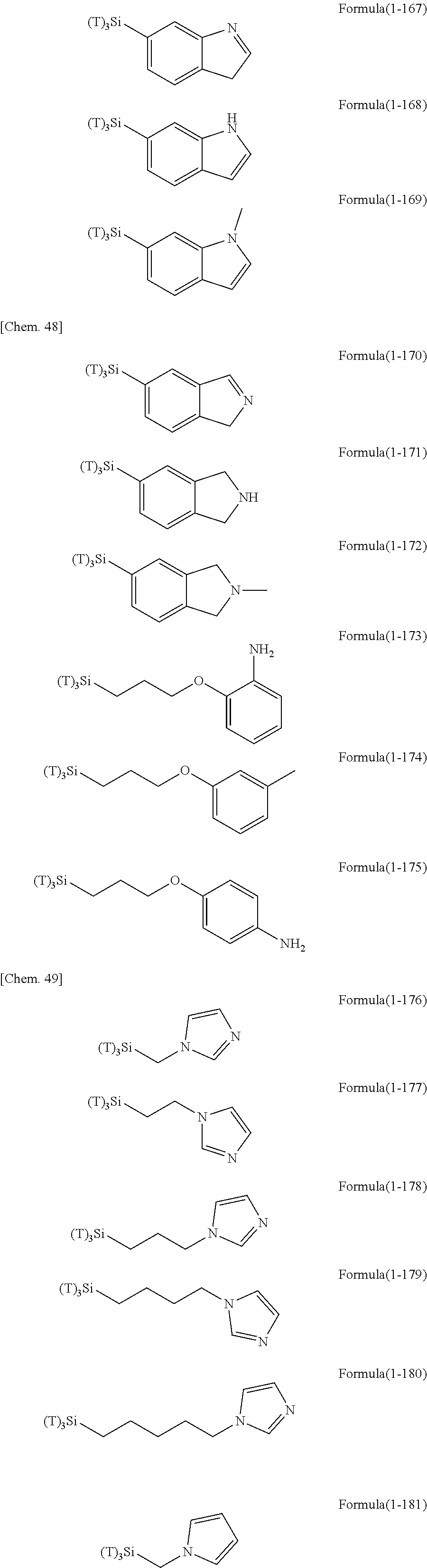

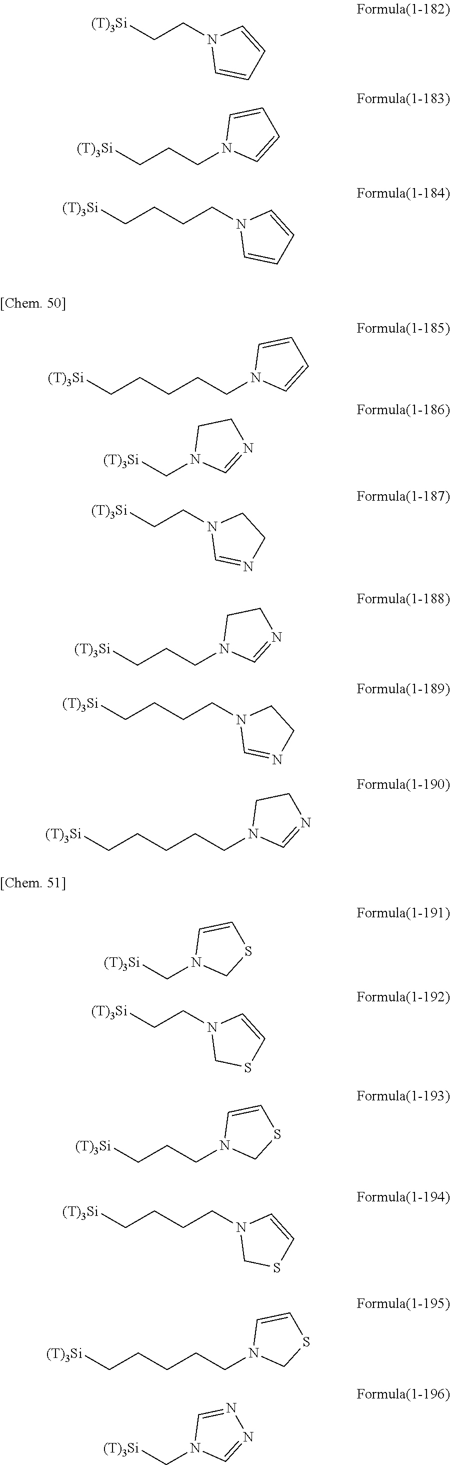

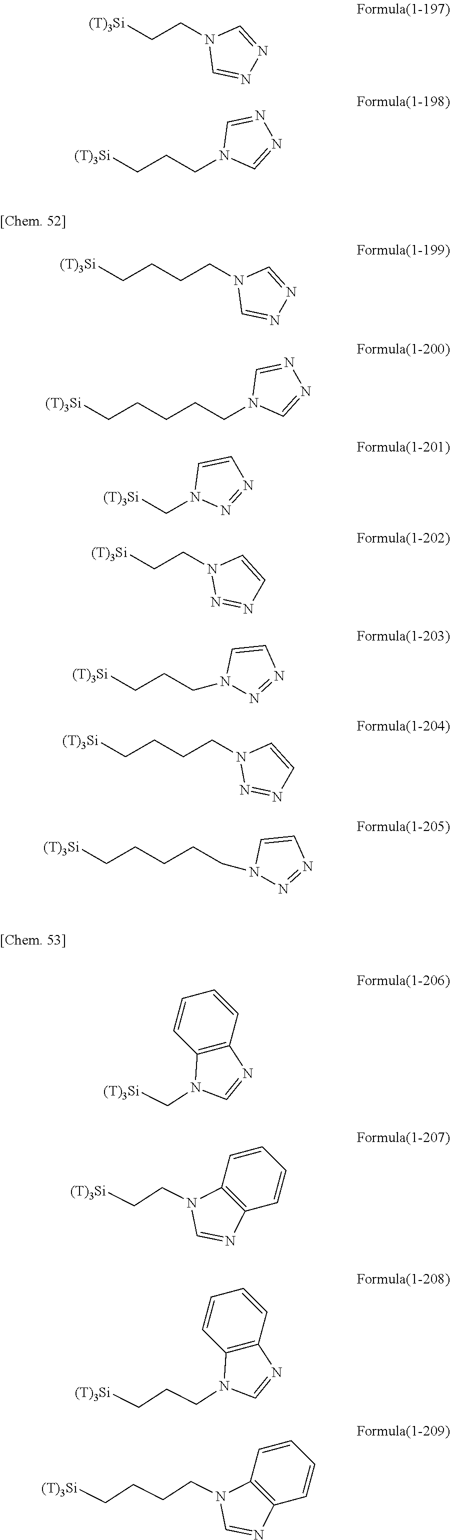

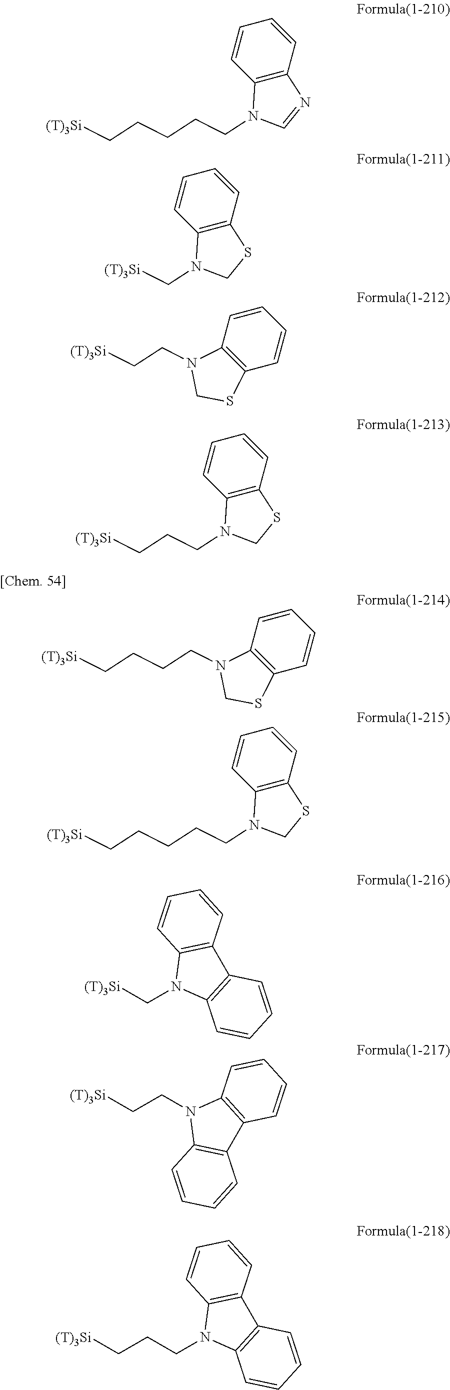

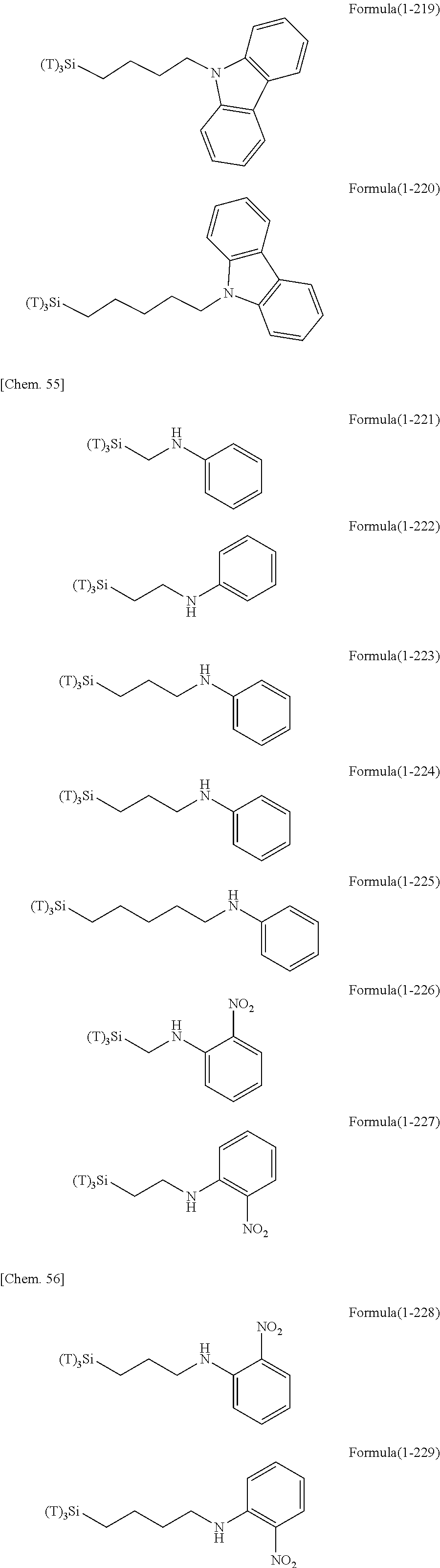

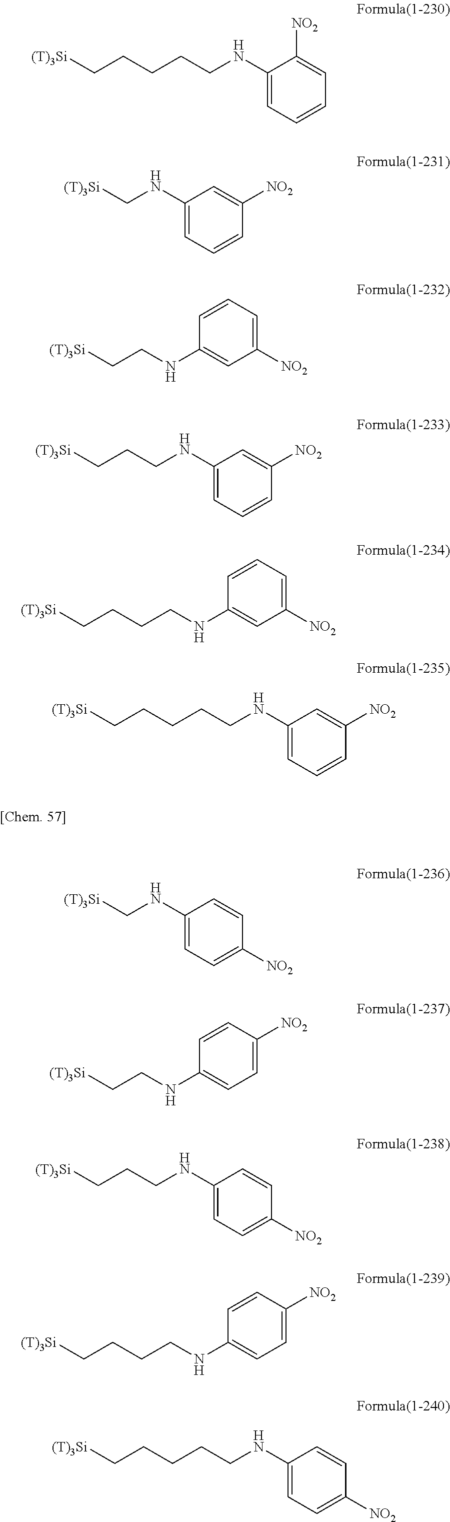

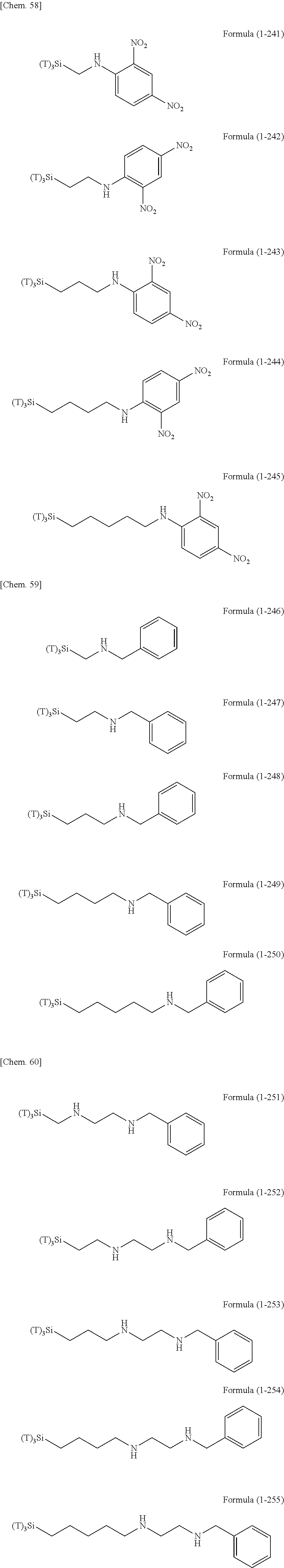

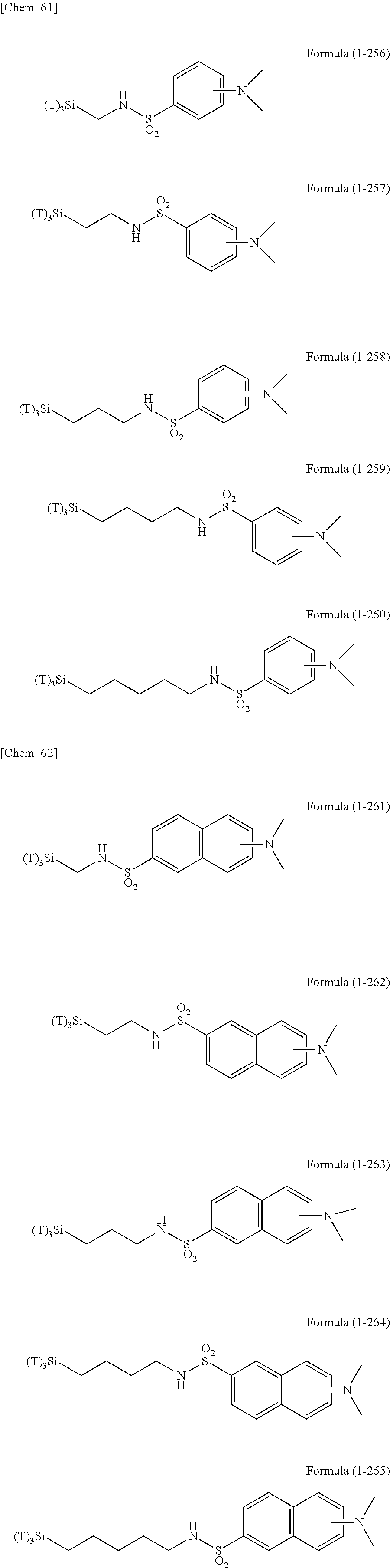

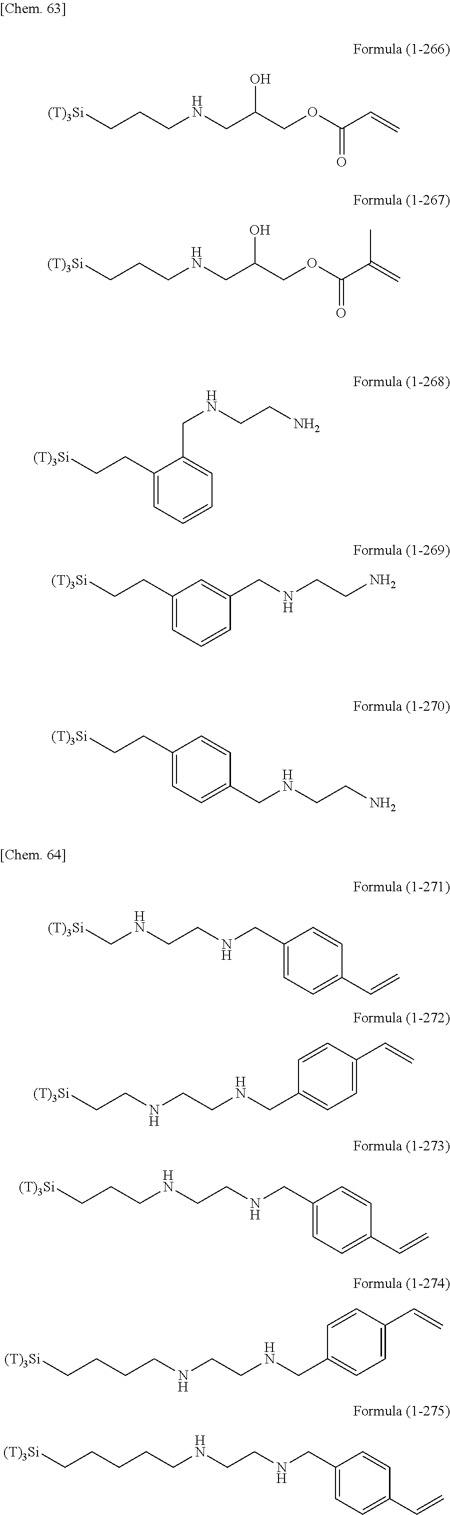

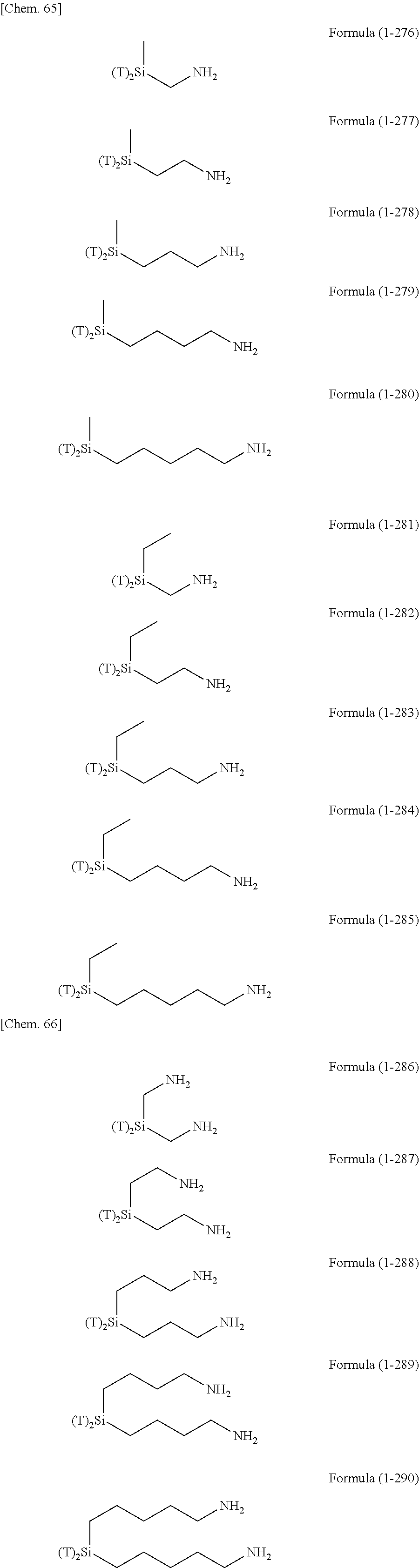

In Formulas (1-1) to (1-290), T each independently represents an alkoxy group, an acyloxy group, or a halogen group, and represents preferably a methoxy group or an ethoxy group, for example.

Among the hydrolyzable silanes represented by Formula (1), specific examples of the hydrolyzable silane having R¹¹, in which R¹¹ is a monovalent group represented by Formula (2a), include silane compounds containing an alkylphosphonic acid such as diethyl [(3-triethoxysilyl)ethyl]phosphonate.

Among the hydrolyzable silanes represented by Formula (1), for example, a commercially available product may be used as the hydrolyzable silane having R¹¹, in which R¹¹ is a monovalent group represented by Formula (2b), and the hydrolyzable silane can also be synthesized by a known method described in WO 2011/102470 A and the like.

Among the hydrolyzable silanes represented by Formula (1), specific examples of the hydrolyzable silane having R¹¹, in which R¹¹ is a monovalent group represented by Formula (2b), include silanes represented by the following Formulas (4-1-1) to (Apr. 1, 2029).

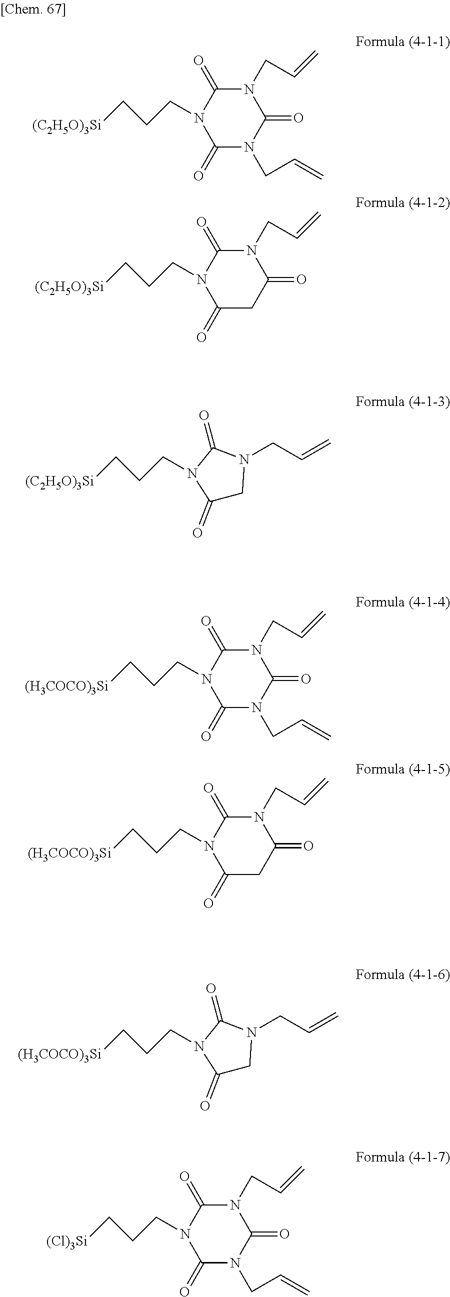

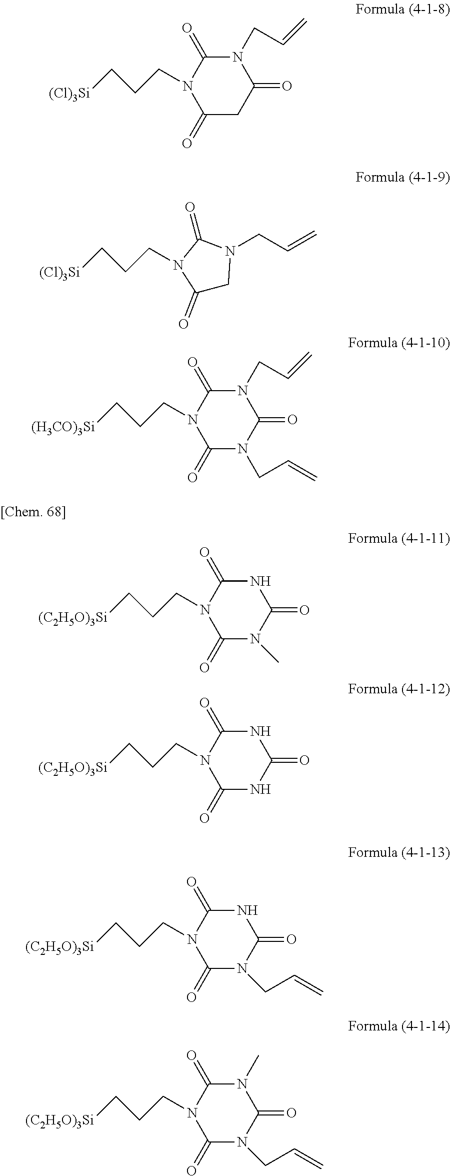

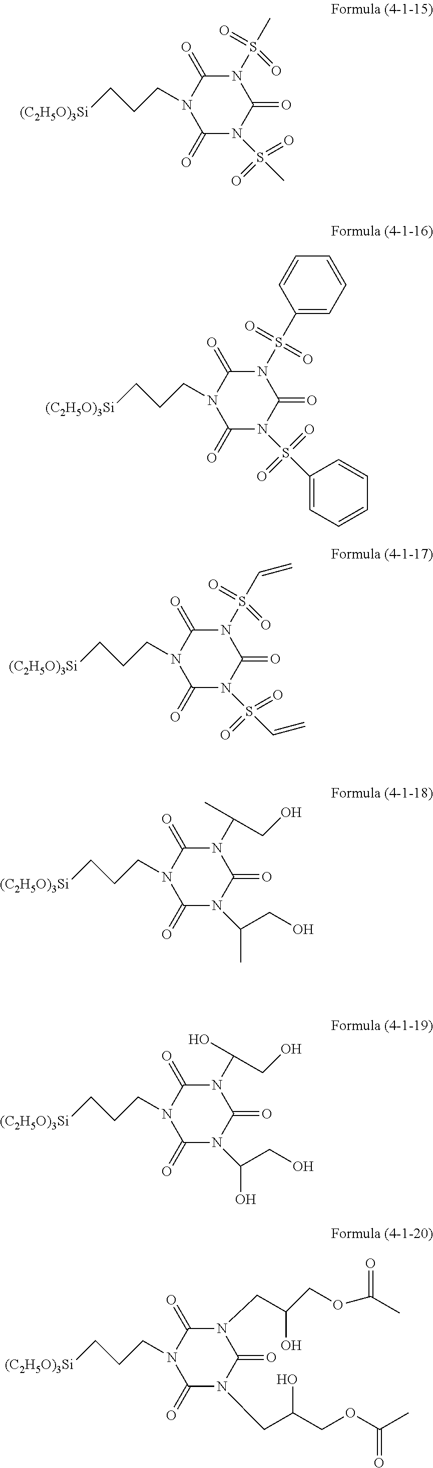

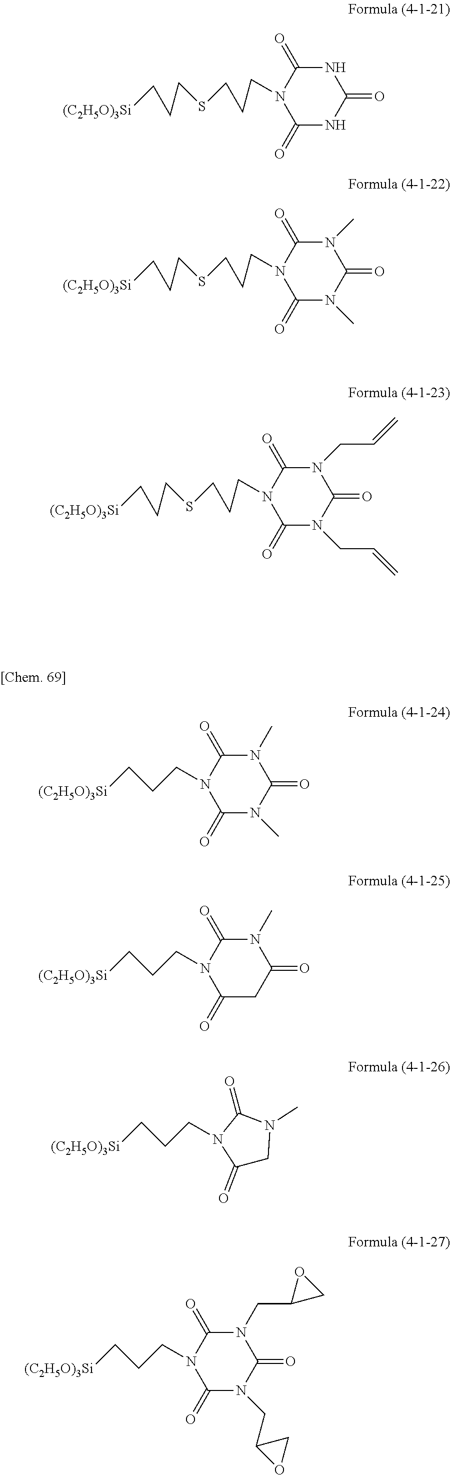

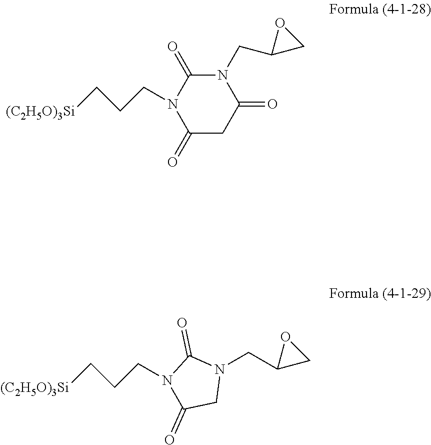

Furthermore, the hydrolyzable silane mixture forming the hydrolysis-condensation compound contained in the silicon-containing resist underlayer film-forming composition of the present invention preferably contains a hydrolyzable silane of a bifunctional monomer represented by the following Formula (1-2) among the hydrolyzable silanes represented by Formula (1).

That is, the hydrolyzable silane mixture according to the present invention preferably contains a hydrolyzable silane of a bifunctional monomer represented by the following Formula (1-2) in addition to the hydrolyzable silane of a tetrafunctional monomer represented by Formula (1-1) and the hydrolyzable silane represented by the following Formula (2).

In addition, the hydrolyzable silane mixture forming the hydrolysis-condensation compound contained in the silicon-containing resist underlayer film-forming composition of the present invention preferably contains a hydrolyzable silane represented by the following Formula (1-3) among the hydrolyzable silanes represented by Formula (1).

That is, the hydrolyzable silane mixture according to the present invention preferably contains a hydrolyzable silane represented by the following Formula (1-3) in addition to the hydrolyzable silane of a tetrafunctional monomer represented by Formula (1-1) and the hydrolyzable silane represented by the following Formula (2).

When the hydrolyzable silane of the bifunctional monomer represented by Formula (1-2) or the hydrolyzable silane represented by Formula (1-3) is contained in the hydrolyzable silane mixture, the solubility of the silicon-containing resist underlayer film obtained from the silicon-containing resist underlayer film-forming composition containing the hydrolysis-condensation compound of the hydrolyzable silane mixture in an alkaline chemical solution (basic chemical solution) can be further improved.

### <<Silane Compound (Hydrolyzable Silane) Represented by Formula (1-2)>>

The hydrolyzable silane mixture according to the present invention preferably contains a hydrolyzable silane of a bifunctional monomer represented by the following Formula (1-2) among the hydrolyzable silanes represented by the above Formula (1).

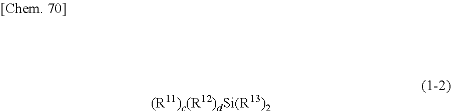

In Formula (1-2), R¹¹, R¹², and R¹³ represent the same as R¹¹, R¹², and R¹³ in Formula (1).
c represents an integer of 0 to 2, d represents an integer of 0 to 2, and c+d=2. c is preferably 0 or 1, and d is preferably 1 or 2.

### <<Silane Compound (Hydrolyzable Silane) Represented by Formula (1-3)>>

The hydrolyzable silane mixture according to the present invention preferably contains a hydrolyzable silane represented by the following Formula (1-3) among the hydrolyzable silanes represented by the above Formula (1).

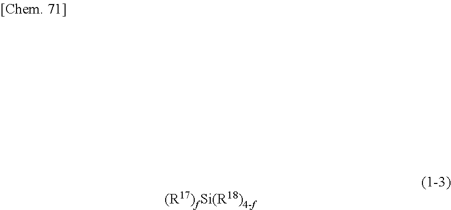

R¹⁷ is a group bonded to a silicon atom, and each independently represents an optionally substituted alkyl group, an optionally substituted aryl group, an optionally substituted aralkyl group, an optionally substituted halogenated alkyl group, an optionally substituted halogenated aryl group, an optionally substituted halogenated aralkyl group, an optionally substituted alkoxyalkyl group, an optionally substituted alkoxyaryl group, an optionally substituted alkoxyaralkyl group, or an optionally substituted alkenyl group, or represents an organic group having an epoxy group, an acryloyl group, a methacryloyl group, a mercapto group, an amino group, or a cyano group.
R¹⁸ is a group or an atom bonded to a silicon atom, and each independently represents an alkoxy group, an aralkyloxy group, an acyloxy group, or a halogen atom.
f represents an integer of 1 to 3.

In R¹⁷ of Formula (1-3), the same group as R¹² of Formula (1) is as described in the section of <<<R¹²>>> above.

In R¹⁸ of Formula (1-3), the same group as R¹³ of Formula (1) is as described in the section of <<<R¹³>>> above.

When the hydrolyzable silane of the bifunctional monomer represented by Formula (1-2) or the hydrolyzable silane represented by Formula (1-3) is contained in the hydrolyzable silane mixture, the peak intensity value of the siloxane bond of the silicon-containing resist underlayer film formed from the silicon-containing resist underlayer film-forming composition containing a hydrolysis-condensation compound of the hydrolyzable silane mixture can be reduced (refer to the results of Examples described later). The decrease in the peak intensity value of the siloxane bond in the silicon-containing resist underlayer film is considered to effectively act to improve the solubility of the silicon-containing resist underlayer film in a chemical solution.

In addition, among the hydrolyzable silanes of the bifunctional monomer contained in the hydrolyzable silane mixture, the use of a hydrolyzable silane of a bifunctional monomer having a high value of the water contact angle resulted in better solubility of the silicon-containing resist underlayer film in a chemical solution (refer to the results of Examples described later), and thus it is more preferable to contain a hydrolyzable silane of a bifunctional monomer having a high value of the water contact angle.

### (Silicon-Containing Resist Underlayer Film-Forming Composition of Second Aspect)

Examples of a preferable embodiment of the silicon-containing resist underlayer film-forming composition of the present invention include a composition containing a hydrolysis-condensation compound of a hydrolyzable silane mixture containing a bifunctional hydrolyzable silane.

### <Hydrolysis-Condensation Compound of Hydrolyzable Silane Mixture>

The hydrolyzable silane mixture contains a hydrolyzable silane represented by the following Formula (1-2), which is particularly a hydrolyzable silane of a bifunctional monomer among the hydrolyzable silanes represented by the above Formula (1).

In addition, the hydrolyzable silane mixture may contain the hydrolyzable silane represented by the above Formula (1-1), the hydrolyzable silane represented by above Formula (2), and the hydrolyzable silane represented by above Formula (1) excluding the hydrolyzable silane represented by the above Formula (1-2), in addition to the hydrolyzable silane represented by the above Formula (1-2).

### <<Silane Compound (Hydrolyzable Silane) Represented by Formula (1-2)>>

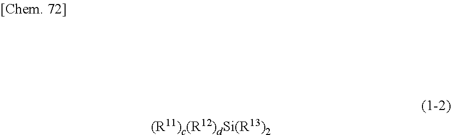

In Formula (1-2), R¹¹, R¹², R¹³, c, and d are as described above.

When the hydrolyzable silane of the bifunctional monomer represented by Formula (1-2) is contained in the hydrolyzable silane mixture, the solubility of the silicon-containing resist underlayer film obtained from the silicon-containing resist underlayer film-forming composition containing the hydrolysis-condensation compound of the hydrolyzable silane mixture in an alkaline chemical solution (basic chemical solution) can be further improved.

When the hydrolyzable silane of the bifunctional monomer represented by Formula (1-2) is contained in the hydrolyzable silane mixture, the peak intensity value of the siloxane bond of the silicon-containing resist underlayer film formed from the silicon-containing resist underlayer film-forming composition containing a hydrolysis-condensation compound of the hydrolyzable silane mixture can be reduced (refer to the results of Examples described later). The decrease in the peak intensity value of the siloxane bond in the silicon-containing resist underlayer film is considered to effectively act to improve the solubility of the silicon-containing resist underlayer film in a chemical solution.

In addition, among the hydrolyzable silanes of the bifunctional monomer contained in the hydrolyzable silane mixture, the use of a hydrolyzable silane of a bifunctional monomer having a high value of the water contact angle resulted in better solubility of the silicon-containing resist underlayer film in a chemical solution (refer to the results of Examples described later), and thus it is more preferable to contain a hydrolyzable silane of a bifunctional monomer having a high value of the water contact angle.

The hydrolyzable silane mixture may contain other silane compounds (hydrolyzable silanes) in addition to the silane compounds exemplified in the first aspect and the second aspect as long as the effects of the present invention are not impaired.

In the hydrolyzable silane mixture of the silicon-containing resist underlayer film-forming composition of the first aspect described above,
the charged amount of the silane compound represented by Formula (1-1) is preferably more than 0 mol % and 30 mol % or less with respect to 100 mol % of the charged amount of all silane compounds (hydrolyzable silanes) contained in the hydrolyzable silane mixture.

For example, in the hydrolyzable silane mixture, the charged amount of the silane compound of the tetrafunctional monomer represented by Formula (1-1) can be 0.1 to 30 mol % with respect to 100 mol % of the charged amount of all silane compounds (hydrolyzable silanes) contained in the hydrolyzable silane mixture.

In addition, for example, in the hydrolyzable silane mixture, the charged amount of the silane compound represented by Formula (2) can be 0.1 to 20 mol % with respect to 100 mol % of the charged amount of all silane compounds (hydrolyzable silanes) contained in the hydrolyzable silane mixture.

In addition, for example, in the hydrolyzable silane mixture, the charged amount of the silane compound of the bifunctional monomer represented by Formula (1-2) among the hydrolyzable silanes represented by Formula (1) can be 0.1 to 50 mol % with respect to 100 mol % of the charged amount of all silane compounds (hydrolyzable silanes) contained in the hydrolyzable silane mixture.

In addition, for example, in the hydrolyzable silane mixture, the charged amount of the silane compound represented by Formula (1-3) among the hydrolyzable silanes represented by Formula (1) can be 0.1 to 20 mol % with respect to 100 mol % of the charged amount of all silane compounds (hydrolyzable silanes) contained in the hydrolyzable silane mixture.

The above-described hydrolysis-condensation compound of hydrolyzable silane mixture may have a weight-average molecular weight of, for example, 500 to 1,000,000. From the viewpoint of suppressing the precipitation of the hydrolysis-condensation compound in the composition, the weight-average molecular weight is preferably 500,000 or less, and more preferably 250,000 or less, and still more preferably 100,000 or less. From the viewpoint of the compatibility between storage stability and coatability, the weight-average molecular weight may be preferably 700 or more, and more preferably 1,000 or more.

The weight-average molecular weight is determined by GPC analysis in terms of polystyrene. The GPC analysis can be performed under the following conditions: GPC apparatus (trade name: HLC-8220GPC, manufactured by Tosoh Corporation), GPC columns (trade name: Shodex (registered trademark) KF803L, KF802, and KF801, manufactured by Showa Denko K.K.), column temperature of 40° C., tetrahydrofuran as an eluent (elution solvent), flow amount (flow rate) of 1.0 mL/min, and polystyrene (manufactured by Showa Denko K. K.) as a standard sample.

The hydrolysis-condensation compound of hydrolyzable silane mixture is prepared by hydrolysis and condensation of the above-described silane compound (hydrolyzable silane).

The above-described silane compound (hydrolyzable silane) contains an alkoxy group, an aralkyloxy group, an acyloxy group, or a halogen atom directly bonded to a silicon atom, that is, an alkoxysilyl group, an aralkyloxysilyl group, an acyloxysilyl group, or a halogenated silyl group, which is a hydrolyzable group.

For the hydrolysis of the hydrolyzable group, ordinarily 0.5 to 100 mol, and preferably 1 to 10 mol of water is used per mol of the hydrolyzable group.

During hydrolysis and condensation, a hydrolysis catalyst may be used for the purpose of promoting the reaction. Alternatively, the hydrolysis and condensation may be performed without use of a hydrolysis catalyst. When a hydrolysis catalyst is used, the amount of the hydrolysis catalyst is ordinarily 0.0001 to 10 mol, and preferably 0.001 to 1 mol per mol of the hydrolyzable group.

The reaction temperature for the hydrolysis and condensation is ordinarily equal to or higher than room temperature, or equal to or lower than the reflux temperature at normal pressure of an organic solvent usable for hydrolysis. The reaction temperature may be, for example, 20 to 110° C., or, for example, 20 to 80° C.

The hydrolysis may be performed completely, that is, all hydrolyzable groups may be converted into silanol groups, or may be performed partially, that is, unreacted hydrolyzable groups may remain.

Examples of the hydrolysis catalyst usable for the hydrolysis and condensation include a metal chelate compound, an organic acid, an inorganic acid, an organic base, and an inorganic base.

Examples of the metal chelate compound as the hydrolysis catalyst include, but are not limited to, titanium chelate compounds such as triethoxy-mono(acetylacetonate)titanium, tri-n-propoxy-mono(acetylacetonate)titanium, tri-i-propoxy-mono(acetylacetonate)titanium, tri-n-butoxy-mono(acetylacetonate)titanium, tri-sec-butoxy-mono(acetylacetonate)titanium, tri-t-butoxy-mono(acetylacetonate)titanium, diethoxy-bis(acetylacetonate)titanium, di-n-propoxy-bis(acetylacetonate)titanium, di-i-propoxy-bis(acetylacetonate)titanium, di-n-butoxy-bis(acetylacetonate)titanium, di-sec-butoxy-bis(acetylacetonate)titanium, di-t-butoxy-bis(acetylacetonate)titanium, monoethoxy-tris(acetylacetonate)titanium, mono-n-propoxy-tris(acetylacetonate)titanium, mono-i-propoxy-tris(acetylacetonate)titanium, mono-n-butoxy-tris(acetylacetonate)titanium, mono-sec-butoxy-tris(acetylacetonate)titanium, mono-t-butoxy-tris(acetylacetonate)titanium, tetrakis(acetylacetonate)titanium, triethoxy-mono(ethyl acetoacetate)titanium, tri-n-propoxy-mono(ethyl acetoacetate)titanium, tri-i-propoxy-mono(ethyl acetoacetate)titanium, tri-n-butoxy-mono(ethyl acetoacetate)titanium, tri-sec-butoxy-mono(ethyl acetoacetate)titanium, tri-t-butoxy-mono(ethyl acetoacetate)titanium, diethoxy-bis(ethyl acetoacetate)titanium, di-n-propoxy-bis(ethyl acetoacetate)titanium, di-i-propoxy-bis(ethyl acetoacetate)titanium, di-n-butoxy-bis(ethyl acetoacetate)titanium, di-sec-butoxy-bis(ethyl acetoacetate)titanium, di-t-butoxy-bis(ethyl acetoacetate)titanium, monoethoxy-tris(ethyl acetoacetate)titanium, mono-n-propoxy-tris(ethyl acetoacetate)titanium, mono-i-propoxy-tris(ethyl acetoacetate)titanium, mono-n-butoxy-tris(ethyl acetoacetate)titanium, mono-sec-butoxy-tris(ethyl acetoacetate)titanium, mono-t-butoxy-tris(ethyl acetoacetate)titanium, tetrakis(ethyl acetoacetate)titanium, mono(acetylacetonate)tris(ethyl acetoacetate)titanium, bis(acetylacetonate)bis(ethyl acetoacetate)titanium, and tris(acetylacetonate) mono(ethyl acetoacetate)titanium; zirconium chelate compounds such as triethoxy-mono(acetylacetonate) zirconium, tri-n-propoxy-mono(acetylacetonate) zirconium, tri-i-propoxy-mono(acetylacetonate) zirconium, tri-n-butoxy-mono(acetylacetonate) zirconium, tri-sec-butoxy-mono(acetylacetonate) zirconium, tri-t-butoxy-mono(acetylacetonate) zirconium, diethoxy-bis(acetylacetonate) zirconium, di-n-propoxy-bis(acetylacetonate) zirconium, di-i-propoxy-bis(acetylacetonate) zirconium, di-n-butoxy-bis(acetylacetonate) zirconium, di-sec-butoxy-bis(acetylacetonate) zirconium, di-t-butoxy-bis(acetylacetonate) zirconium, monoethoxy-tris(acetylacetonate) zirconium, mono-n-propoxy-tris(acetylacetonato) zirconium, mono-i-propoxy-tris(acetylacetonate) zirconium, mono-n-butoxy-tris(acetylacetonate) zirconium, mono-sec-butoxy-tris(acetylacetonate) zirconium, mono-t-butoxy-tris(acetylacetonate) zirconium, tetrakis(acetylacetonate) zirconium, triethoxy-mono(ethyl acetoacetate) zirconium, tri-n-propoxy-mono(ethyl acetoacetate) zirconium, tri-i-propoxy-mono(ethyl acetoacetate) zirconium, tri-n-butoxy-mono(ethyl acetoacetate) zirconium, tri-sec-butoxy-mono(ethyl acetoacetate) zirconium, tri-t-butoxy-mono(ethyl acetoacetate) zirconium, diethoxy-bis(ethyl acetoacetate) zirconium, di-n-propoxy-bis(ethyl acetoacetate) zirconium, di-i-propoxy-bis(ethyl acetoacetate) zirconium, di-n-butoxy-bis(ethyl acetoacetate) zirconium, di-sec-butoxy-bis(ethyl acetoacetate) zirconium, di-t-butoxy-bis(ethyl acetoacetate) zirconium, monoethoxy-tris(ethyl acetoacetate) zirconium, mono-n-propoxy-tris(ethyl acetoacetate) zirconium, mono-i-propoxy-tris(ethyl acetoacetate) zirconium, mono-n-butoxy-tris(ethyl acetoacetate) zirconium, mono-sec-butoxy-tris(ethyl acetoacetate) zirconium, mono-t-butoxy-tris(ethyl acetoacetate) zirconium, tetrakis(ethyl acetoacetate) zirconium, mono(acetylacetonate)tris(ethyl acetoacetate) zirconium, bis(acetylacetonate)bis(ethyl acetoacetate) zirconium, and tris(acetylacetonate) mono(ethyl acetoacetate) zirconium; and aluminum chelate compounds such as tris(acetylacetonate)aluminum and tris(ethyl acetoacetate)aluminum.

Examples of the organic acid as the hydrolysis catalyst include, but are not limited to, acetic acid, propionic acid, butanoic acid, pentanoic acid, hexanoic acid, heptanoic acid, octanoic acid, nonanoic acid, decanoic acid, oxalic acid, maleic acid, methylmalonic acid, adipic acid, sebacic acid, gallic acid, butyric acid, mellitic acid, arachidonic acid, 2-ethylhexanoic acid, oleic acid, stearic acid, linoleic acid, linolenic acid, salicylic acid, benzoic acid, p-aminobenzoic acid, p-toluenesulfonic acid, benzenesulfonic acid, monochloroacetic acid, dichloroacetic acid, trichloroacetic acid, trifluoroacetic acid, formic acid, malonic acid, sulfonic acid, phthalic acid, fumaric acid, citric acid, and tartaric acid.

Examples of the inorganic acid as the hydrolysis catalyst include, but are not limited to, hydrochloric acid, nitric acid, sulfuric acid, hydrofluoric acid, and phosphoric acid.

Examples of the organic base as the hydrolysis catalyst include, but are not limited to, pyridine, pyrrole, piperazine, pyrrolidine, piperidine, picoline, trimethylamine, triethylamine, monoethanolamine, diethanolamine, dimethylmonoethanolamine, monomethyldiethanolamine, triethanolamine, diazabicyclooctane, diazabicyclononane, diazabicycloundecene, tetramethylammonium hydroxide, tetraethylammonium hydroxide, tetrapropylammonium hydroxide, tetrabutylammonium hydroxide, trimethylphenylammonium hydroxide, benzyltrimethylammonium hydroxide, and benzyltriethylammonium hydroxide.

Examples of the inorganic base as the hydrolysis catalyst include, but are not limited to, ammonia, sodium hydroxide, potassium hydroxide, barium hydroxide, and calcium hydroxide.

Among these catalysts, metal chelate compounds, organic acids, and inorganic acids are preferable. These catalysts may be used alone or in combination of two or more types thereof.

In particular, nitric acid can be suitably used as a hydrolysis catalyst in the present invention. The use of nitric acid enables an improvement in the storage stability of a reaction solution after the hydrolysis and condensation, and particularly enables suppression of a change in the molecular weight of a hydrolysis-condensation compound. It is known that the stability of the hydrolysis-condensation compound contained in the solution depends on the pH of the solution. As a result of intensive studies, it has been found that the pH of the solution falls in a stable range by use of an appropriate amount of nitric acid.

When hydrolysis and condensation are performed, an organic solvent may be used as a solvent, and specific examples thereof include, but are not limited to, aliphatic hydrocarbon-based solvents such as n-pentane, i-pentane, n-hexane, i-hexane, n-heptane, i-heptane, 2,2,4-trimethylpentane, n-octane, i-octane, cyclohexane, and methylcyclohexane; aromatic hydrocarbon-based solvents such as benzene, toluene, xylene, ethylbenzene, trimethylbenzene, methylethylbenzene, n-propylbenzene, i-propylbenzene, diethylbenzene, i-butylbenzene, triethylbenzene, di-i-propylbenzene, and n-amylnaphthalene; monoalcohol-based solvents such as methanol, ethanol, n-propanol, i-propanol, n-butanol, i-butanol, sec-butanol, t-butanol, n-pentanol, i-pentanol, 2-methylbutanol, sec-pentanol, t-pentanol, 3-methoxybutanol, n-hexanol, 2-methylpentanol, sec-hexanol, 2-ethylbutanol, n-heptanol, sec-heptanol, 3-heptanol, n-octanol, 2-ethylhexanol, sec-octanol, n-nonyl alcohol, 2,6-dimethyl-4-heptanol, n-decanol, sec-undecyl alcohol, trimethylnonyl alcohol, sec-tetradecyl alcohol, sec-heptadecyl alcohol, phenol, cyclohexanol, methylcyclohexanol, 3,3,5-trimethylcyclohexanol, benzyl alcohol, phenylmethylcarbinol, diacetone alcohol, and cresol; polyhydric alcohol-based solvents such as ethylene glycol, propylene glycol, 1,3-butylene glycol, 2,4-pentanediol, 2-methyl-2,4-pentanediol, 2,5-hexanediol, 2,4-heptanediol, 2-ethyl-1,3-hexanediol, diethylene glycol, dipropylene glycol, triethylene glycol, tripropylene glycol, and glycerin; ketone-based solvents such as acetone, methyl ethyl ketone, methyl-n-propyl ketone, methyl-n-butyl ketone, diethyl ketone, methyl-1-butyl ketone, methyl-n-pentyl ketone, ethyl-n-butyl ketone, methyl-n-hexyl ketone, di-i-butyl ketone, trimethylnonanone, cyclohexanone, methylcyclohexanone, 2,4-pentanedione, acetonylacetone, diacetone alcohol, acetophenone, and fenchon; ether-based solvents such as ethyl ether, i-propyl ether, n-butyl ether, n-hexyl ether, 2-ethylhexyl ether, ethylene oxide, 1,2-propylene oxide, dioxolane, 4-methyldioxolane, dioxane, dimethyldioxane, ethylene glycol monomethyl ether, ethylene glycol monoethyl ether, ethylene glycol diethyl ether, ethylene glycol mono-n-butyl ether, ethylene glycol mono-n-hexyl ether, ethylene glycol monophenyl ether, ethylene glycol mono-2-ethyl butyl ether, ethylene glycol dibutyl ether, diethylene glycol monomethyl ether, diethylene glycol monoethyl ether, diethylene glycol diethyl ether, diethylene glycol mono-n-butyl ether, diethylene glycol di-n-butyl ether, diethylene glycol mono-n-hexyl ether, ethoxy triglycol, tetraethylene glycol di-n-butyl ether, propylene glycol monomethyl ether (1-methoxy-2-propanol), propylene glycol monoethyl ether (1-ethoxy-2-propanol), propylene glycol monopropyl ether, propylene glycol monobutyl ether, propylene glycol monomethyl ether acetate (1-methoxy-2-propanol monoacetate), dipropylene glycol monomethyl ether, dipropylene glycol monoethyl ether, dipropylene glycol monopropyl ether, dipropylene glycol monobutyl ether, tripropylene glycol monomethyl ether, tetrahydrofuran, and 2-methyltetrahydrofuran; ester-based solvents such as diethyl carbonate, methyl acetate, ethyl acetate, γ-butyrolactone, γ-valerolactone, n-propyl acetate, i-propyl acetate, n-butyl acetate, i-butyl acetate, sec-butyl acetate, n-pentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, n-nonyl acetate, methyl acetoacetate, ethyl acetoacetate, ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate, propylene glycol monoethyl ether acetate, propylene glycol monopropyl ether acetate, propylene glycol monobutyl ether acetate, dipropylene glycol monomethyl ether acetate, dipropylene glycol monoethyl ether acetate, glycol diacetate, methoxytriglycol acetate, ethylene glycol diacetate, triethylene glycol methyl ether acetate, ethyl propionate, n-butyl propionate, i-amyl propionate, diethyl oxalate, di-n-butyl oxalate, methyl lactate, ethyl lactate, n-butyl lactate, n-amyl lactate, diethyl malonate, dimethyl phthalate, and diethyl phthalate; nitrogen-containing solvents such as N-methylformamide, N,N-dimethylformamide, N,N-diethylformamide, acetamide, N-methylacetamide, N,N-dimethylacetamide, N-methylpropionamide, and N-methyl-2-pyrrolidone; and sulfur-containing solvents such as dimethyl sulfide, diethyl sulfide, thiophene, tetrahydrothiophene, dimethyl sulfoxide, sulfolane, and 1,3-propane sultone. These solvents can be used alone or in combination of two or more types thereof.

After completion of the hydrolysis and condensation reactions, the reaction solution is used as is, or diluted or concentrated. The obtained reaction solution can be neutralized or treated with an ion exchange resin, and thus the hydrolysis catalyst, such as an acid or a base, used for the hydrolysis and condensation can be removed. Before or after such a treatment, alcohols: by-products, water, the used hydrolysis catalyst, and the like can be removed from the reaction solution, for example, by distillation under reduced pressure.

The hydrolysis-condensation compound obtained in this manner (hereinafter, also referred to as “polysiloxane”) is in the form of a polysiloxane varnish dissolved in an organic solvent, which may be used as is for preparation of the silicon-containing resist underlayer film-forming composition. That is, the reaction solution may be used as is (or diluted) for preparation of the silicon-containing resist underlayer film-forming composition. In this case, the hydrolysis catalyst used for the hydrolysis and condensation, by-products, and the like may remain in the reaction solution as long as the effects of the present invention is not impaired. For example, nitric acid used as a hydrolysis catalyst or used for capping of silanol groups with an alcohol may remain in the polymer varnish solution in an amount of about 100 ppm to 5,000 ppm.

The obtained polysiloxane varnish may be subjected to solvent replacement, or may be appropriately diluted with a solvent. When the storage stability of the obtained polysiloxane varnish is not poor, the organic solvent may be distilled off to achieve a film-forming component concentration of 100%. The film-forming component refers to a component obtained by removing a solvent component from all the components of the composition.

The organic solvent used for solvent replacement, dilution, or the like of the polysiloxane varnish may be identical to or different from the organic solvent used for the hydrolysis and condensation reactions of the hydrolyzable silane. The solvent for dilution is not particularly limited, and one type or two or more types of solvents may be selected and used in any manner.

The silicon-containing resist underlayer film-forming composition of the present invention can contain a solvent, a curing catalyst, nitric acid, an amine, a hydroxide, and other components in addition to the hydrolysis-condensation compound (polysiloxane) of the hydrolyzable silane mixture.

### <Solvent>

The solvent used in the silicon-containing resist underlayer film-forming composition of the present invention can be used without particular limitation as long as the solvent is a solvent capable of dissolving the solid content in the resist underlayer film-forming composition.

Such a solvent is not limited as long as the solvent dissolves other components such as the hydrolysis-condensation compound of the hydrolyzable silane mixture and the curing catalyst.

The solvent is preferably an alcohol-based solvent, more preferably alkylene glycol monoalkyl ether which is alcohol-based solvent, and still more preferably propylene glycol monoalkyl ether. Since these solvents are also capping agents for silanol groups of the polysiloxane, the solvent replacement or the like is not required. The silicon-containing resist underlayer film-forming composition can be prepared from a solution obtained by preparation of the polysiloxane.

Examples of the alkylene glycol monoalkyl ether include ethylene glycol monomethyl ether, ethylene glycol monoethyl ether, ethylene glycol monopropyl ether, ethylene glycol monobutyl ether, propylene glycol monomethyl ether (1-methoxy-2-propanol), propylene glycol monoethyl ether (1-ethoxy-2-propanol), methyl isobutyl carbinol, and propylene glycol monobutyl ether.

Examples of other solvents include methyl cellosolve acetate, ethyl cellosolve acetate, propylene glycol, propylene glycol monomethyl ether (1-methoxy-2-propanol), propylene glycol monoethyl ether (1-ethoxy-2-propanol), methyl isobutyl carbinol, propylene glycol monobutyl ether, propylene glycol monomethyl ether acetate (1-methoxy-2-propanol monoacetate), propylene glycol monoethyl ether acetate, propylene glycol monopropyl ether acetate, propylene glycol monobutyl ether acetate, toluene, xylene, methyl ethyl ketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropionate, ethyl 3-methoxypropionate, ethyl 3-ethoxypropionate, methyl 3-ethoxypropionate, methyl pyruvate, ethyl pyruvate, ethylene glycol monomethyl ether, ethylene glycol monoethyl ether, ethylene glycol monopropyl ether, ethylene glycol monobutyl ether, ethylene glycol monomethyl ether acetate, ethylene glycol monoethyl ether acetate, ethylene glycol monopropyl ether acetate, ethylene glycol monobutyl ether acetate, diethylene glycol dimethyl ether, diethylene glycol diethyl ether, diethylene glycol dipropyl ether, diethylene glycol dibutyl ether propylene glycol monomethyl ether, propylene glycol dimethyl ether, propylene glycol diethyl ether, propylene glycol dipropyl ether, propylene glycol dibutyl ether, ethyl lactate, propyl lactate, isopropyl lactate, butyl lactate, isobutyl lactate, methyl formate, ethyl formate, propyl formate, isopropyl formate, butyl formate, isobutyl formate, amyl formate, isoamyl formate, methyl acetate, ethyl acetate, amyl acetate, isoamyl acetate, hexyl acetate, methyl propionate, ethyl propionate, propyl propionate, isopropyl propionate, butyl propionate, isobutyl propionate, methyl butyrate, ethyl butyrate, propyl butyrate, isopropyl butyrate, butyl butyrate, isobutyl butyrate, ethyl hydroxyacetate, methyl 2-hydroxy-2-methylpropionate, methyl 3-methoxy-2-methylpropionate, methyl 2-hydroxy-3-methylbutyrate, ethyl methoxyacetate, ethyl ethoxyacetate, methyl 3-methoxypropionate, ethyl 3-ethoxypropionate, ethyl 3-methoxypropionate, 3-methoxybutyl acetate, 3-methoxypropyl acetate, 3-methyl-3-methoxybutyl acetate, 3-methyl-3-methoxybutylpropionate, 3-methyl-3-methoxybutylbutyrate, methyl acetoacetate, toluene, xylene, methyl ethyl ketone, methyl propyl ketone, methyl butyl ketone, 2-heptanone, 3-heptanone, 4-heptanone, cyclohexanone, N,N-dimethylformamide, N-methylacetamide, N,N-dimethylacetamide, N-methyl-2-pyrrolidone, 4-methyl-2-pentanol, and γ-butyrolactone. The solvent may be used alone or in combination of two or more types thereof.

The silicon-containing resist underlayer film-forming composition of the present invention may contain water as a solvent. When water is contained as the solvent, the content thereof may be, for example, 30 mass % or less, preferably 20 mass % or less, and still more preferably 15 mass % or less relative to the total mass of the solvent contained in the composition.

### <Curing Catalyst>

The curing catalyst may be, for example, an ammonium salt, a phosphine compound, a phosphonium salt, or a sulfonium salt. The salts described below as curing catalysts may be added in the form of a salt, or may be substances that form a salt in the composition (that is, substances added as separate compounds at the time of addition and form a salt in the system).

Examples of the ammonium salt include a quaternary ammonium salt having a structure represented by Formula (D-1):

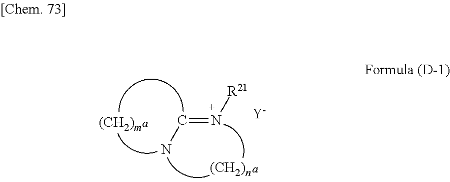

(in the formula, m^{a} represents an integer of 2 to 11, n^{a} represents an integer of 2 to 3, R²¹ represents an alkyl group, an aryl group, or an aralkyl group, and Y⁻ represents an anion);
a quaternary ammonium salt having a structure represented by Formula (D-2):

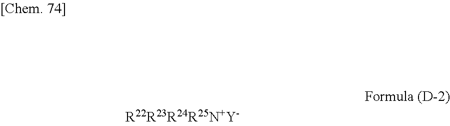

(in the formula, R²², R²³, R²⁴, and R²⁵ each independently represent an alkyl group, an aryl group, or an aralkyl group, Y⁻ represents an anion, and R²², R²³, R²⁴, and R²⁵ are each bonded to the nitrogen atom);
a quaternary ammonium salt having a structure represented by Formula (D-3):

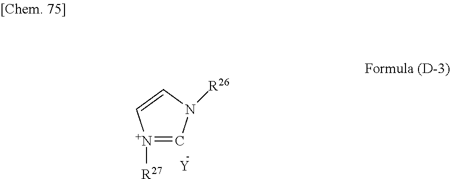

(in the formula, R²⁶ and R²⁷ each independently represent an alkyl group, an aryl group, or an aralkyl group, and Y⁻ represents an anion);
a quaternary ammonium salt having a structure represented by Formula (D-4):

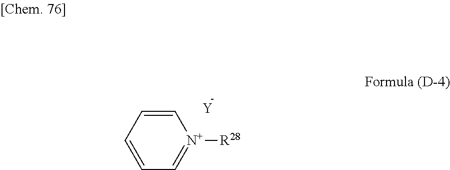

(in the formula, R²⁸ represents an alkyl group, an aryl group, or an aralkyl group, and Y-represents an anion);
a quaternary ammonium salt having a structure represented by Formula (D-5):

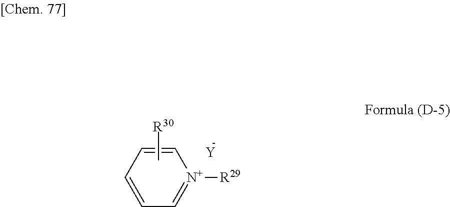

(in the formula, R²⁹ and R³⁰ each independently represent an alkyl group, an aryl group, or an aralkyl group, and Y⁻ represents an anion); and
a tertiary ammonium salt having a structure represented by Formula (D-6):

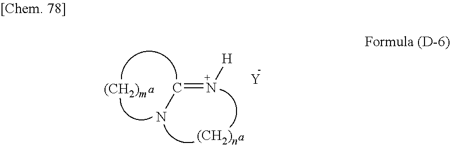

(in the formula, m^{a} represents an integer of 2 to 11, n^{a} represents an integer of 2 to 3, and Y⁻ represents an anion).

Examples of the phosphonium salt include a quaternary phosphonium salt represented by the following Formula (D-7):

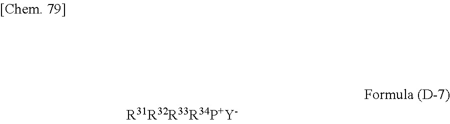

(in Formula, R³¹, R³², R³³, and R³⁴ each independently represent an alkyl group, an aryl group, or an aralkyl group, Y⁻ represents an anion, and each of R³¹, R³², R³³, and R³⁴ is bonded to the phosphorus atom).

Examples of the sulfonium salt include a tertiary sulfonium salt represented by the following Formula (D-8):

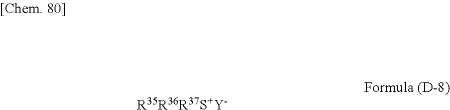

(in the formula, R³⁵, R³⁶, and R³⁷ each independently represent an alkyl group, an aryl group, or an aralkyl group, Y⁻ represents an anion, and each of R³⁵, R³⁶, and R³⁷ is bonded to the sulfur atom).

The compound of Formula (D-1) is a quaternary ammonium salt derived from an amine, where m^{a} represents an integer of 2 to 11, and n^{a} represents an integer of 2 to 3. R²¹ of the quaternary ammonium salt represents, for example, an alkyl group having 1 to 18 carbon atoms, preferably 2 to 10 carbon atoms, an aryl group having 6 to 18 carbon atoms, or an aralkyl group having 7 to 18 carbon atoms. Examples thereof include linear alkyl groups such as an ethyl group, a propyl group, and a butyl group; a benzyl group, a cyclohexyl group, a cyclohexylmethyl group, and a dicyclopentadienyl group. Further, examples of the anion (Y⁻) include halide ions such as chlorine ion (Cl⁻), bromine ion (Br⁻), and iodine ion (I⁻); and acid groups such as carboxylate (—COO⁻), sulfonate (—SO₃⁻), and alkoxide (—O⁻).

The compound of Formula (D-2) is a quaternary ammonium salt represented by R²²R²³R²⁴R²⁵N⁺Y⁻. R²², R²³, R²⁴, and R²⁵ of the quaternary ammonium salt are each, for example, an alkyl group having 1 to 18 carbon atoms such as an ethyl group, a propyl group, a butyl group, a cyclohexyl group, and a cyclohexylmethyl group; an aryl group having 6 to 18 carbon atoms such as a phenyl group; or an aralkyl group having 7 to 18 carbon atoms such as a benzyl group. Examples of the anion (Y⁻) include halide ions such as chlorine ion (Cl⁻), bromine ion (Br⁻), and iodine ion (I⁻); and acid groups such as carboxylate (—COO⁻), sulfonate (—SO₃⁻), and alkoxide (—O⁻). The quaternary ammonium salt is commercially available, and examples of the quaternary ammonium salt include tetramethylammonium acetate, tetrabutylammonium acetate, triethylbenzylammonium chloride, triethylbenzylammonium bromide, trioctylmethylammonium chloride, tributylbenzylammonium chloride, and trimethylbenzylammonium chloride.

The compound of Formula (D-3) is a quaternary ammonium salt derived from 1-substituted imidazole. The number of carbon atoms of each of R²⁶ and R²⁷ is, for example, 1 to 18, and the total number of carbon atoms of R²⁶ and R²⁷ is preferably 7 or more. Examples of R²⁶ include alkyl groups such as a methyl group, an ethyl group, and a propyl group; and aryl groups such as a phenyl group. Examples of R²⁷ include aralkyl groups such as a benzyl group; and alkyl groups such as an octyl group and an octadecyl group. Examples of the anion (Y⁻) include halide ions such as chlorine ion (Cl⁻), bromine ion (Br⁻), and iodine ion (I⁻); and acid groups such as carboxylate (—COO⁻), sulfonate (—SO₃⁻), and alkoxide (—O⁻). Although this compound is commercially available, the compound may be produced, for example, by reacting an imidazole-based compound (for example, 1-methylimidazole or 1-benzylimidazole) with halogenated aralkyl, halogenated alkyl, or halogenated aryl such as benzyl bromide, methyl bromide, or benzene bromide.

The compound of Formula (D-4) is a quaternary ammonium salt derived from pyridine. R²⁸ is, for example, an alkyl group having 1 to 18 carbon atoms, preferably 4 to 18 carbon atoms, an aryl group having 6 to 18 carbon atoms, or an aralkyl group having 7 to 18 carbon atoms. Examples thereof include a butyl group, an octyl group, a benzyl group, and a lauryl group. Examples of the anion (Y⁻) include halide ions such as chlorine ion (Cl⁻), bromine ion (Br⁻), and iodine ion (I⁻); and acid groups such as carboxylate (—COO⁻), sulfonate (—SO₃⁻), and alkoxide (—O⁻). Although this compound is commercially available, the compound may be produced, for example, by reacting pyridine with a halogenated alkyl or halogenated aryl such as lauryl chloride, benzyl chloride, benzyl bromide, methyl bromide, or octyl bromide. Examples of this compound include N-laurylpyridinium chloride and N-benzylpyridinium bromide.

The compound of Formula (D-5) is a quaternary ammonium salt derived from a substituted pyridine, such as picoline. R²⁹ is, for example, an alkyl group having 1 to 18 carbon atoms, preferably 4 to 18 carbon atoms, an aryl group having 6 to 18 carbon atoms, or an aralkyl group having 7 to 18 carbon atoms. Examples thereof include a methyl group, an octyl group, a lauryl group, and a benzyl group. R³⁰ is, for example, an alkyl group having 1 to 18 carbon atoms, an aryl group having 6 to 18 carbon atoms, or an aralkyl group having 7 to 18 carbon atoms. For example, R³⁰ is a methyl group when the compound represented by Formula (D-5) is a quaternary ammonium derived from picoline. Examples of the anion (Y⁻) include halide ions such as chlorine ion (Cl⁻), bromine ion (Br⁻), and iodine ion (I⁻); and acid groups such as carboxylate (—COO⁻), sulfonate (—SO₃⁻), and alkoxide (—O⁻). Although this compound is commercially available, the compound may be produced, for example, by reacting a substituted pyridine (for example, picoline) with an alkyl halide or an aryl halide, such as methyl bromide, octyl bromide, lauryl chloride, benzyl chloride, or benzyl bromide. Examples of this compound include N-benzylpicolinium chloride, N-benzylpicolinium bromide, and N-laurylpicolinium chloride.

The compound of Formula (D-6) is a tertiary ammonium salt derived from an amine, where m^{a} represents an integer of 2 to 11, and n^{a} represents 2 or 3. Further, examples of the anion (Y⁻) include halide ions such as chlorine ion (Cl⁻), bromine ion (Br⁻), and iodine ion (I⁻); and acid groups such as carboxylate (—COO⁻), sulfonate (—SO₃⁻), and alkoxide (—O⁻). The compound may be produced by reacting an amine with a weak acid, such as a carboxylic acid or phenol. Examples of the carboxylic acid include formic acid and acetic acid. When formic acid is used, the anion (Y⁻) is (HCOO⁻). When acetic acid is used, the anion (Y⁻) is (CH₃COO⁻). When phenol is used, the anion (Y⁻) is (C₆H₅O⁻).

The compound of Formula (D-7) is a quaternary phosphonium salt having a structure of R³¹R³²R³³R³⁴P⁺Y⁻. R³¹, R³², R³³, and R³⁴ are each, for example, an alkyl group having 1 to 18 carbon atoms such as an ethyl group, a propyl group, a butyl group, or a cyclohexylmethyl, an aryl group having 6 to 18 carbon atoms such as phenyl group, or an aralkyl group having 7 to 18 carbon atoms such as a benzyl group. Three of four substituents of R³¹ to R³⁴ are each preferably an unsubstituted phenyl group or a substituted phenyl group. Examples thereof include a phenyl group or a tolyl group. The remaining one substituent is an alkyl group having 1 to 18 carbon atoms, an aryl group having 6 to 18 carbon atoms, or an aralkyl group having 7 to 18 carbon atoms. Further, examples of the anion (Y⁻) include halide ions such as chlorine ion (Cl⁻), bromine ion (Br⁻), and iodine ion (I⁻); and acid groups such as carboxylate (—COO⁻), sulfonate (—SO₃⁻), and alkoxide (—O⁻). This compound is commercially available, and examples of the compound include halogenated tetraalkylphosphonium compounds such as halogenated tetra-n-butylphosphonium and halogenated tetra-n-propylphosphonium; halogenated trialkylbenzylphosphonium compounds such as halogenated triethylbenzylphosphonium; halogenated triphenylmonoalkylphosphonium compounds such as halogenated triphenylmethylphosphonium and halogenated triphenylethylphosphonium; halogenated triphenylbenzylphosphonium; halogenated tetraphenylphosphonium; halogenated tritylmonoarylphosphonium; or halogenated tritylmonoalkylphosphonium (above, the halogen atom is a chlorine atom or a bromine atom). Particularly preferred are halogenated triphenylmonoalkylphosphonium compounds such as halogenated triphenylmethylphosphonium and halogenated triphenylethylphosphonium; halogenated triphenylmonoarylphosphonium compounds such as halogenated triphenylbenzylphosphonium; halogenated tritylmonoarylphosphonium compounds such as halogenated tritylmonophenylphosphonium; and halogenated tritylmonoalkylphosphonium compounds such as halogenated tritylmethylphosphonium (the halogen atom is a chlorine atom or a bromine atom).

Examples of the phosphine compound include primary phosphines such as methylphosphine, ethylphosphine, propylphosphine, isopropylphosphine, isobutylphosphine, and phenylphosphine; secondary phosphines such as dimethylphosphine, diethylphosphine, diisopropylphosphine, diisoamylphosphine, and diphenylphosphine; and tertiary phosphines such as trimethylphosphine, triethylphosphine, triphenylphosphine, methyldiphenylphosphine, and dimethylphenylphosphine.

The compound of Formula (D-8) is a tertiary sulfonium salt having a structure of R³⁵R³⁶R³⁷S⁺Y⁻. R³⁵, R³⁶, and R³⁷ are each, for example, an alkyl group having 1 to 18 carbon atoms such as an ethyl group, a propyl group, a butyl group, or a cyclohexylmethyl; an aryl group having 6 to 18 carbon atoms such as a phenyl group; or an aralkyl group having 7 to 18 carbon atoms such as a benzyl group. Two of three substituents of R³⁵ to R³⁷ are each preferably an unsubstituted phenyl group or a substituted phenyl group. Examples thereof include a phenyl group or a tolyl group. The remaining one substituent is an alkyl group having 1 to 18 carbon atoms, an aryl group having 6 to 18 carbon atoms, or an aralkyl group having 7 to 18 carbon atoms. Examples of the anion (Y⁻) include halide ions such as chlorine ion (Cl⁻), bromine ion (Br⁻), or iodine ion (I⁻); and acid groups such as carboxylate (—COO⁻), sulfonate (—SO₃⁻), alkoxide (—O—), maleate anion, or nitrate anion. This compound is commercially available, and examples of the compound include halogenated trialkylsulfonium compounds such as halogenated tri-n-butylsulfonium and halogenated tri-n-propylsulfonium; halogenated dialkylbenzylsulfonium compounds such as halogenated diethylbenzylsulfonium; halogenated diphenylmonoalkylsulfonium compounds such as halogenated diphenylmethylsulfonium and halogenated diphenylethylsulfonium; and halogenated triphenylsulfonium (above, the halogen atom is a chlorine atom or a bromine atom). Further examples include trialkylsulfonium carboxylates such as tri-n-butylsulfonium carboxylate and tri-n-propylsulfonium carboxylate; dialkylbenzylsulfonium carboxylates such as diethylbenzylsulfonium carboxylate; diphenylmonoalkylsulfonium carboxylates such as diphenylmethylsulfonium carboxylate and diphenylethylsulfonium carboxylate; and triphenylsulfonium carboxylate. In addition, halogenated triphenylsulfonium and triphenylsulfonium carboxylate can be preferably used.

In addition, a nitrogen-containing silane compound may be added as a curing catalyst. Examples of the nitrogen-containing silane compound include silane compounds containing an imidazole ring such as N-(3-triethoxysilylpropyl)-4,5-dihydroimidazole.

When a curing catalyst is used, the content is preferably 0.1 to 30 parts by mass, more preferably 0.5 to 25 parts by mass, and still more preferably 1 to 20 parts by mass with respect to 100 parts by mass of the polysiloxane.

### <Nitric Acid>

The silicon-containing resist underlayer film-forming composition preferably contains nitric acid.

Nitric acid may be added during preparation of the silicon-containing resist underlayer film-forming composition. Alternatively, nitric acid may be used as a hydrolysis catalyst or used for capping of silanol groups with an alcohol in the production of the polysiloxane described above, and may remain in the polysiloxane varnish.

The amount of the nitric acid (amount of residual nitric acid) added may be, for example, 0.0001 mass % to 1 mass %, 0.001 mass % to 0.1 mass %, or 0.005 mass % to 0.05 mass % relative to the total mass of the silicon-containing resist underlayer film-forming composition.

### <Amine and Hydroxide>

The silicon-containing resist underlayer film-forming composition preferably contains at least one selected from amine and hydroxide from the viewpoint of more sufficiently achieving the effects of the present invention.

Examples of the amine include ammonia; primary amines such as monomethanolamine, monoethanolamine, monopropanolamine, methylamine, ethylamine, propylamine, and butylamine; secondary amines such as dimethylamine, ethylmethylamine, and diethylamine; tertiary amines such as trimethylamine, triethylamine, tripropylamine, dimethylethylamine, methyldiisopropylamine, diisopropylethylamine, diethylethanolamine, and triethanolamine; amines such as ethylenediamine and tetramethylethylenediamine; and cyclic amines such as pyridine and morpholine.

Examples of the hydroxide include an inorganic alkali hydroxide and an organic alkali hydroxide.

Examples of the inorganic alkali hydroxide include sodium hydroxide and potassium hydroxide.

Examples of the organic alkali hydroxide include tetraalkylammonium hydroxide, triarylsulfonium hydroxide, and diaryliodonium hydroxide. Examples of the tetraalkylammonium hydroxide include tetramethylammonium hydroxide, tetraethylammonium hydroxide, and tetrabutylammonium hydroxide. Examples of the triarylsulfonium hydroxide include triphenylsulfonium hydroxide and tris(t-butylphenyl) sulfonium hydroxide. Examples of the diaryliodonium hydroxide include diphenyliodonium hydroxide and bis(t-butylphenyl) iodonium hydroxide.

The content of the amine and hydroxide components in the silicon-containing resist underlayer film-forming composition may be preferably 0.05 to 20 parts by mass, more preferably 0.1 to 15 parts by mass, and still more preferably 0.5 to 10 parts by mass, relative to 100 parts by mass of the polysiloxane.

### <Other Components (Other Additives)>

In the silicon-containing resist underlayer film-forming composition of the present invention, various additives (also referred to as other additives) as other components can be incorporated depending on the use of the composition.

Examples of other components (other additives), which may be incorporated into the resist underlayer film-forming composition, include known additives incorporated in materials (compositions) for forming various films (for example, resist underlayer film, bottom anti-reflective coating, and pattern reversing film) that can be used in the production of a semiconductor device, such as a crosslinking agent, a crosslinking catalyst, a stabilizer (for example, an organic acid, water, or an alcohol), an organic polymer, an acid generator, a surfactant (for example, a nonionic surfactant, an anionic surfactant, a cationic surfactant, a silicon-based surfactant, a fluorine-based surfactant, or an UV-curable surfactant), a pH adjuster, a metal oxide, a rheology modifier, and an adhesion aid.

Hereinafter, various additives will be exemplified, but the additives are not limited thereto.

### <<Stabilizer>>

The stabilizer may be added for the purpose of stabilizing the hydrolysis-condensation compound of the hydrolyzable silane mixture, or the like, and specific examples thereof include organic acids, water, alcohols, or combinations thereof.

Examples of the organic acid include oxalic acid, malonic acid, methylmalonic acid, succinic acid, maleic acid, malic acid, tartaric acid, phthalic acid, citric acid, glutaric acid, lactic acid, and salicylic acid. Among these organic acids, oxalic acid and maleic acid are preferable. When the organic acid is added, the amount of the organic acid added is 0.1 to 5.0 mass % relative to the mass of the hydrolysis-condensation compound of the hydrolyzable silane mixture. These organic acids may also serve as pH adjusters.

As the water, pure water, ultrapure water, ion exchanged water, or the like may be used. When pure water, ultrapure water, or ion exchanged water is used, the amount of the water added can be 1 parts by mass to 20 parts by mass relative to 100 parts by mass of the resist underlayer film-forming composition.

The alcohol is preferably an alcohol that easily dissipates (volatilizes) when heated after the coating, and examples of the alcohol include methanol, ethanol, propanol, i-propanol, and butanol. When an alcohol is added, the amount of the alcohol added may be 1 parts by mass to 20 parts by mass relative to 100 parts by mass of the resist underlayer film-forming composition.

### <<Organic Polymer>>

Addition of the organic polymer to the resist underlayer film-forming composition enables adjustment of the dry etching rate (the amount of reduction in film thickness per unit time), attenuation coefficient, refractive index, and the like of a film (resist underlayer film) formed from the composition. The organic polymer compound is not particularly limited, and is appropriately selected from various organic polymers (condensation polymer and addition polymerization polymer) depending on the purpose of addition thereof.

Specific examples of the organic polymer include addition polymerization polymers and condensation polymers, such as polyester, polystyrene, polyimide, acrylic polymer, methacrylic polymer, polyvinyl ether, phenol novolac, naphthol novolac, polyether, polyamide, and polycarbonate.

In the present invention, an organic polymer containing an aromatic ring or a heteroaromatic ring such as a benzene ring, a naphthalene ring, an anthracene ring, a triazine ring, a quinoline ring, or a quinoxaline ring, which functions as a light absorption site, can also be suitably used when such a function is required. Specific examples of such an organic polymer compound include, but are not limited to, addition polymerization polymers containing, as structural units, addition polymerizable monomers such as benzyl acrylate, benzyl methacrylate, phenyl acrylate, naphthyl acrylate, anthryl methacrylate, anthryl methyl methacrylate, styrene, hydroxystyrene, benzyl vinyl ether, and N-phenylmaleimide, and condensation polymers such as phenol novolac and naphthol novolac.

When an addition polymerization polymer is used as an organic polymer compound, the polymer compound may be either a homopolymer or a copolymer.

An addition polymerizable monomer is used for the production of the addition polymerization polymer. Specific examples of the addition polymerizable monomer include, but are not limited to, acrylic acid, methacrylic acid, an acrylate ester compound, a methacrylic acid ester compound, an acrylamide compound, a methacrylamide compound, a vinyl compound, a styrene compound, a maleimide compound, maleic anhydride, and acrylonitrile.

Specific examples of the acrylate ester compound include, but are not limited to, methyl acrylate, ethyl acrylate, normal hexyl acrylate, i-propyl acrylate, cyclohexyl acrylate, benzyl acrylate, phenyl acrylate, anthrylmethyl acrylate, 2-hydroxyethyl acrylate, 3-chloro-2-hydroxypropyl acrylate, 2-hydroxypropyl acrylate, 2,2,2-trifluoroethyl acrylate, 2,2,2-trichloroethyl acrylate, 2-bromoethyl acrylate, 4-hydroxybutyl acrylate, 2-methoxyethyl acrylate, tetrahydrofurfuryl acrylate, 2-methyl-2-adamantyl acrylate, 5-acryloyloxy-6-hydroxynorbornene-2-carboxylic-6-lactone, 3-acryloxypropyltriethoxysilane, and glycidyl acrylate.

Specific examples of the methacrylic acid ester compound include, but are not limited to, methyl methacrylate, ethyl methacrylate, normal hexyl methacrylate, i-propyl methacrylate, cyclohexyl methacrylate, benzyl methacrylate, phenyl methacrylate, anthrylmethyl methacrylate, 2-hydroxyethyl methacrylate, 2-hydroxypropyl methacrylate, 2,2,2-trifluoroethyl methacrylate, 2,2,2-trichloroethyl methacrylate, 2-bromoethyl methacrylate, 4-hydroxybutyl methacrylate, 2-methoxyethyl methacrylate, tetrahydrofurfuryl methacrylate, 2-methyl-2-adamantyl methacrylate, 5-methacryloyloxy-6-hydroxynorbornene-2-carboxylic-6-lactone, 3-methacryloxypropyltriethoxysilane, glycidyl methacrylate, 2-phenylethyl methacrylate, hydroxyphenyl methacrylate, and bromophenyl methacrylate.

Specific examples of the acrylamide compound include, but are not limited to, acrylamide, N-methylacrylamide, N-ethylacrylamide, N-benzylacrylamide, N-phenylacrylamide, N,N-dimethylacrylamide, and N-anthrylacrylamide.

Specific examples of the methacrylamide compound include, but are not limited to, methacrylamide, N-methylmethacrylamide, N-ethylmethacrylamide, N-benzylmethacrylamide, N-phenylmethacrylamide, N,N-dimethylmethacrylamide, and N-anthrylmethacrylamide.

Specific examples of the vinyl compound include, but are not limited to, vinyl alcohol, 2-hydroxyethyl vinyl ether, methyl vinyl ether, ethyl vinyl ether, benzyl vinyl ether, vinyl acetic acid, vinyltrimethoxysilane, 2-chloroethyl vinyl ether, 2-methoxyethyl vinyl ether, vinylnaphthalene, and vinylanthracene.

Specific examples of the styrene compound include, but are not limited to, styrene, hydroxystyrene, chlorostyrene, bromostyrene, methoxystyrene, cyanostyrene, and acetylstyrene.

Examples of the maleimide compound include, but are not limited to, maleimide, N-methylmaleimide, N-phenylmaleimide, N-cyclohexylmaleimide, N-benzylmaleimide, and N-hydroxyethylmaleimide.

When a condensation polymer is used as the polymer, the polymer is, for example, a condensation polymer composed of a glycol compound and a dicarboxylic acid compound. Examples of the glycol compound include diethylene glycol, hexamethylene glycol, and butylene glycol. Examples of the dicarboxylic acid compound include succinic acid, adipic acid, terephthalic acid, and maleic anhydride. Further, examples of the polymer include, but are not limited to, polyesters, polyamides, and polyimides, such as polypyromellitimide, poly(p-phenyleneterephthalamide), polybutylene terephthalate, and polyethylene terephthalate.

When the organic polymer compound contains a hydroxy group, the hydroxy group may be crosslinked with a hydrolysis-condensation compound, or the like.

The organic polymer compound may ordinarily have a weight-average molecular weight of 1,000 to 1,000,000. From the viewpoint of sufficiently achieving the effect of the polymer function and suppressing the precipitation of the polymer in the composition, the weight-average molecular weight of the organic polymer compound to be incorporated may be, for example, 3,000 to 300,000, 5,000 to 300,000, or 10,000 to 200,000.

The organic polymer compound may be used alone or in combination of two or more types thereof.

When the silicon-containing resist underlayer film-forming composition of the present invention contains an organic polymer compound, the content of the organic polymer compound cannot be uniformly specified, since the content should be appropriately determined in consideration of the function of the organic polymer compound or the like. Ordinarily, the content may be 1 to 200 mass % relative to the mass of the hydrolysis-condensation compound of the hydrolyzable silane mixture. From the viewpoint of suppressing the precipitation of the organic polymer compound in the composition and the like, the content may be, for example, 100 mass % or less, preferably 50 mass % or less, and more preferably 30 mass % or less. From the viewpoint of sufficiently achieving the effect of the polymer compound and the like, the content may be, for example, 5 mass % or more, preferably 10 mass % or more, and more preferably 30 mass % or more.

### <<Acid Generator>>

Examples of the acid generator include a thermal acid generator and a photoacid generator, and a photoacid generator may be preferably used.

Examples of the photoacid generator include, but are not limited to, an onium salt compound, a sulfonimide compound, and a disulfonyldiazomethane compound.

Examples of the thermal acid generator include, but are not limited to, tetramethylammonium nitrate.

Specific examples of the onium salt compound include, but are not limited to, iodonium salt compounds such as diphenyliodonium hexafluorophosphate, diphenyliodonium trifluoromethanesulfonate, diphenyliodonium nonafluoro normal butanesulfonate, diphenyliodonium perfluoro normal octanesulfonate, diphenyliodonium camphorsulfonate, bis(4-t-butylphenyl) iodonium camphorsulfonate, and bis(4-t-butylphenyl) iodonium trifluoromethanesulfonate; and sulfonium salt compounds such as triphenylsulfonium hexafluoroantimonate, triphenylsulfonium nonafluoro normal butanesulfonate, triphenylsulfonium camphorsulfonate, triphenylsulfonium trifluoromethanesulfonate, triphenylsulfonium nitrate, triphenylsulfonium trifluoroacetate, triphenylsulfonium maleate, and triphenylsulfonium chloride.

Specific examples of the sulfonimide compound include, but are not limited to, N-(trifluoromethanesulfonyloxy)succinimide, N-(nonafluoronormalbutanesulfonyloxy)succinimide, N-(camphorsulfonyloxy)succinimide, and N-(trifluoromethanesulfonyloxy)naphthalimide.

Specific examples of the disulfonyl diazomethane compound include, but are not limited to, bis(trifluoromethylsulfonyl)diazomethane, bis(cyclohexylsulfonyl)diazomethane, bis(phenylsulfonyl)diazomethane, bis(p-toluenesulfonyl)diazomethane, bis(2,4-dimethylbenzenesulfonyl)diazomethane, and methylsulfonyl-p-toluenesulfonyl diazomethane.

When the silicon-containing resist underlayer film-forming composition contains an acid generator, the content of the acid generator cannot be uniformly specified, since the content should be appropriately determined in consideration of the type of the acid generator or the like. Ordinarily, the content of the acid generator is 0.01 to 5 mass % relative to the mass of the hydrolysis-condensation compound of the hydrolyzable silane mixture. From the viewpoint of suppressing the precipitation of the acid generator in the composition and the like, the content is preferably 3 mass % or less, and more preferably 1 mass % or less. From the viewpoint of sufficiently obtaining the effect of the acid generator and the like, the content is preferably 0.1 mass % or more, more preferably 0.5 mass % or more.

The acid generators may be used alone or in combination of two or more types thereof. A photoacid generator and a thermal acid generator may be used in combination.

### <<Surfactant>>

When the silicon-containing resist underlayer film-forming composition is applied to a substrate, a surfactant is effective in suppressing occurrence of pinholes, striations, and the like. Examples of the surfactant include a nonionic surfactant, an anionic surfactant, a cationic surfactant, a silicon-based surfactant, a fluorine-based surfactant, and a UV-curable surfactant. Specific examples of the surfactant include, but are not limited to, nonionic surfactants, for example, polyoxyethylene alkyl ethers such as polyoxyethylene lauryl ether, polyoxyethylene stearyl ether, polyoxyethylene cetyl ether, and polyoxyethylene oleyl ether, polyoxyethylene alkylaryl ethers such as polyoxyethylene octylphenol ether and polyoxyethylene nonylphenol ether, polyoxyethylene-polyoxypropylene block copolymers, sorbitan fatty acid esters such as sorbitan monolaurate, sorbitan monopalmitate, sorbitan monostearate, sorbitan monooleate, sorbitan trioleate, and sorbitan tristearate, polyoxyethylene sorbitan fatty acid esters such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate; fluorine-based surfactants such as trade names EFTOP (registered trademark) EF301, EF303, and EF352 (manufactured by Mitsubishi Materials Electronic Chemicals Co., Ltd. (former Tohkem Products Corporation)), trade names MEGAFACE (registered trademark) F171, F173, R-08, R-30, R-30N, and R-40 LM (manufactured by DIC Corporation), Fluorad FC430 and FC431 (manufactured by 3M Japan Limited), trade name Asahi Guard (registered trademark) AG710 (manufactured by AGC Inc.), and trade names SURFLON (registered trademark) S-382, SC101, SC102, SC103, SC104, SC105, and SC106 (manufactured by AGC Seimi Chemical Co., Ltd.); and Organosiloxane Polymer KP341 (manufactured by Shin-Etsu Chemical Co., Ltd.).

The surfactants may be used alone or in combination of two or more types thereof.

When the silicon-containing resist underlayer film-forming composition contains a surfactant, the content of the surfactant is ordinarily 0.0001 to 5 mass %, preferably 0.001 to 4 mass %, and more preferably 0.01 to 3 mass % relative to the mass of the hydrolysis-condensation compound of the hydrolyzable silane mixture.

### <<Rheology Modifier>>

The rheology modifier is added mainly for the purpose of improving the fluidity of the silicon-containing resist underlayer film-forming composition, particularly in a baking step, improving the uniformity of the film thickness of a film to be formed, or improving the fillability of the composition into holes. Specific examples of the rheology modifier include phthalic acid derivatives such as dimethyl phthalate, diethyl phthalate, di-i-butyl phthalate, dihexyl phthalate, and butyl-1-decyl phthalate; adipic acid derivatives such as di-normal butyl adipate, di-i-butyl adipate, di-i-octyl adipate, and octyl decyl adipate; maleic acid derivatives such as di-normal butyl maleate, diethyl maleate, and dinonyl maleate; oleic acid derivatives such as methyl oleate, butyl oleate, and tetrahydrofurfuryl oleate; and stearic acid derivatives such as normal butyl stearate and glyceryl stearate.

When such a rheology modifier is used, the amount of the rheology modifier added is ordinarily less than 30 mass % relative to all film-forming components of the silicon-containing resist underlayer film-forming composition.

### <<Adhesion Aid>>

The adhesion aid is added for the purpose of mainly improving the adhesion between a substrate or a resist and a film (resist underlayer film) formed from the silicon-containing resist underlayer film-forming composition, in particular, suppressing or preventing the peeling of the resist during development. Specific examples of the adhesion aid include chlorosilanes such as trimethylchlorosilane, dimethylvinylchlorosilane, methyldiphenylchlorosilane, and chloromethyldimethylchlorosilane; alkoxysilanes such as trimethylmethoxysilane, dimethyldiethoxysilane, methyldimethoxysilane, and dimethylvinylethoxysilane; silazanes such as hexamethyldisilazane, N,N′-bis(trimethylsilyl)urea, dimethyltrimethylsilylamine, and trimethylsilyl imidazole; other silanes such as γ-chloropropyltrimethoxysilane, γ-aminopropyltriethoxysilane, and γ-glycidoxypropyltrimethoxysilane; heterocyclic compounds such as benzotriazole, benzimidazole, indazole, imidazole, 2-mercaptobenzimidazole, 2-mercaptobenzothiazole, 2-mercaptobenzoxazole, urazole, thiouracil, mercaptoimidazole, mercaptopyrimidine; and urea or thiourea compounds such as 1,1-dimethylurea and 1,3-dimethylurea.

When such an adhesion aid is used, the amount of the adhesion aid added is ordinarily less than 5 mass, preferably less than 2 mass %, relative to all solid contents of the silicon-containing resist underlayer film-forming composition.

### <<pH Adjuster>>

In addition, the pH adjuster may be an acid having one or two or more carboxylic acid groups, for example, an organic acid described above in <<Stabilizer>>. When a pH adjuster is used, the amount of the pH adjuster added may be 0.01 to 20 parts by mass, 0.01 to 10 parts by mass, or 0.01 to 5 parts by mass relative to 100 parts by mass of the polysiloxane.

### <<Metal Oxide>>

Examples of the metal oxide that may be added to the silicon-containing resist underlayer film-forming composition include, but are not limited to, oxides of a combination of one or more selected from among metals such as tin (Sn), titanium (Ti), aluminum (Al), zirconium (Zr), zinc (Zn), niobium (Nb), tantalum (Ta), and W (tungsten), and semimetals such as boron (B), silicon (Si), germanium (Ge), arsenic (As), antimony (Sb), and tellurium (Te).

The concentration of the film-forming component in the silicon-containing resist underlayer film-forming composition may be, for example, 0.1 to 50 mass %, 0.1 to 30 mass %, 0.1 to 25 mass %, or 0.5 to 20.0 mass % relative to the total mass of the composition.

The content of the polysiloxane in the film-forming component is ordinarily 20 mass % to 100 mass %. From the viewpoint of achieving the effects of the present invention at high reproducibility or the like, the lower limit value of the content of the polysiloxane is preferably 50 mass %, more preferably 60 mass %, still more preferably 70 mass, and yet still more preferably 80 mass %. The upper limit value of the content is preferably 99 mass %. The balance may be an additive described below.

Further, the silicon-containing resist underlayer film-forming composition preferably has a pH of 2 to 5, and more preferably a pH of 3 to 4.

The silicon-containing resist underlayer film-forming composition can be produced by mixing a hydrolysis-condensation compound of the hydrolyzable silane mixture, a solvent, and when other components are contained as desired, the other components. At this time, a solution containing a hydrolysis-condensation compound or the like may be prepared in advance, and this solution may be mixed with a solvent or other components.

The order of mixing these components is not particularly limited. For example, a solvent may be added to and mixed with a solution containing a hydrolysis-condensation compound or the like, and other components may be added to the mixture, or a solution containing a hydrolysis-condensation compound or the like, a solvent, and other components may be simultaneously mixed.

If necessary, additional solvent may be finally added, or some components that can be relatively easily dissolved in the solvent may be finally added without being incorporated into the mixture. However, from the viewpoint of suppressing aggregation or separation of the components to prepare a composition having high uniformity with high reproducibility, the composition is preferably prepared from a previously prepared solution containing the well-dissolved hydrolysis-condensation compound or the like. Note that attention is paid to the fact that hydrolysis-condensation compound or the like may aggregate or precipitate when mixed, depending on the type and amount of solvent to be mixed together, the amount and properties of other components, and the like. In addition, in the case of preparing a composition using a solution in which a hydrolysis-condensation compound or the like is dissolved, it is also noted that it is necessary to determine the concentration of the solution of the hydrolysis-condensation compound or the like and the use amount thereof such that the hydrolysis-condensation compound or the like in the finally obtained composition becomes a desired amount.

During preparation of the composition, the composition may be appropriately heated as long as the components are not decomposed or denatured.

In the present invention, the silicon-containing resist underlayer film-forming composition may be filtered with a submicrometer-order filter or the like during production of the silicon-containing resist underlayer film-forming composition or after mixing of all the components. The type of the material of the filter used is not limited. For example, a nylon-made filter or a fluororesin-made filter may be used.

The silicon-containing resist underlayer film-forming composition of the present invention may be suitably used as a composition for forming a resist underlayer film used in a lithography step.

The silicon-containing resist underlayer film-forming composition of the present invention may be suitably used as a composition for forming a resist underlayer film used in an EUV or ArF lithography step.

### [Silicon-Containing Resist Underlayer Film, Laminate, Method for Forming Pattern, and Method for Producing Semiconductor Element]

The silicon-containing resist underlayer film of the present invention is a cured product of the silicon-containing resist underlayer film-forming composition of the present invention.

The laminate of the present invention includes, for example, a semiconductor substrate and the silicon-containing resist underlayer film of the present invention.

The method for producing a semiconductor element of the present invention includes, for example,
a step of forming an organic underlayer film on a substrate;
a step of forming a silicon-containing resist underlayer film on the organic underlayer film using the silicon-containing resist underlayer film-forming composition of the present invention; and
a step of forming a resist film on the silicon-containing resist underlayer film.

The method for forming a pattern of the present invention includes, for example,
a step of forming an organic underlayer film on a semiconductor substrate;
a step of applying the silicon-containing resist underlayer film-forming composition of the present invention on the organic underlayer film and baking to form a silicon-containing resist underlayer film;
a step of forming a resist film on the silicon-containing resist underlayer film;
a step of exposing and developing the resist film to obtain a resist pattern;
a step of etching the silicon-containing resist underlayer film using the resist pattern as a mask; and
a step of etching the organic underlayer film using the patterned silicon-containing resist underlayer film as a mask.

Hereinafter, as one aspect of the present invention, a laminate, a method for forming a pattern, and a method for producing a semiconductor element using the silicon-containing resist underlayer film of the present invention or the silicon-containing resist underlayer film-forming composition of the present invention will be described.

First, the silicon-containing resist underlayer film-forming composition of the present invention is applied onto a substrate used for the production of a precise integrated circuit element [for example, a semiconductor substrate such as a silicon wafer coated with a silicon oxide film, a silicon nitride film, or a silicon oxynitride film, a silicon nitride substrate, a quartz substrate, a glass substrate (including alkali-free glass, low alkali glass, or crystallized glass), a glass substrate coated with an indium tin oxide (ITO) film or an indium zinc oxide (IZO) film, a plastic (polyimide, PET or the like) substrate, a substrate coated with a low dielectric constant material (low-k material), or a flexible substrate] by an appropriate coating method with, for example, a spinner or a coater. Thereafter, the composition is converted into a cured product through baking by heating means (for example, a hot plate) to form a resist underlayer film. Hereinafter, in this specification, the term “silicon-containing resist underlayer film” refers to a film formed from the silicon-containing resist underlayer film-forming composition of the present invention.

The baking conditions are appropriately selected from a baking temperature of 40° C. to 400° C., or 80° C. to 250° C., and a baking time of 0.3 minutes to 60 minutes. Preferably, the baking temperature is 150° C. to 250° C., and the baking time is 0.5 minutes to 2 minutes.

The resist underlayer film formed here has a film thickness of, for example, 10 nm to 1,000 nm, or 20 nm to 500 nm, or 50 nm to 300 nm, or 100 nm to 200 nm, or 10 to 150 nm.

As the silicon-containing resist underlayer film-forming composition used for formation of the resist underlayer film, the silicon-containing resist underlayer film-forming composition filtered through a nylon filter may be used. Here, the term “silicon-containing resist underlayer film-forming composition filtered through a nylon filter” refers to a composition that has been subjected to filtration with a nylon filter during production of the silicon-containing resist underlayer film-forming composition or after mixing all the components.

In one aspect of the present invention, the organic underlayer film is formed on the substrate, and then the silicon-containing resist underlayer film is formed on the organic underlayer film. In some cases, an aspect may be employed in which the organic underlayer film is not provided.

The organic underlayer film used here is not particularly limited, and may be selected from organic underlayer films commonly used in the lithography process.

In one aspect, the organic underlayer film is formed on the substrate, and the silicon-containing resist underlayer film is formed on the organic underlayer film, followed by formation of a resist film as described below on the silicon-containing resist underlayer film. This can narrow the pattern width of a photoresist film. Thus, even when the photoresist film is formed thinly for preventing pattern collapse, the substrate can be processed through selection of an appropriate etching gas described below. For example, the silicon-containing resist underlayer film can be processed by using, as an etching gas, a fluorine-containing gas that achieves a sufficiently high etching rate for the photoresist film. Further, the organic underlayer film can be processed by using, as an etching gas, an oxygen-containing gas that achieves a sufficiently high etching rate for the silicon-containing resist underlayer film. Further, the substrate can be processed by using, as an etching gas, a fluorine-containing gas that achieves a sufficiently high etching rate for the organic underlayer film.

The substrate and coating method usable in this process are the same as those described above.

Subsequently, for example, a layer (resist film) of a photoresist material is formed on the silicon-containing resist underlayer film. The resist film can be formed by a well-known method. For example, the resist film can be formed by applying a coating-type resist material (for example, a composition for forming a resist film) onto the silicon-containing resist underlayer film, and baking the resist material.

The resist film has a film thickness of, for example, 10 nm to 10,000 nm, or 100 nm to 2,000 nm, or 200 nm to 1,000 nm, or 30 nm to 200 nm.

The photoresist material used for the resist film formed on the silicon-containing resist underlayer film is not particularly limited as long as the photoresist material is sensitive to light used for exposure (for example, a KrF excimer laser or an ArF excimer laser), and both a negative photoresist material and a positive photoresist material can be used. Examples of the photoresist include a positive photoresist material formed of a novolac resin and 1,2-naphthoquinone diazide sulfonic acid ester; a chemically amplified photoresist material formed of a binder having a group that is decomposed by an acid to increase an alkali dissolution rate and a photoacid generator; a chemically amplified photoresist material formed of a low molecular weight compound that is decomposed by an acid to increase an alkali dissolution rate of the photoresist material, an alkali-soluble binder, and a photoacid generator; a chemically amplified photoresist material formed of a binder having a group that is decomposed by an acid to increase an alkali dissolution rate, a low molecular weight compound having a group that is decomposed by an acid to increase an alkali dissolution rate of the photoresist material, and photoacid generator.

Specific examples of commercially available products thereof include, but are not limited to, APEX-E (trade name, manufactured by Shipley Company L. L. C), PAR710 (trade name, manufactured by Sumitomo Chemical Co., Ltd.), AR2772JN (trade name, manufactured by JSR Corporation), and SEPR430 (trade name, manufactured by Shin-Etsu Chemical Co., Ltd.). Further, examples of the photoresist include a fluorine-containing atomic polymer-based photoresist material as described in Proc. SPIE, Vol. 3999, 330-334 (2000), Proc. SPIE, Vol. 3999, 357-364 (2000), or Proc. SPIE, Vol. 3999, 365-374 (2000).

As the resist film formed on the silicon-containing resist underlayer film, a resist film for electron beam lithography (also referred to as an electron beam resist film) or a resist film for EUV lithography (also referred to as an EUV resist film) can be used instead of the photoresist film.

As the electron beam resist material for forming the electron beam resist film, both a negative type material and a positive type material can be used. Specific examples of the negative type material and the positive type material include: a chemically amplified resist material containing an acid generator and a binder having a group that is decomposed by an acid to change the alkali dissolution rate; a chemically amplified resist material containing an alkali-soluble binder, an acid generator, and a low molecular weight compound that is decomposed by an acid to change the alkali dissolution rate of the resist material; a chemically amplified resist material containing an acid generator, a binder having a group that is decomposed by an acid to change the alkali dissolution rate, and a low molecular weight compound that is decomposed by an acid to change the alkali dissolution rate of the resist material; a non-chemically amplified resist material containing a binder having a group that is decomposed by an electron beam to change the alkali dissolution rate; and a non-chemically amplified resist material containing a binder having a moiety that is cleaved by an electron beam to change the alkali dissolution rate. Even when these electron beam resist materials are used, a resist film pattern can be formed similarly to a case where a photoresist material is used with an electron beam being used as an irradiation source.

As the EUV resist material for forming the EUV resist film, a methacrylate resin-based resist material can be used.

The resist material may be a metal-containing resist.

The metal-containing resist is also called a metal oxide resist (metal oxide resist (MOR)), and typical examples thereof include a tin oxide-based resist.

The material of the metal oxide resist is, for example, a coating composition containing a metal oxo-hydroxo network having an organic ligand through a metal carbon bond and/or a metal carboxylate bond described in JP 2019-113855 A.

In an example of the metal-containing resist, a peroxo ligand is used as a radiation-sensitive stabilizing ligand. Details of the peroxo based metal oxo-hydroxo compounds are described, for example, in paragraph of JP 2019-532489 A. Examples of the Patent Literature include U.S. Pat. No. 9,176,377 B2, US 2013/0224652 A1, U.S. Pat. No. 9,310,684 B2, US 2016/0116839 A1, and U.S. Ser. No. 15/291,738 A.

Subsequently, light exposure is performed on the resist film formed above the silicon-containing resist underlayer film through a predetermined mask (reticle). The light exposure may be performed using a KrF excimer laser (wavelength: 248 nm), an ArF excimer laser (wavelength: 193 nm), an F2 excimer laser (wavelength: 157 nm), EUV (wavelength: 13.5 nm), electron beams, or the like.

After the light exposure, post exposure bake may be performed as necessary. The post exposure bake is performed under appropriately selected conditions: a heating temperature of 70° C. to 150° C. and a heating time of 0.3 minutes to 10 minutes.

Next, development is performed with a developer (for example, an alkaline developer). When, for example, a positive photoresist film is used, an exposed portion of the photoresist film is removed, and thus a pattern of the photoresist film is formed.

Examples of the developer (alkaline developer) include alkaline aqueous solutions (alkaline developers) such as: aqueous solutions of alkali metal hydroxides such as potassium hydroxide and sodium hydroxide; aqueous solutions of quaternary ammonium hydroxides such as tetramethylammonium hydroxide, tetraethylammonium hydroxide, and choline; and aqueous amine solutions such as ethanolamine, propylamine, and ethylenediamine. Furthermore, a surfactant or the like may be added to these developers. Development conditions are appropriately selected from a temperature of 5 to 50° C., and a time of 10 seconds to 600 seconds.

In the present invention, an organic solvent can be used as a developer. Development is performed with a developer (solvent) after light exposure. When, for example, a negative photoresist film is used, an unexposed portion of the photoresist film is removed, and thus a pattern of the photoresist film is formed.

Examples of the developer (organic solvent) include methyl acetate, butyl acetate, ethyl acetate, isopropyl acetate, amyl acetate, isoamyl acetate, ethyl methoxyacetate, ethyl ethoxyacetate, propylene glycol monomethyl ether acetate, ethylene glycol monoethyl ether acetate, ethylene glycol monopropyl ether acetate, ethylene glycol monobutyl ether acetate, ethylene glycol monophenyl ether acetate, diethylene glycol monomethyl ether acetate, diethylene glycol monopropyl ether acetate, diethylene glycol monoethyl ether acetate, diethylene glycol monophenyl ether acetate, diethylene glycol monobutyl ether acetate, diethylene glycol monoethyl ether acetate, 2-methoxybutyl acetate, 3-methoxybutyl acetate, 4-methoxybutyl acetate, 3-methyl-3-methoxybutyl acetate, 3-ethyl-3 methoxybutyl acetate, propylene glycol monomethyl ether acetate, propylene glycol monoethyl ether acetate, propylene glycol monopropyl ether acetate, 2-ethoxybutyl acetate, 4-ethoxybutyl acetate, 4-propoxybutyl acetate, 2-methoxypentyl acetate, 3-methoxypentyl acetate, 4-methoxypentyl acetate, 2-methyl-3-methoxypentyl acetate, 3-methyl-3-methoxypentyl acetate, 3-methyl-4-methoxypentyl acetate, 4-methyl-4-methoxypentyl acetate, propylene glycol diacetate, methyl formate, ethyl formate, butyl formate, propyl formate, ethyl lactate, butyl lactate, propyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, methyl 2-hydroxypropionate, ethyl 2-hydroxypropionate, methyl-3-methoxypropionate, ethyl-3-methoxypropionate, ethyl-3 ethoxypropionate, and propyl-3-methoxypropionate. Furthermore, a surfactant or the like may be added to these developers. Development conditions are appropriately selected from a temperature of 5° C. to 50° C., and a time of 10 seconds to 600 seconds.

The pattern of the photoresist film (upper layer) formed in this manner is used as a protective film to remove the resist underlayer film (intermediate layer), and then a film including the patterned photoresist film and the patterned resist underlayer film (intermediate layer) is used as a protective film to remove the organic underlayer film (underlayer). Finally, the patterned photoresist film (upper layer), the patterned resist underlayer film (intermediate layer), and the patterned organic underlayer film (underlayer) are used as protective films to process the substrate.

Removal of the resist underlayer film (intermediate layer) performed using the pattern of the resist film (upper layer) as the protective film is performed through dry etching, and gases such as tetrafluoromethane (CF₄), perfluorocyclobutane (C₄F₈), perfluoropropane (C₃F₈), trifluoromethane, carbon monoxide, argon, oxygen, nitrogen, sulfur hexafluoride, difluoromethane, nitrogen trifluoride, chlorine trifluoride, chlorine, trichloroborane, and dichloroborane can be used.

A halogen-based gas is preferably used for dry etching of the resist underlayer film. The resist film (photoresist film) made of an organic material is basically less likely to be removed by dry etching with a halogen-containing gas. In contrast, the silicon-containing resist underlayer film containing numerous silicon atoms is quickly removed by a halogen-containing gas. Therefore, a decrease in the film thickness of the photoresist film due to dry etching of the resist underlayer film can be suppressed. Then, as a result, the photoresist film can be used as a thin film. Therefore, the dry etching of the resist underlayer film is preferably performed with a fluorine-based gas, and examples of the fluorine-based gas include, but are not limited to, tetrafluoromethane (CF₄), perfluorocyclobutane (C₄F₈), perfluoropropane (C₃F₈), trifluoromethane, and difluoromethane (CH₂F₂).

When the organic underlayer film is provided between the substrate and the resist underlayer film, the removal of the organic underlayer film (underlayer), which is carried out using the film composed of the patterned resist underlayer film (intermediate layer) (and, if still remaining, the patterned resist film (upper layer)) as a protective film, is preferably performed by dry etching using an oxygen-based gas such as oxygen gas or an oxygen/carbonyl sulfide (COS) mixed gas. This is because the silicon-containing resist underlayer film of the present invention, which contains numerous silicon atoms, is less likely to be removed by dry etching with an oxygen-containing gas.

Thereafter, the patterned silicon-containing resist underlayer film (intermediate layer) and, if desired, the patterned organic underlayer film (underlayer) are used as protective films to process (pattern) the (semiconductor) substrate. The (semiconductor) substrate is preferably processed (patterned) by dry etching with a fluorine-containing gas.

Examples of the fluorine-based gas include tetrafluoromethane (CF₄), perfluorocyclobutane (C₄F₈), perfluoropropane (C₃F₈), trifluoromethane, and difluoromethane (CH₂F₂).

After the removal (patterning) of the organic underlayer film or after the processing (patterning) of the substrate, the resist underlayer film may be removed. The silicon-containing resist underlayer film may be removed by dry etching or wet etching.

The dry etching of the silicon-containing resist underlayer film is preferably performed with a fluorine-containing gas as described in the patterning. Examples of the fluorine-containing gas include, but are not limited to, tetrafluoromethane (CF₄), perfluorocyclobutane (C₄F₈), perfluoropropane (C₃F₈), trifluoromethane, and difluoromethane (CH₂F₂)

Examples of the chemical solution used for wet etching of the silicon-containing resist underlayer film include alkaline chemical solutions, such as dilute hydrofluoric acid (hydrofluoric acid), buffered hydrofluoric acid (mixed solution of HF and NH₄F), an aqueous solution containing hydrochloric acid and hydrogen peroxide (SC-2 chemical solution), an aqueous solution containing sulfuric acid and hydrogen peroxide (SPM chemical solution), an aqueous solution containing hydrofluoric acid and hydrogen peroxide (FPM chemical solution), an aqueous solution containing ammonia and hydrogen peroxide (SC-1 chemical solution), and alkaline solutions such as a resist stripping solution (ST-120, manufactured by Tokyo Ohka Kogyo Co., Ltd.). Further, examples of the alkaline chemical solution include an aqueous solution containing 1 to 99 mass % of ammonia, tetramethylammonium hydroxide (TMAH), tetraethylammonium hydroxide, tetrapropylammonium hydroxide, tetrabutylammonium hydroxide, choline hydroxide, benzyltrimethylammonium hydroxide, benzyltriethylammonium hydroxide, diazabicycloundecene (DBU), diazabicyclononene (DBN), hydroxylamine, 1-butyl-1-methylpyrrolidinium hydroxide, 1-propyl-1-methylpyrrolidinium hydroxide, 1-butyl-1-methylpiperidinium hydroxide, 1-propyl-1-methylpiperidinium hydroxide, mepiquat hydroxide, trimethylsulfonium hydroxide, a hydrazine compound, an ethylenediamine compound, or guanidine, in addition to the above-described ammonia-hydrogen peroxide mixture prepared by mixing ammonia, hydrogen peroxide water, and water (SC-1 chemical solution). These chemical solutions can also be used in combination.

An organic bottom anti-reflective coating may be formed on the silicon-containing resist underlayer film before formation of the resist film. The bottom anti-reflective coating composition to be used is not particularly limited, and can be selected and used in any manner, for example, from those conventionally used in a lithography process, and the bottom anti-reflective coating can be formed by a commonly used method, for example, coating using a spinner or a coater and baking.

In addition, the substrate to which the silicon-containing resist underlayer film-forming composition is applied may have an organic or inorganic bottom anti-reflective coating formed on the surface thereof by, for example, a CVD process. The silicon-containing resist underlayer film may be formed on the bottom anti-reflective coating. Even in a case where the silicon-containing resist underlayer film of the present invention is formed on the organic underlayer film formed on the substrate, the substrate used may have an organic or inorganic bottom anti-reflective coating formed on the surface thereof by, for example, a CVD process.

The silicon-containing resist underlayer film formed from the silicon-containing resist underlayer film-forming composition may absorb light used in a lithography process depending on the wavelength of the light. In such a case, the resist underlayer film can function as a bottom anti-reflective coating having the effect of preventing reflection of light from the substrate.

Furthermore, the silicon-containing resist underlayer film can be used as, for example, a layer for preventing the interaction between the substrate and the resist film (such as a photoresist film); a layer having the function of preventing the adverse effect, on the substrate, of a material used for the resist film or a substance generated during the exposure of the resist film to light; a layer having the function of preventing diffusion of a substance generated from the substrate during heating and baking to the resist film; and a barrier layer for reducing a poisoning effect of a dielectric layer of the semiconductor substrate on the resist film.

The silicon-containing resist underlayer film can be applied to a substrate having via holes for use in a dual damascene process, and can be used as a hole filling material (embedding material) to fill up the holes without gaps. The resist underlayer film can also be used as a planarization material for planarizing the surface of a semiconductor substrate having irregularities.

The silicon-containing resist underlayer film of the present invention functions as an underlayer of EUV resist film or a hard mask. In addition, the resist underlayer film is capable of, without intermixing with the EUV resist film, preventing the reflection, from a substrate or an interface, of exposure light undesirable for EUV exposure (wavelength: 13.5 nm), such as UV (ultraviolet) light or DUV (deep ultraviolet) light (ArF light, KrF light). Therefore, the silicon-containing resist underlayer film-forming composition of the present invention can be suitably used to form an underlayer bottom anti-reflective coating of EUV resist film. Thus, the silicon-containing resist underlayer film-forming composition can efficiently prevent the light reflection as the underlayer of the EUV resist film. When the silicon-containing resist underlayer film-forming composition is used as an EUV resist underlayer film, the film can be processed in a similar manner to the photoresist underlayer film.

A semiconductor substrate can be suitably processed by using a laminate including the above-described silicon-containing resist underlayer film of the present invention and a semiconductor substrate.

In addition, according to the method for producing a semiconductor element, the method including: the step of forming an organic underlayer film; the step of forming a silicon-containing resist underlayer film on the organic underlayer film using the silicon-containing resist underlayer film-forming composition of the present invention, and the step of forming a resist film on the silicon-containing resist underlayer film, as described above, highly accurate processing of a semiconductor substrate can be reproducibly achieved, and thus stable production of semiconductor elements can be expected.

### EXAMPLES

Hereinafter, the contents and effects of the present invention will be described in more detail by way of examples, but the present invention is not limited thereto.

The hydrolysis-condensation compound (polyorganosiloxane) of the hydrolyzable silane is a condensation compound having a weight-average molecular weight of 1,000 to 1,000,000 or 1,000 to 100,000. The molecular weight used in the present invention is a molecular weight obtained in terms of polystyrene by GPC analysis.

The GPC analysis can be performed, for example, under the following conditions: GPC apparatus (trade name: HLC-8220GPC, manufactured by Tosoh Corporation), GPC columns (trade name: Shodex (registered trademark) KF803L, KF802, and KF801, manufactured by Showa Denko K.K.), column temperature of 40° C., tetrahydrofuran as an eluent (elution solvent), flow amount (flow rate) of 1.0 mL/min, and polystyrene (manufactured by Showa Denko K.K.) as a standard sample.

### [1] Synthesis Examples 1 to 9 and Comparative Synthesis Example: Synthesis of Hydrolysis-Condensation Compound (Polysiloxane)

Compound 1 to 9 used in each synthesis is shown below.

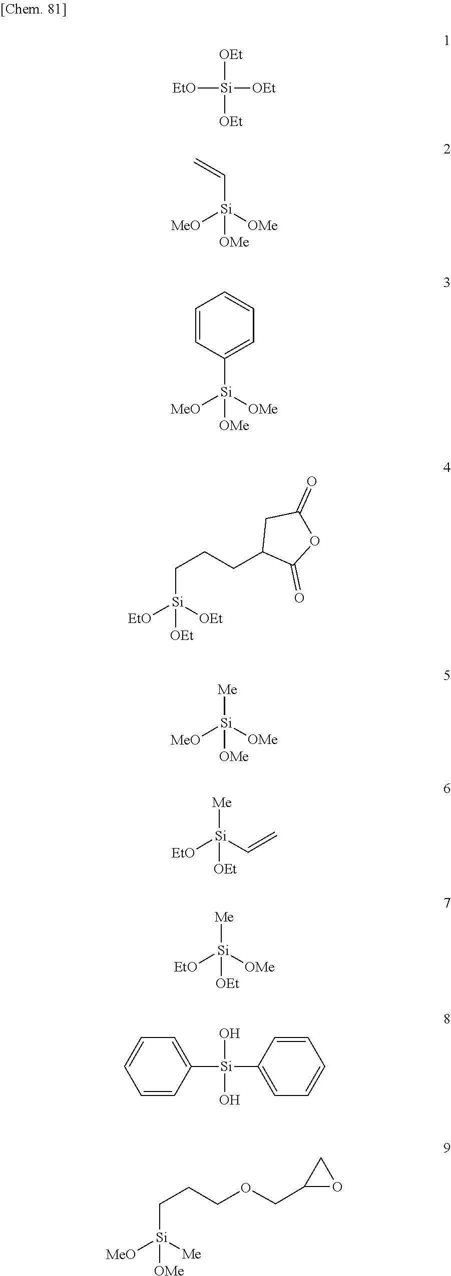

In the above Formulas, Me represents a methyl group, and Et represents an ethyl group.

### Synthesis Example 1

In a 200 mL flask, 6.2 g of the compound 1, 5.9 g of the compound 2, 3.0 g of the compound 3, 1.5 g of the compound 4, 1.8 g of the compound 5, and 25 g of 1-ethoxy-2-propanol were charged and stirred, and a 0.2 mol/L aqueous nitric acid solution (13 g) was added dropwise thereto while stirring the obtained solution with a magnetic stirrer.

After the dropwise addition, the flask was transferred to an oil bath set at 65° C. and the mixed solution was reacted for 20 hours. Thereafter, the reaction solution was cooled to room temperature, 34 g of 1-ethoxy-2 propanol was added to the reaction solution, and water and nitric acid, and methanol and ethanol as reaction by-products were distilled off under reduced pressure to obtain a concentrated solution of a hydrolysis-condensation compound (polymer) using 1-ethoxy-2-propanol as a solvent. The solid content concentration of the obtained concentrated solution was more than 20 mass % in terms of solid residue when heated at 150° C.

The obtained hydrolysis-condensation compound (polysiloxane) corresponded to the following formula, and the weight-average molecular weight (Mw) by GPC was 1, 539 in terms of polystyrene.

In the chemical formulas described in the following Synthesis Examples and Comparative Synthesis Examples, the number attached to the side of the siloxane unit represents a molar ratio (total 100).

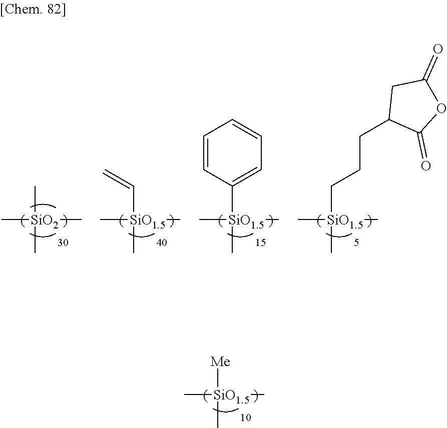

Compounds (monomers) shown in Table 1 were used under the same conditions as in Synthesis Example 1, <Synthesis Example 2> to <Synthesis Example 9> and <Comparative Synthesis Example> were carried out, and hydrolysis-condensation compounds (polysiloxane compounds) as target compounds were obtained. The weight-average molecular weight of the obtained hydrolysis-condensation compound is shown in Table 1.

TABLE 1

| | | | | | | | | | | Weight- |
|---|---|---|---|---|---|---|---|---|---|---|
| | | | | | | | | | | average |
| | Com- | Com- | Com- | Com- | Com- | Com- | Com- | Com- | Com- | molecular |
| No. | pound 1 | pound 2 | pound 3 | pound 4 | pound 5 | pound 6 | pound 7 | pound 8 | pound 9 | weight |
| Synthesis | 6.2 g | 5.9 g | 3.0 g | 1.5 g | 1.8 g | — | — | — | — | 1539 |
| Example 1 | 30 | 40 | 15 | 5 | 10 | | | | | |
| (Mol %) | | | | | | | | | | |
| Synthesis | 6.2 g | 5.9 g | 3.0 g | 1.5 g | — | — | — | — | 2.5 g | 1793 |
| Example 2 | 30 | 40 | 15 | 5 | | | | | 10 | |
| (Mol %) | | | | | | | | | | |
| Synthesis | 6.2 g | 4.4 g | 3.0 g | 1.5 g | — | — | — | — | 5 g | 1702 |
| Example 3 | 30 | 30 | 15 | 5 | | | | | 20 | |
| (Mol %) | | | | | | | | | | |
| Synthesis | 6.2 g | 5.9 g | 3.0 g | 1.5 g | — | — | 1.5 g | — | — | 2250 |
| Example 4 | 30 | 40 | 15 | 5 | | | 10 | | | |
| (Mol %) | | | | | | | | | | |
| Synthesis | 6.2 g | 4.4 g | 3.0 g | 1.5 g | — | — | 3 g | — | — | 2427 |
| Example 5 | 30 | 30 | 15 | 5 | | | 20 | | | |
| (Mol %) | | | | | | | | | | |
| Synthesis | 6.2 g | 5.9 g | 3.0 g | 1.5 g | — | 1.6 g | — | — | — | 1956 |
| Example 6 | 30 | 40 | 15 | 5 | | 10 | | | | |
| (Mol %) | | | | | | | | | | |
| Synthesis | 6.2 g | 4.4 g | 3.0 g | 1.5 g | — | 3.2 g | — | — | — | 1983 |
| Example 7 | 30 | 30 | 15 | 5 | | 20 | | | | |
| (Mol %) | | | | | | | | | | |
| Synthesis | 6.2 g | 5.9 g | 3.0 g | 1.5 g | — | — | — | 2.2 g | — | 1377 |
| Example 8 | 30 | 40 | 15 | 5 | | | | 10 | | |
| (Mol %) | | | | | | | | | | |
| Synthesis | 6.2 g | 5.9 g | 1.0 g | 1.5 g | — | — | — | 4.3 g | — | 1213 |
| Example 9 | 30 | 40 | 5 | 5 | | | | 20 | | |
| (Mol %) | | | | | | | | | | |
| Comparative | 12.5 g | — | — | — | 4.6 g | — | — | — | — | 4976 |
| Synthesis | 70 | | | | 30 | | | | | |
| Example | | | | | | | | | | |
| (Mol %) | | | | | | | | | | |

### [2] Preparation Examples 1 to 9 and Comparative Preparation Example: Preparation of Silicon-Containing Resist Underlayer Film-Forming Composition (Coating Solution)

Additives and solvents were mixed with the hydrolysis-condensation compound (polymer) 1 to 9 obtained in the above Synthesis Example and the hydrolysis-condensation compound (polymer) of Comparative Synthesis Example in the proportions shown in Table 2, and the mixture was filtered through a 0.02 μm polyethylene filter to prepare composition solutions for forming a polysiloxane underlayer film. In Table 2, the amount of each component added is shown by parts by mass.

In Table 2, the fact that the amount of each synthesis example described in the column of composition is 2 parts by mass means that the amount of the hydrolysis-condensation compound is 2 parts by mass. In Table 2, MA means maleic acid, TPSNO3 means triphenylsulfonium nitrate, PGEE means propylene glycol monoethyl ether, and PGME means propylene glycol monomethyl ether.

TABLE 2

| | Compo- | Addi- | Addi- | | | |
|---|---|---|---|---|---|---|
| No. | sition | tive 1 | tive 2 | Solvent | | |
| Preparation | Synthesis | MA | TPSNO3 | PGEE | PGME | Water |
| Example 1 | Example 1 | 0.02 | 0.01 | 80 | 8 | 12 |
| (parts by | 2 | | | | | |
| mass) | | | | | | |
| Preparation | Synthesis | MA | TPSNO3 | PGEE | PGME | Water |
| Example 2 | Example 2 | 0.02 | 0.01 | 80 | 8 | 12 |
| (parts by | 2 | | | | | |
| mass) | | | | | | |
| Preparation | Synthesis | MA | TPSNO3 | PGEE | PGME | Water |
| Example 3 | Example 3 | 0.02 | 0.01 | 80 | 8 | 12 |
| (parts by | 2 | | | | | |
| mass) | | | | | | |
| Preparation | Synthesis | MA | TPSNO3 | PGEE | PGME | Water |
| Example 4 | Example 4 | 0.02 | 0.01 | 80 | 8 | 12 |
| (parts by | 2 | | | | | |
| mass) | | | | | | |
| Preparation | Synthesis | MA | TPSNO3 | PGEE | PGME | Water |
| Example 5 | Example 5 | 0.02 | 0.01 | 80 | 8 | 12 |
| (parts by | 2 | | | | | |
| mass) | | | | | | |
| Preparation | Synthesis | MA | TPSNO3 | PGEE | PGME | Water |
| Example 6 | Example 6 | 0.02 | 0.01 | 80 | 8 | 12 |
| (parts by | 2 | | | | | |
| mass) | | | | | | |
| Preparation | Synthesis | MA | TPSNO3 | PGEE | PGME | Water |
| Example 7 | Example 7 | 0.02 | 0.01 | 80 | 8 | 12 |
| (parts by | 2 | | | | | |
| mass) | | | | | | |
| Preparation | Synthesis | MA | TPSNO3 | PGEE | PGME | Water |
| Example 8 | Example 8 | 0.02 | 0.01 | 80 | 8 | 12 |
| (parts by | 2 | | | | | |
| mass) | | | | | | |
| Preparation | Synthesis | MA | TPSNO3 | PGEE | PGME | Water |
| Example 9 | Example 9 | 0.02 | 0.01 | 80 | 8 | 12 |
| (parts by | 2 | | | | | |
| mass) | | | | | | |
| Comparative | Compar- | MA | TPSNO3 | PGEE | PGME | Water |
| Preparation | ative | 0.02 | 0.01 | 80 | 8 | 12 |
| Example | Synthesis | | | | | |
| (parts by | Example | | | | | |
| mass) | 2 | | | | | |

### [3] Examples 1 to 9, Comparative Example: Evaluation of Siloxane Binding Strength Ratio by FT-IR

The coating solution obtained in Preparation Example 1 was applied onto a silicon wafer by spin coating, and heated on a hot plate at 215° C. for 1 minute to form a silicon-containing resist underlayer film. On the formed silicon-containing resist underlayer film, lamination was further performed 2 times in the same step to obtain a silicon-containing resist underlayer film (film thickness: 80 nm) laminated 3 times.

In the same procedure, a silicon-containing resist underlayer film was formed using each coating solution obtained in Preparation Examples 2 to 9 and Comparative Preparation Example.

For each of the obtained silicon-containing resist underlayer films, the peak intensity of a siloxane bond observed at a wave number of 1,000 to 1,250 cm-1 was compared using Fourier transform infrared spectroscopy (FT/IR-6600 (manufactured by JASCO Corporation)). The peak intensity was compared using a value normalized by setting the intensity of the silicon-containing resist underlayer film of Comparative Example to 100. When the binding strength ratio to the comparative example is relatively low (for example, 60 or less), solubility tends to be improved. The obtained results are shown in Table 3.

### [4] Examples 1 to 9, Comparative Example: Evaluation of Water Contact Angle

The coating solution obtained in Preparation Example 1 was applied onto a silicon wafer by spin coating, and heated on a hot plate at 215° C. for 1 minute to form a silicon-containing resist underlayer film.

In the same procedure, a silicon-containing resist underlayer film was formed using each coating solution obtained in Preparation Examples 2 to 9 and Comparative Preparation Example.

Each of the obtained silicon-containing resist underlayer films was measured using a fully automatic contact angle meter DM-701 (manufactured by Kyowa Interface Science Co., Ltd.) after the liquid amount was 3 μL and the resist underlayer film was stationary for 7 seconds after liquid deposition. When the value of the water contact angle is higher than that of Comparative Example, solubility tends to be improved. The obtained measurement results are shown in Table 3.

### [5] Examples 1 to 9, Comparative Example: Evaluation of Removability by Resist Stripping Solution ST-120 (Manufactured by Tokyo Ohka Kogyo Co., Ltd.)

The coating solution obtained in Preparation Example 1 was applied onto a silicon wafer by spin coating, and heated on a hot plate at 215° C. for 1 minute to form a silicon-containing resist underlayer film (20 nm).

In the same procedure, a silicon-containing resist underlayer film was formed using each coating solution obtained in Preparation Examples 2 to 9 and Comparative Preparation Example.

The obtained silicon wafer on which each silicon-containing resist underlayer film was formed was immersed in ST-120 adjusted to a liquid temperature of 40° C. for 60 seconds, then rinsed with water for 20 seconds, and then dried. Then, the thickness of the silicon-containing resist underlayer film after immersion in ST-120 for 60 seconds was measured, and the film thickness change rate (%) was calculated. A film having a change rate of the film thickness after immersion with respect to the film thickness of the silicon-containing resist underlayer film before immersion of 80% or more was evaluated as “extremely good”, a film having a change rate of 5% or more and less than 80% was evaluated as “good”, and a film having a change rate of less than 5% was evaluated as “poor”. The obtained results are shown in Table 3.

TABLE 3

| | | Siloxane | Water | ST-120 |
|---|---|---|---|---|
| | | binding | contact | chemical |
| | Preparation | strength ratio | angle | solution |
| Example | Example | (%) | (°) | removability |
| Example 1 | Preparation | 59 | 77 | Good |
| | Example 1 | | | |
| Example 2 | Preparation | 51 | 70 | Good |
| | Example 2 | | | |
| Example 3 | Preparation | 46 | 66 | Good |
| | Example 3 | | | |
| Example 4 | Preparation | 54 | 81 | Extremely |
| | Example 4 | | | good |
| Example 5 | Preparation | 52 | 84 | Extremely |
| | Example 5 | | | good |
| Example 6 | Preparation | 51 | 78 | Extremely |
| | Example 6 | | | good |
| Example 7 | Preparation | 50 | 79 | Extremely |
| | Example 7 | | | good |
| Example 8 | Preparation | 57 | 82 | Extremely |
| | Example 8 | | | good |
| Example 9 | Preparation | 54 | 85 | Extremely |
| | Example 9 | | | good |
| Comparative | Comparative | 100 | 63 | Poor |
| Example | Preparation | (Reference) | | |
| | Example | | | |

1. A silicon-containing resist underlayer film-forming composition for forming a silicon-containing resist underlayer film containing a hydrolysis-condensation compound of a hydrolyzable silane mixture containing a hydrolyzable silane represented by Formula (1-1) below and a hydrolyzable silane represented by Formula (2) below and soluble in a basic chemical solution, the composition containing:
a hydrolyzable silane represented by Formula (1-1) 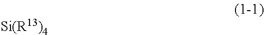
(in Formula (1-1),
R¹³ is a group or an atom bonded to a silicon atom, and each independently represents a hydroxy group, an alkoxy group, an aralkyloxy group, an acyloxy group, or a halogen atom); and
a hydrolyzable silane represented by Formula (2) 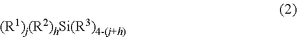
(in Formula (2),
R¹ is a group bonded to a silicon atom, and represents an organic group containing a succinic anhydride skeleton,
R² is a group bonded to a silicon atom, and each independently represents an optionally substituted alkyl group, an optionally substituted halogenated alkyl group, or an optionally substituted alkoxyalkyl group, or represents an organic group containing an epoxy group, an acryloyl group, a methacryloyl group, a mercapto group, an amino group, an amide group, an alkoxy group, a sulfonyl group, or a cyano group, or a combination of two or more thereof,
R³ is a group or an atom bonded to a silicon atom, and each independently represents an alkoxy group, an aralkyloxy group, an acyloxy group, or a halogen atom,
j represents 1, h represents an integer of 0 to 2, and 4-(j+h) represents an integer of 1 to 3).

2. The silicon-containing resist underlayer film-forming composition according to claim 1, wherein in the hydrolyzable silane mixture, a content ratio of the hydrolyzable silane represented by the Formula (1-1) is more than 0 mol % and 30 mol % or less with respect to 100 mol % of the hydrolyzable silane contained in the hydrolyzable silane mixture.

3. The silicon-containing resist underlayer film-forming composition according to claim 1, wherein the hydrolyzable silane mixture further contains a hydrolyzable silane represented by Formula (1) below: 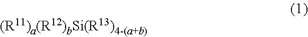
in Formula (1), R¹¹ is a group bonded to a silicon atom, and each independently represents a monovalent group represented by Formula (2a) below or a monovalent group represented by Formula (2b) below,
R¹² is a group bonded to a silicon atom, and each independently represents an optionally substituted alkyl group, an optionally substituted aryl group, an optionally substituted aralkyl group, an optionally substituted halogenated alkyl group, an optionally substituted halogenated aryl group, an optionally substituted halogenated aralkyl group, an optionally substituted alkoxyalkyl group, an optionally substituted alkoxyaryl group, an optionally substituted alkoxyaralkyl group, or an optionally substituted alkenyl group, or an organic group including an epoxy group, an acryloyl group, a methacryloyl group, a mercapto group, an amino group, an alkoxy group, a sulfonyl group, or a cyano group, or a combination of two or more thereof,
R¹³ is a group or an atom bonded to a silicon atom, and each independently represents a hydroxy group, an alkoxy group, an aralkyloxy group, an acyloxy group, or a halogen atom,
a represents an integer of 0 to 2, b represents an integer of 0 to 2, and 4-(a+b) represents an integer of 1 to 3, 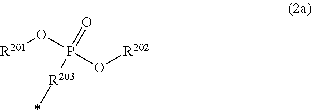
(in Formula (2a),
R²⁰¹ to R²⁰² each independently represent a hydrogen atom or an organic group containing an optionally substituted alkyl group, R²⁰³ represents an optionally substituted alkylene group, and * represents a bond bonded to a silicon atom,) 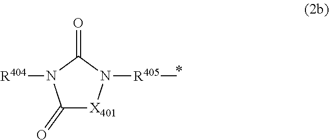
(in Formula (2b),
R⁴⁰⁴ each independently represents a hydrogen atom, an optionally substituted alkyl group, an optionally substituted alkenyl group, or an organic group having an epoxy group or an organic group having a sulfonyl group, and R⁴⁰⁵ each independently represents an alkylene group, a hydroxyalkylene group, a sulfide bond (—S—), an ether bond (—O—), or an ester bond (—CO—O— or —O—CO—). * represents a bond,
X⁴⁰¹ each independently represents any one of the groups represented by Formulas (4-3) to (4-5) below, and a carbon atom of a ketone group in Formulas (4-4) and (4-5) below is bonded to the nitrogen atom to which R⁴⁰⁵ in Formula (2b) is bonded, 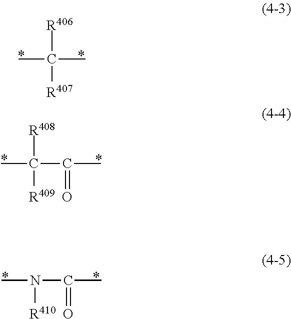
(in Formulas (4-3) to (4-5),
R⁴⁰⁶ to R⁴¹⁰ each independently represent a hydrogen atom, an optionally substituted alkyl group, an optionally substituted alkenyl group, or an organic group having an epoxy group or a sulfonyl group. * represents a bond)).

4. The silicon-containing resist underlayer film-forming composition according to claim 3, containing a hydrolyzable silane represented by Formula (1-2) below among the hydrolyzable silanes represented by the Formula (1): 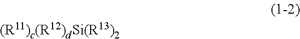
in Formula (1-2),
R¹¹ is the same as R¹¹ in the Formula (1),
R¹² is the same as R¹² in the Formula (1),
R¹³ is the same as R¹³ in the Formula (1),
c represents an integer of 0 to 2, d represents an integer of 0 to 2, and c+d=2.

5. The silicon-containing resist underlayer film-forming composition according to claim 3, containing a hydrolyzable silane represented by Formula (1-3) below among the hydrolyzable silanes represented by the Formula (1): 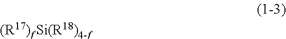
in Formula (1-3), R¹⁷ is a group bonded to a silicon atom, and each independently represents an optionally substituted alkyl group, an optionally substituted aryl group, an optionally substituted aralkyl group, an optionally substituted halogenated alkyl group, an optionally substituted halogenated aryl group, an optionally substituted halogenated aralkyl group, an optionally substituted alkoxyalkyl group, an optionally substituted alkoxyaryl group, an optionally substituted alkoxyaralkyl group, or an optionally substituted alkenyl group, or an organic group containing an epoxy group, an acryloyl group, a methacryloyl group, a mercapto group, an amino group, or a cyano group,
R¹⁸ is a group or an atom bonded to a silicon atom, and each independently represents an alkoxy group, an aralkyloxy group, an acyloxy group, or a halogen atom,
f represents an integer of 1 to 3.

6. A silicon-containing resist underlayer film, which is a cured product of the silicon-containing resist underlayer film-forming composition according to claim 1.

7. A laminate comprising: a semiconductor substrate; and the silicon-containing resist underlayer film according to claim 6.

8. A method for producing a semiconductor element, the method comprising:
forming an organic underlayer film on a substrate;
forming a silicon-containing resist underlayer film using the silicon-containing resist underlayer film-forming composition according to claim 1 on the organic underlayer film; and
forming a resist film on the silicon-containing resist underlayer film.

9. A method for forming a pattern, the method comprising:
forming an organic underlayer film on a semiconductor substrate;
applying the silicon-containing resist underlayer film-forming composition according to claim 1 on the organic underlayer film and baking to form a silicon-containing resist underlayer film;
forming a resist film on the silicon-containing resist underlayer film;
exposing and developing the resist film to obtain a resist pattern;
a step of etching the silicon-containing resist underlayer film using the resist pattern as a mask; and
etching the organic underlayer film using the patterned silicon-containing resist underlayer film as a mask.

10. The method for forming a pattern according to claim 9, further comprising removing the silicon-containing resist underlayer film by a wet method using a chemical solution, after etching the organic underlayer film.

11. The method for forming a pattern according to claim 10, wherein the chemical solution is a basic chemical solution.
